(19) United States
(12) Patent Application Publication
(10) Pub. No.: US 2009/0280440 A1
(43) Pub. Date: Nov. 12, 2009

(54) SURFACE TREATING AGENT FOR RESIST-PATTERN, AND PATTERN-FORMING METHOD USING SAME

(75) Inventors: Shinji Tarutani, Haibara-gun (JP); Hideaki Tsubaki, Haibara-gun (JP); Naoya Sugimoto, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/433,384

(22) Filed: Apr. 30, 2009

Related U.S. Application Data
(60) Provisional application No. 61/050,477, filed on May 5, 2008.

(30) Foreign Application Priority Data
May 2, 2008 (JP) 2008-120627

(51) Int. Cl. G03F 7/20; G03F 7/00

(52) U.S. Cl. 430/325; 430/331

(57) ABSTRACT

A surface treating agent for resist pattern, characterized by containing not only a chemical species having a functional group capable of chemical adsorption to resist pattern and a polymerizable group but also a solvent.

### CROSS-REFERENCE TO RELATED APPLICATIONS

This application claims the benefit of U.S. Provisional Application No. 61/050,477, filed May 5, 2008.

This application is based upon and claims the benefit of priority from prior Japanese Patent Application No. 2008-120627, filed May 2, 2008, the entire contents of which are incorporated herein by reference.

### BACKGROUND OF THE INVENTION

1. Field of the Invention

The present invention relates to a surface treating agent for resist pattern formation employed in a semiconductor production process for an IC or the like, a circuit board production process for a liquid crystal, thermal head or the like and other photofabrication lithography processes, and also relates to a method of forming a pattern with the use thereof.

More particularly, the present invention relates to a surface treating agent for resist pattern formation that is suitable for exposure by means of any type of projection exposure unit (including a liquid immersion exposure unit) using far ultraviolet rays of 200 nm or shorter wavelength as a light source, and to a method of forming a pattern with the use thereof.

2. Description of the Related Art

Due to the wavelength shortening of the exposure light source to 248 nm using a KrF excimer laser, it has been of common practice to, in order to compensate for any sensitivity deterioration caused by light absorption, employ an image forming method through chemical amplification as a resist image forming method and employ a resist suitable for the same. Brief description of an image forming method through positive chemical amplification is given below by way of example. Upon exposure, an acid generator will be decomposed at exposed areas to thereby generate an acid. Upon baking after the exposure (PEB: Post-Exposure Baking), the generated acid is used as a reaction catalyst so that an alkali-insoluble group is converted to an alkali-soluble group. Thereafter, alkali development is carried out to thereby remove the exposed areas. Thus, the relevant image forming method is provided.

In accordance with the miniaturization of semiconductor elements, the wavelength shortening of the exposure light source and the realization of high numerical apertures (high NA) for projector lenses have advanced. Further, an exposure machine using an ArF excimer laser of 193 nm wavelength as a light source has been developed. The degree of attainment of semiconductor element miniaturization can be expressed by the resolving power. As is commonly known, the resolving power can be expressed by the following formula.

(Resolving power)=k₁·(λ/NA)

In the formula, λ is the wavelength of the exposure light source; NA is the numerical aperture of the projector lens; and k₁ is a factor relating to the process.

Heretofore, a method of filling an interspace between a projector lens and a sample with a liquid of high refractive index (hereinafter also referred to as a “liquid for liquid immersion”), known as a liquid immersion method, is recommended as a technology for enhancing of the resolving power.

With respect to the “effect of liquid immersion,” taking λ₀ as the wavelength of exposure light in air, n as the refractive index of liquid for liquid immersion to air and θ as the convergent half angle of light beam, where NA₀=sin θ, the above-mentioned resolving power and the relevant focal depth in the event of liquid immersion can be expressed by the following formula.

(Resolving power)=k₁·(λ₀/n)/NA₀

That is, the effect of liquid immersion is equivalent to the use of a 1/n exposure wavelength. In other words, in projection optic systems of identical NA, the liquid immersion would enable the focal depth to be n-fold.

As another technology for enhancing the resolving power, pattern forming methods using a special process have been proposed. These correspond to lowering of the value of k₁ in the above formula of resolving power. One of the methods is a freezing process (see, for example, patent reference (1) and non-patent references (1) to (4)).

The freezing process refers to the process wherein, in the double patterning technique involving formation of a first resist pattern on a first resist film, formation of a second resist film on the first resist pattern and formation of a second resist pattern thereon, the properties of the first resist pattern are changed by chemical or physical treatment to avoid, in the formation of the second resist film, the first resist pattern being dissolved in a second resist liquid or mixed with the second resist film. By the employment of this technology, any desired resist pattern can be formed through division into two steps and there can be realized a resolving power of twice that attained by the ordinary exposure process.

Patent reference (1) discloses a technology in which in the double patterning technique, a freezing treatment agent containing a specified metal compound is applied onto the first resist pattern so as to form a metal oxide coating, thereby insolubilizing the resist pattern in the solvent of a second applied resist and also a thereafter applied developer.

However, in this technology, as the second resist pattern is not provided with any metal oxide coating, a difference would occur in the etching resistance between the first resist pattern and the second resist pattern, thereby causing the control of pattern dimension after etching to be difficult. It would be conceivable to apply a surface treating agent to the second resist pattern for avoiding this problem. However, a problem of increasing the number of operations would arise.

Moreover, as a resist pattern forming material capable of forming a micropattern exceeding a wavelength limit, patent reference (2) discloses a micropattern forming material consisting of the following composition. The composition is one containing a water-soluble organic compound having a cationic group and either water or a mixed solvent consisting of water and a water-soluble organic solvent, wherein the cationic group of the water-soluble organic compound forms a salt in cooperation with an anionic group within a resist pattern to thereby form an insolubilized film. However, even if the surface of the first resist pattern is treated by this method, suppression of the solubility in the resist solvent would be unsatisfactory, which would thereby cause the application thereof to a freezing process to be infeasible.

Still further, non-patent reference (2) reveals the results of the application of a freezing process. However, problems such that freezing has resulted in a decrease of the height of first resist pattern or an increase in the line width roughness (LWR) of the pattern have been indicated.

[Patent reference 1] Jpn. Pat. Appln. KOKAI Publication No. (hereinafter referred to as JP-A-) 2008-33174

[Patent reference 2] JP-A-2006-18095

[Non-patent reference 1] Proceedings of SPIE, Vol. 6153, 615301 (2006)

[Non-patent reference 2] Proceedings of SPIE, Vol. 6923, 69230H (2008)

[Non-patent reference 3] Proceedings of SPIE, Vol. 6924, 69240R (2008)

[Non-patent reference 4] Proceedings of SPIE, Vol. 6520, 65200F (2007)

### BRIEF SUMMARY OF THE INVENTION

It is an object of the present invention to provide a surface treating agent for a resist pattern that in the double patterning technique, is capable of modifying the properties of a first resist pattern so as to avoid dissolution of the first resist pattern in the resist liquid and developer used in the forming of second resist pattern and so as to, after the formation of the second resist pattern, ensure suppression of changes of the width, LWR and height of the first resist pattern, thereby being suitable for the freezing process. It is another object of the present invention to provide a method of forming a resist pattern with the use of the surface treating agent.

The inventor has conducted extensive and intensive studies with a view toward solving the above problems. As a result, the following present invention has been arrived at.

(1) A surface treating agent for resist pattern, containing a chemical species having a functional group capable of chemical adsorption to resist pattern and a polymerizable group, and a solvent.

(2) The surface treating agent for resist pattern according to item (1), wherein the chemical adsorption is based on an ionic bond or electrostatic attractive force.

(3) The surface treating agent for resist pattern according to item (1) or (2), wherein the functional group capable of chemical adsorption is a basic functional group.

(4) The surface treating agent for resist pattern according to item (3), wherein the basic functional group is an amino group.

(5) The surface treating agent for resist pattern according to any one of items (1) to (4), wherein the polymerizable group is a group containing an ethylenically unsaturated bond.

(6) The surface treating agent for resist pattern according to any one of items (1) to (5), wherein further a polymerization initiator is contained.

(7) The surface treating agent for resist pattern according to item (6), wherein the polymerization initiator is a thermal radical initiator.

(8) The surface treating agent for resist pattern according to any one of items (1) to (7), in a resist pattern consisting of a first resist pattern obtained by exposing a first resist film and development and a second resist pattern obtained by exposing a second resist film provided on the first resist pattern and development, being a surface treating agent for the first resist pattern.

(9) A method of forming a resist pattern, including the step of exposing a first resist film and development to thereby obtain a first resist pattern and the step of forming a second resist film on the first resist pattern obtained in the above step and exposing the same and development to thereby obtain a second resist pattern, wherein between the first resist pattern forming step and the second resist pattern forming step, there is interposed the step of treating the first resist pattern with the use of the surface treating agent according to any one of items (1) to (8).

(10) The resist pattern forming method according to item (9), wherein a heating step is interposed between the first resist pattern treating step using the surface treating agent according to any one of items (1) to (8) and the second resist pattern forming step.

(11) The resist pattern forming method according to item (9) or (10), wherein the step of treating the first resist pattern with the use of an acid is interposed between the first resist pattern forming step and the first resist pattern treating step using the surface treating agent according to any one of items (1) to (8).

(12) The resist pattern forming method according to item (11), wherein a heating step is interposed between the step of treating the first resist pattern with the use of an acid and the first resist pattern treating step using the surface treating agent according to any one of items (1) to (8).

The present invention provides a surface treating agent for resist pattern that is suitable for the freezing process and a method of forming a resist pattern with the use thereof, by which it has become feasible to suppress any changes of the width, LWR and height of first resist pattern upon the formation of second resist pattern.

### BRIEF DESCRIPTION OF THE SEVERAL VIEWS OF THE DRAWING

FIG. 1 is a process flow diagram explaining the method of forming a pattern as employed in Examples.

In the diagram, 1 is a first resist film, 2 is a second resist film, 3 is a surface treating agent (freezing agent), 4 is a antireflection film, 5 is a silicon wafer, 1a is a first resist pattern, 1b is a first resist pattern (after freezing treatment), 2a is a second resist pattern, m1 and m2 are masks, and n is a nozzle.

### DETAILED DESCRIPTION OF THE INVENTION

Now, the present invention will be described in detail.

With respect to the expression of group (atomic group) used in this specification, the expression even when there is no mention of “substituted and unsubstituted” comprehends groups not only having no substituent but also having substituents. For example, the “alkyl groups” include not only alkyls having no substituent (unsubstituted alkyls) but also alkyls having substituents (substituted alkyls).

1. Surface Treating Agent for Resist Pattern

<Chemical Species>

The chemical species contained as an indispensable component in the surface treating agent for resist pattern according to the present invention (hereinafter also referred to as “chemical species according to the present invention”) has a functional group capable of chemical adsorption to resist pattern and a polymerizable group.

The functional group capable of chemical adsorption to a resist pattern (hereinafter also referred to as “chemical adsorption functional group” or the like) is not limited as long as the functional group is capable of inducing adsorption by the action of a chemical binding force or the manifestation of a chemical interaction between the same and the surface of resist pattern. In particular, as generally an alcoholic hydroxyl group, a carboxylate group, etc. are present on the resist pattern, the chemical adsorption functional group is preferably one capable of chemical adsorption with such functional groups by the action of a chemical binding force or the manifestation of a chemical interaction therewith. Especially, from the viewpoint of such chemical interaction, it is preferred to employ either a functional group capable of inducing an electrostatic attractive force, such as a hydrogen bond, or a functional group capable of forming an ionic bond through an acid base neutralization reaction with the functional groups being present on the resist pattern.

As the functional group capable of forming an ionic bond through an acid base neutralization reaction, there can be mentioned a basic functional group, such as an amino group, a thioalkoxy group or an alkoxy group. As the functional group capable of inducing an electrostatic attractive force, such as a hydrogen bond, there can be mentioned, for example, a carbonyl group, a carboxyl group, a cyano group, an ether group or the like. From the viewpoint of higher adsorptive force, the ionic bond is preferred to the electrostatic attractive force, such as a hydrogen bond. Among them, an amino group is most preferred from the viewpoint of stability.

The amino group is represented by the formula —NRR′ (each of R and R′ independently represents a hydrogen atom, an alkyl group or a cycloalkyl group). The alkyl groups represented by R and R′ are preferably an alkyl group having 1 to 6 carbon atoms, more preferably an alkyl group having 1 to 3 carbon atoms. The cycloalkyl group is preferably a cycloalkyl group having 3 to 8 carbon atoms, more preferably a cycloalkyl group having 3 to 6 carbon atoms.

The polymerizable group included in the chemical species according to the present invention is not limited as long as the group can generally induce a polymerization reaction by radical, etc. The polymerizable group is preferably a group containing an ethylenically unsaturated bond, more preferably a (meth)acryloyl group, an allyl group or a vinyl group. For example, there can be mentioned any of groups represented by the below shown general formulae (RP1) to (RP3).

The chemical species according to the present invention in one aspect thereof can be represented by the following general formula.

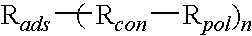

In the formula,

R_{ads} is a functional group capable of chemical adsorption to resist pattern,

Rₚₒₗ is a polymerizable group,

R_{con} is a connecting group, and

n is a positive integer, preferably from 1 to 3, more preferably 1 or 2 and most preferably 1.

The chemical adsorption functional group represented by R_{ads} is as described above.

The polymerizable group represented by Rₚₒₗ is as described above. As specific examples thereof, there can be mentioned groups represented by the following general formulae (RP1) to (RP3).

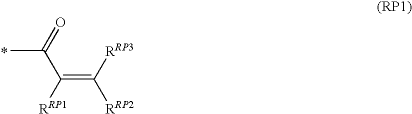

In the formula (RP1),

* is a bonding hand with a connecting group, and

each of R^{RP1} to R^{RP3} independently represents a hydrogen atom or a monovalent organic group.

As preferred R^{RP1}, there can be mentioned a hydrogen atom or an optionally substituted alkyl group. A hydrogen atom or a methyl group is especially preferred. As preferred R^{RP2} or R^{RP3}, there can be mentioned a hydrogen atom, a halogen atom, an amino group, a carboxyl group, an alkoxycarbonyl group, a cyano group, an optionally substituted alkyl group, an optionally substituted alkoxy group, an optionally substituted alkylamino group or the like. A hydrogen atom, a carboxyl group, an alkoxycarbonyl group, an optionally substituted alkyl group or the like is more preferred. R^{RP1} to R^{RP3} may be bonded with each other to thereby form a ring structure.

As a substituent optionally further included in R^{RP1} to R^{RP3}, there can be mentioned an alkyl group, an alkenyl group, an alkynyl group, an alkoxy group, a halogen atom, an amino group, an alkylamino group, a carboxyl group, an alkoxycarbonyl group, a cyano group or the like.

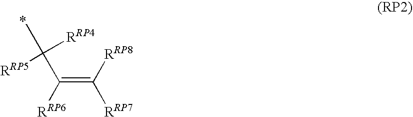

In the formula (RP2),

* is a bonding hand with a connecting group, and

each of R^{RP4} to R^{RP8} independently represents a monovalent organic group.

As preferred R^{RP4} to R^{RP8}, there can be mentioned a hydrogen atom, a halogen atom, an amino group, a dialkylamino group, a carboxyl group, an alkoxycarbonyl group, a cyano group, an optionally substituted alkyl group, an optionally substituted alkoxy group, an optionally substituted alkylamino group or the like. A hydrogen atom, a carboxyl group, an alkoxycarbonyl group, an optionally substituted alkyl group or the like is especially preferred. R^{RP4} to R^{RP8} may be bonded with each other to thereby form a ring structure. As a substituent optionally further included in R^{RP4} to R^{RP8}, there can be mentioned any of those as mentioned above with respect to the general formula (RP1).

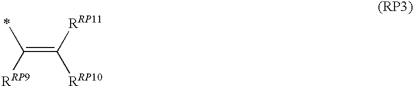

In the formula (RP3),

* is a bonding hand with a connecting group.

As preferred R^{RP9}, there can be mentioned a hydrogen atom, an optionally substituted alkyl group or the like. A hydrogen atom and a methyl group are especially preferred. Each of R^{RP10} and R^{RP11} independently represents a hydrogen atom, a halogen atom, an amino group, a dialkylamino group, a carboxyl group, an alkoxycarbonyl group, a cyano group, an optionally substituted alkyl group, an optionally substituted alkoxy group, an optionally substituted alkylamino group or the like. A hydrogen atom, a carboxyl group, an alkoxycarbonyl group and an optionally substituted alkyl group are especially preferred. R^{RP9} to R^{RP11} may be bonded with each other to thereby form a ring structure. As a substituent optionally further included in R^{RP9} to R^{RP11}, there can be mentioned any of those as mentioned above with respect to the general formula (RP1).

The connecting group represented by R_{con} is not limited as long as it is a single bond or a bivalent organic group. As such, there can be mentioned a single bond, an alkylene group, a cycloalkylene group, a carbonyl group, an ether bond, an ester bond, an amido bond, an arylene group, a group of, connected to each other, at least two groups selected from among these, or the like. Especially, a single bond, an alkylene group, an ether bond and a group of, connected to each other, at least two groups selected from among these are preferred.

When the chemical adsorption functional group is bivalent or of higher valence, and when the polymerizable functional group is also bivalent or of higher valence, the connecting group may form a ring structure in cooperation with other functional groups.

Specific examples of the chemical species having a functional group capable of chemical adsorption to resist pattern and a polymerizable group will be shown below, which should be interpreted as being nonlimiting.

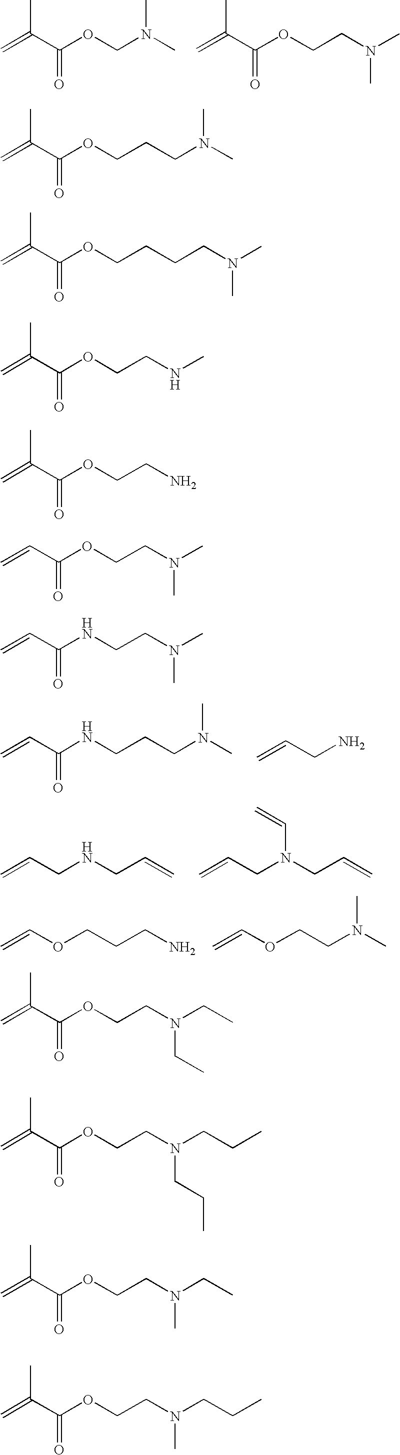

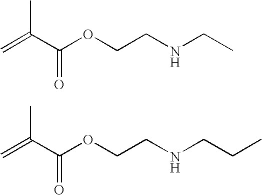

In the surface treating agent of the present invention, the concentration of the total solid content including the chemical species according to the present invention (ratio of all components excluding the solvent in the treating agent) is preferably in the range of 0.1 to 20 mass %, more preferably 0.3 to 10 mass % and still more preferably 0.5 to 5 mass %.

The content of the chemical species according to the present invention in the treating agent is preferably in the range of 50 to 99.9 mass %, more preferably 80 to 99 mass %, based on the total solid content.

<Polymerization Initiator>

The surface treating agent for resist pattern according to the present invention may contain a polymerization initiator. As a preferred polymerization initiator usable in the present invention, there can be mentioned a thermal radical initiator. The thermal radical initiator refers to a compound that generates a radical upon receipt of thermal energy and thereby initiates and promotes the polymerization of a compound having a polymerizable unsaturated group. As the thermal radical initiator in the present invention, use can be made of a member selected from among common thermal radical initiators, compounds having a bond of low bond dissociation energy, and the like. There can be mentioned, for example, an onium salt, a triazine compound with a trihalomethyl group, a peroxide, an azo polymerization initiator, an azide compound, a quinone diazide compound, a metallocene compound and the like. Of these, an onium salt and an azo initiator are preferred.

As the onium salt, there can be mentioned a diazonium salt, an iodonium salt, a sulfonium salt, an ammonium salt, a pyridinium salt or the like. As preferred examples thereof, there can be mentioned an iodonium salt, a diazonium salt, a sulfonium salt and the like. In the present invention, this onium salt functions as an ionic radical polymerization initiator, not as an acid generator.

The onium salts of the following general formulae (II) to (IV) are suitable for use in the present invention.

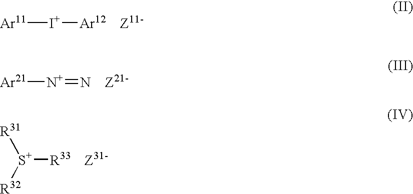

In the formula (II), each of Ar¹¹ and Ar¹² independently represents an optionally substituted aryl group having 20 or less carbon atoms. When the aryl group is substituted, as a preferred substituent, there can be mentioned a halogen atom, a nitro group, an alkyl group having 12 or less carbon atoms, an alkoxy group having 12 or less carbon atoms or an aryloxy group having 12 or less carbon atoms. Z¹¹⁻ represents a counter ion selected from the group consisting of a halide ion, a perchlorate ion, a tetrafluoroborate ion, a hexafluorophosphate ion and a sulfonate ion. A perchlorate ion, a hexafluorophosphate ion and an arylsulfonate ion are preferred.

In the formula (III), Ar²¹ represents an optionally substituted aryl group having 20 or less carbon atoms. As a preferred substituent, there can be mentioned a halogen atom, a nitro group, an alkyl group having 12 or less carbon atoms, an alkoxy group having 12 or less carbon atoms, an aryloxy group having 12 or less carbon atoms, an alkylamino group having 12 or less carbon atoms, a dialkylamino group having 12 or less carbon atoms, an arylamino group having 12 or less carbon atoms or a diarylamino group having 12 or less carbon atoms. Z²¹⁻ represents the same counter ion as mentioned with respect to Z¹¹⁻.

In the formula (IV), each of R³¹, R³² and R³³ independently represents an optionally substituted hydrocarbon group having 20 or less carbon atoms. As a preferred substituent, there can be mentioned a halogen atom, a nitro group, an alkyl group having 12 or less carbon atoms, an alkoxy group having 12 or less carbon atoms or an aryloxy group having 12 or less carbon atoms. Z³¹⁻ represents the same counter ion as mentioned with respect to Z¹¹⁻.

Specific examples of the onium salts ([OI-1] to [OI-10]) of the general formula (II), onium salts ([ON-1] to [ON-5]) of the general formula (III) and onium salts ([OS-1] to [OS-6]) of the general formula (IV) that are suitable for use in the present invention will be shown below, which however in no way limit the scope of onium salts employable in the present invention.

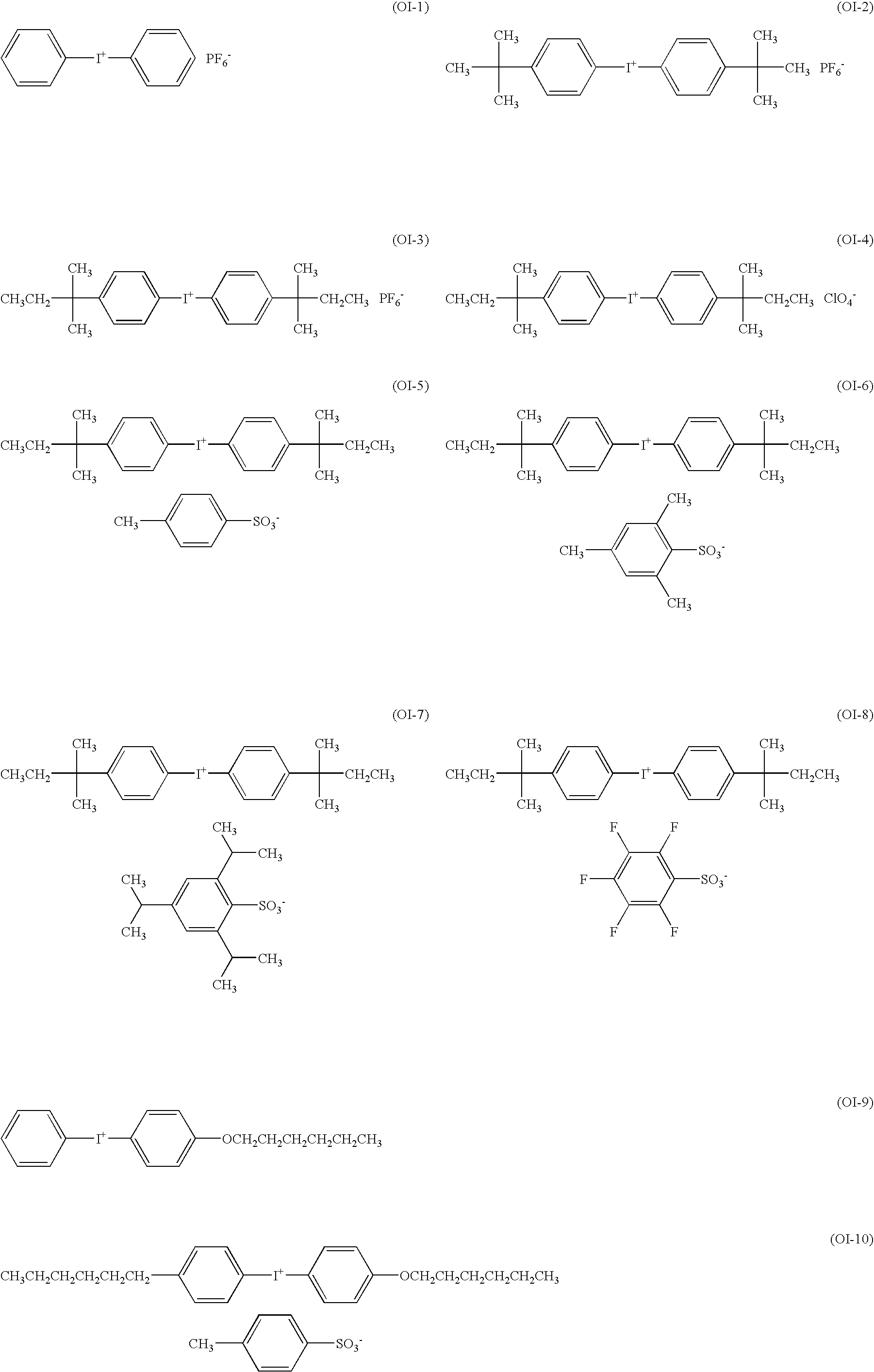

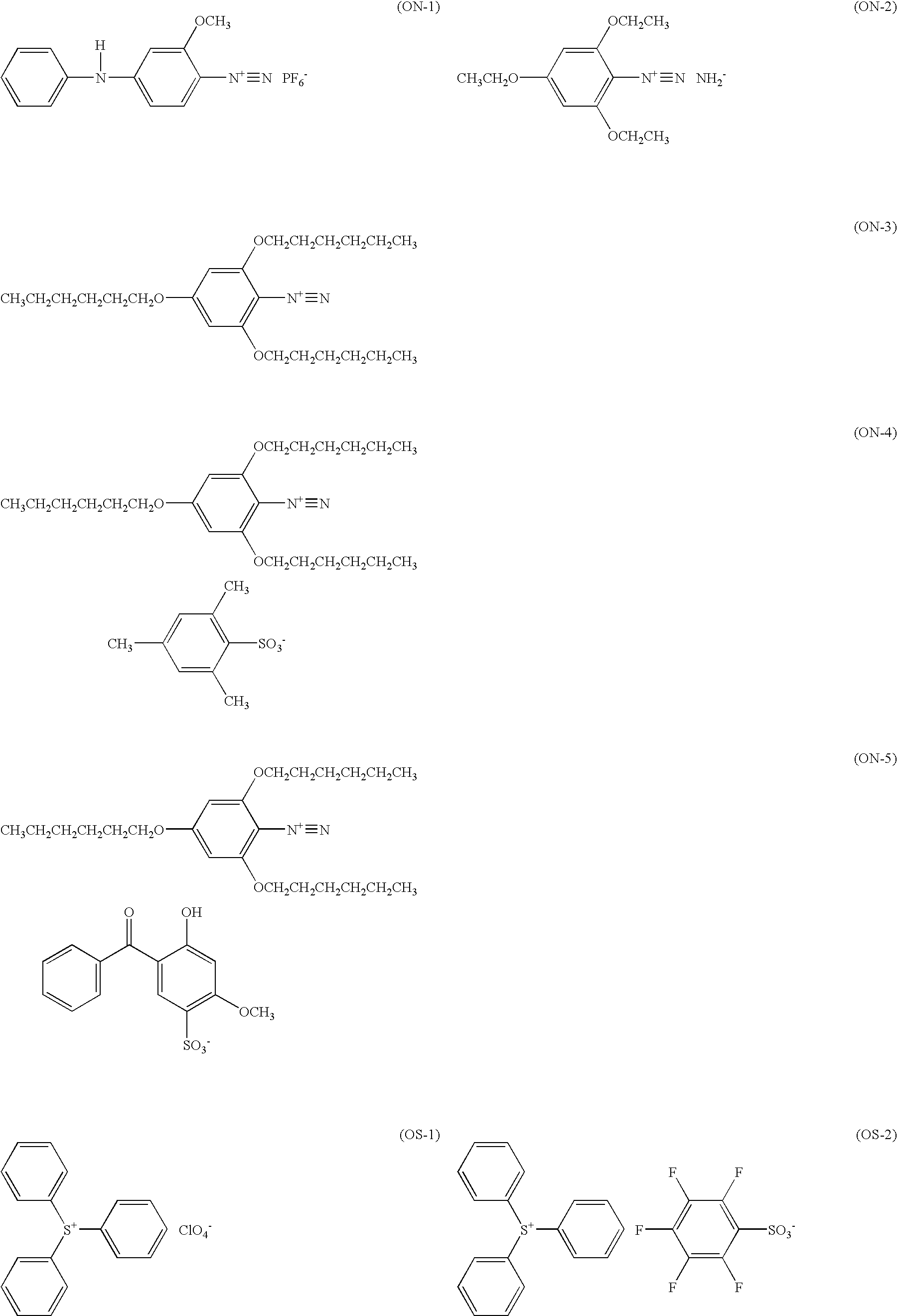

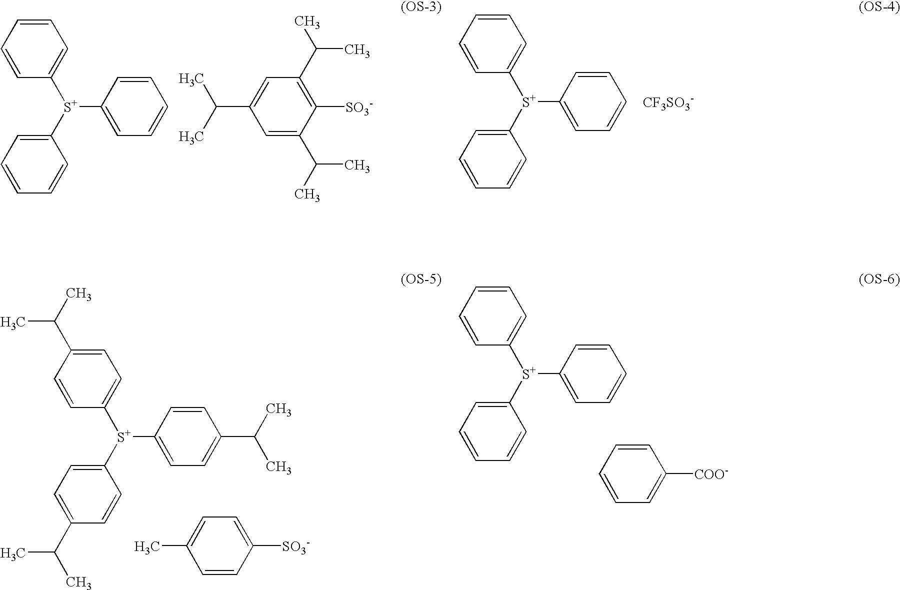

The azo initiator is preferably an azo initiator having an ester group, a cyano group or a carboxyl group.

The azo initiator suitable for use in the present invention is any one of those of the following general formula.

Rⁱⁿⁱ¹—N═N—Rⁱⁿⁱ²

In the formula, each of Rⁱⁿⁱ¹ and Rⁱⁿⁱ² represents an organic group. The organic group has preferably at least one chemical structure selected from among an ester bond, a cyano group and a carboxyl group. Although the Rⁱⁿⁱ¹ and Rⁱⁿⁱ² may be identical with or different from each other, it is preferred that they be identical with each other from the viewpoint of synthesis and procurement easiness.

Specific examples of the azo initiators will be shown below, which should be interpreted as being nonlimiting.

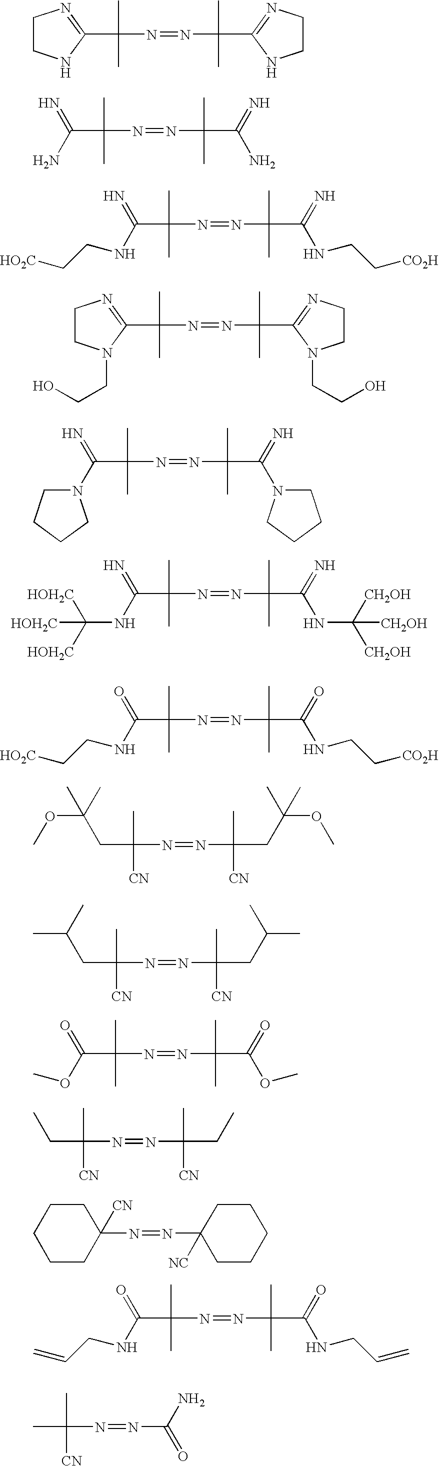

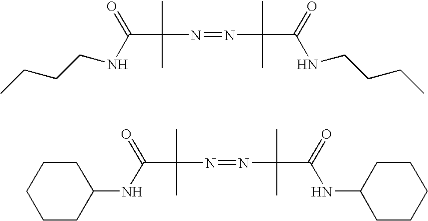

These azo initiators are available from, for example, Wako Pure Chemical Industries, Ltd.

The content of polymerization initiator in the treating agent is preferably in the range of 0.1 to 50 mass %, more preferably 1 to 20 mass % based on total solid mass.

<Solvent>

The solvent for incorporation in the surface treating agent for resist pattern according to the present invention is preferably one that does not dissolve the first resist pattern but is capable of dissolving the chemical species according to the present invention. In this connection, not dissolving the first resist pattern refers to that, when at 23° C. a 200 nm line-and-space pattern of 0.2 μm height is formed and immersed in an organic solvent for 10 min, both a pattern dimensional variation and height variation of pattern fall within 5%. As such a solvent, there can be mentioned an alcohol solvent, a fluorinated solvent, a saturated hydrocarbon solvent or the like. Especially, an alcohol solvent is preferred from the viewpoint of solubility of the chemical species according to the present invention.

It is preferred that the alcohol solvent be a monohydric alcohol from the viewpoint of environmental safety, storage stability and human safety. Alcohols can be used either individually or in a mixture.

As specific examples of the monohydric alcohols, there can be mentioned methanol, ethanol, n-propanol, isopropanol, n-butanol, sec-butanol, tert-butanol, isobutanol, tert-pentanol, n-hexanol, n-heptanol, 2-heptanol, n-octanol, n-decanol, 3-methyl-3-pentanol, 2,3-dimethyl-2-pentanol, 4-phenyl-2-methyl-2-hexanol, 1-phenyl-2-methyl-2-propanol, s-amyl alcohol, t-amyl alcohol, isoamyl alcohol, 2-ethyl-1-butanol, n-undecanol and the like. Of these, alcohols having 4 to 11 carbon atoms are preferred. Alcohols having 5 to 9 carbon atoms are more preferred. From the viewpoint of suppression of solvent evaporation, the number of carbon atoms is preferably 5 or greater, more preferably 6 or greater.

As the fluorinated solvent, use can be made of perfluoro-2-butyltetrahydrofuran, perfluorotetrahydrofuran, perfluorohexane, perfluoroheptane, perfluorotributylamine, perfluorotetrapentylamine, perfluorotetrahexylamine or the like. These organic solvents can be used either individually or in a mixture. The content of fluorine in each molecule is preferably in the range of 40 to 80 mass %, more preferably 50 to 80 mass %.

In particular, the fluorinated solvent has preferably 7 to 12 carbon atoms, more preferably 9 to 12 carbon atoms. From the viewpoint of suppression of solvent evaporation, the number of carbon atoms is preferably 7 or greater, more preferably 9 or greater.

As the saturated hydrocarbon solvent, there can be mentioned a linear or branched alkane or a cycloalkane. Specifically, use can be made of pentane, 2-methylbutane, 3-methylpentane, hexane, 2,2-dimethylbutane, 2,3-dimethylbutane, heptane, octane, 2,2,4-trimethylpentane, 2,2,3-trimethylhexane, nonane, decane, undecane, dodecane, 2,2,4,6,6-pentamethylheptane, tridecane, pentadecane, tetradecane, hexadecane, cyclopentane, cyclohexane, cycloheptane, cyclooctane or the like. These organic solvents can be used either individually or in a mixture. Further, a terpenic saturated hydrocarbon can be used as a solvent. As a preferred example, there can be mentioned a cyclic saturated terpene, such as pinane, bornane, carane, fencane, thujane, o-menthane, m-menthane or p-menthane.

These saturated hydrocarbon solvents each have preferably 6 to 10 carbon atoms, more preferably 7 to 9 carbon atoms. From the viewpoint of suppression of solvent evaporation, the number of carbon atoms is preferably 6 or greater, more preferably 7 or greater.

Preferably, the organic solvent is one that does not dissolve the first resist pattern but is capable of dissolving the chemical species according to the present invention. In the employed solvent, it is preferred that any of an alcohol solvent, a fluorinated solvent and a saturated hydrocarbon solvent be contained in an amount of 80 mass % or more, especially 90 mass % or more.

As other organic solvents, use can be made of at least any one member appropriately selected from among ester, ether, ketone, amide, aromatic hydrocarbon and cyclic ketone solvents. For example, there can be mentioned an ester, such as ethyl lactate, ethyl acetate, butyl acetate or methyl methoxypropionate; an ether, such as a monomethyl ether, monoethyl ether or monophenyl ether of ethylene glycol monoacetate, diethylene glycol monoacetate, propylene glycol monoacetate or dipropylene glycol monoacetate, or a derivative thereof; a cyclic ether, such as dioxane; a ketone, such as acetone, methyl ethyl ketone, cyclohexanone or 2-heptanone; or the like.

The content of organic solvent in the treating agent is not particularly limited as long as the chemical species according to the present invention is dissolved. Preparation is preferably made so that the content falls within the range of 80 to 99.9 mass %, more preferably 90 to 99.7 mass % and still more preferably 95 to 99.5 mass %.

<Surfactant>

The treating agent of the present invention preferably contains any of various surfactants. As the surfactant, there can be mentioned those employable in the “first resist” as described later. The surfactants may be used either individually or in combination.

The amount of surfactant used is preferably in the range of 0.0001 to 2 mass %, more preferably 0.001 to 1 mass % based on the total mass of the treating agent.

The applicability of the treating agent can be enhanced by the addition of a surfactant to the treating agent.

2. First Resist

In the present invention, it is important to, after the formation of the first resist pattern on the first resist film, change the first resist pattern so as not to be dissolved in the second resist liquid by the use of the treating agent containing the chemical species according to the present invention. This regulation can be achieved by changing not only the properties of the treating agent but also the properties of the first resist and/or the process conditions at the application of the treating agent.

Although the first resist may be either a positive resist or a negative resist, the positive resist is preferred from the viewpoint of intention to enhance the reactivity with the treating agent. Herein, the “positive resist” refers to a resist whose exposed area is dissolved in a developer, while the “negative resist” refers to a resist whose non-exposed area is dissolved in a developer. In the positive resist, generally, a chemical reaction, such as elimination of an atomic group protecting an alkali soluble group, is utilized in order to enhance the solubility of the exposed area in the developer. On the other hand, in most negative resists, an intermolecular bond formation, such as crosslinking reaction or polymerization reaction, is utilized.

The positive resist preferably contains (A) a resin that is decomposed by the action of an acid to thereby have an increased solubility in an alkali developer and (B) a compound that when exposed to actinic rays or radiation, generates an acid.

[1] Resin that is Decomposed by the Action of an Acid to Thereby have an Increased Solubility in an Alkali Developer (Resin (A))

The resin (A) is preferably one that generates a carboxyl group by chemical reaction during the process of first resist pattern formation so that chemical adsorption is induced with the treating agent containing the chemical species according to the present invention to thereby change the properties of the first resist pattern so as not to be dissolved in the second resist liquid. A resin containing a carboxyl group may be contained in the first resist prior to pattern formation.

The resin (A) is a resin whose solubility in an alkali developer is increased by the action of an acid, especially a resin provided at its principal chain or side chain or both thereof with a group that is decomposed by the action of an acid to thereby generate an alkali soluble group (hereinafter also referred to as an “acid-decomposable group”).

As the alkali soluble group, there can be mentioned a phenolic hydroxyl group, a carboxyl group, a fluoroalcohol group, a sulfonate group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group or the like.

As preferred alkali soluble groups, there can be mentioned a carboxyl group, a fluoroalcohol group (preferably hexafluoroisopropanol) and a sulfonate group.

The acid-decomposable group is preferably a group as obtained by substituting the hydrogen atom of any of these alkali soluble groups with an acid eliminable group.

As the acid eliminable group,

there can be mentioned, for example, —C(R₃₆)(R₃₇)(R₃₈), —C(R₃₆)(R₃₇)(OR₃₉), —C(R₀₁)(R₀₂)(OR₃₉) or the like.

In the formulae, each of R₃₆ to R₃₉ independently represents an alkyl group, a cycloalkyl group, an aryl group, an aralkyl group or an alkenyl group. R₃₆ and R₃₇ may be bonded with each other to thereby form a ring structure.

Each of R₀₁ to R₀₂ independently represents a hydrogen atom, an alkyl group, a cycloalkyl group, an aryl group, an aralkyl group or an alkenyl group.

Preferably, the acid-decomposable group is a cumyl ester group, an enol ester group, an acetal ester group, a tertiary alkyl ester group or the like. A tertiary alkyl ester group is more preferred.

In the resin (A), the repeating unit having the acid-decomposable group is preferably any of those of the following general formula (AI).

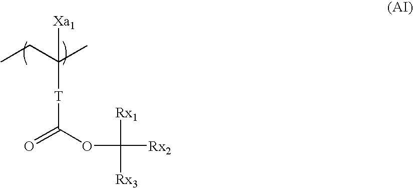

In the general formula (AI),

Xa₁ represents a hydrogen atom, a methyl group, a trifluoromethyl group or a hydroxymethyl group,

T represents a single bond or a bivalent connecting group, and

each of Rx₁ to Rx₃ independently represents an alkyl group (linear or branched) or a cycloalkyl group (monocyclic or polycyclic),

provided that at least two of Rx₁ to Rx₃ may be bonded with each other to thereby form a cycloalkyl group (monocyclic or polycyclic).

As the bivalent connecting group represented by T, there can be mentioned an alkylene group, a group of the formula —COO-Rt-, a group of the formula —O-Rt- or the like. In the formulae, Rt represents an alkylene group or a cycloalkylene group.

T is preferably a single bond or a group of the formula —COO-Rt-. Rt is preferably an alkylene group having 1 to 5 carbon atoms, more preferably a —CH₂— group or —(CH₂)₃— group.

The alkyl group represented by each of Rx₁ to Rx₃ is preferably one having 1 to 4 carbon atoms, such as a methyl group, an ethyl group, an n-propyl group, an isopropyl group, an n-butyl group, an isobutyl group or a t-butyl group.

The cycloalkyl group represented by each of Rx₁ to Rx₃ is preferably a cycloalkyl group of one ring, such as a cyclopentyl group or a cyclohexyl group, or a cycloalkyl group of multiple rings, such as a norbornyl group, a tetracyclodecanyl group, a tetracyclododecanyl group or an adamantyl group.

The cycloalkyl group formed by bonding of at least two of Rx₁ to Rx₃ is preferably a cycloalkyl group of one ring, such as a cyclopentyl group or a cyclohexyl group, or a cycloalkyl group of multiple rings, such as a norbornyl group, a tetracyclodecanyl group, a tetracyclododecanyl group or an adamantyl group.

In a preferred mode, Rx₁ is a methyl group or an ethyl group, and Rx₂ and Rx₃ are bonded with each other to thereby form any of the above-mentioned cycloalkyl groups.

The above-mentioned atomic groups may further have substituents. As examples thereof, there can be mentioned an alkyl group, a cycloalkyl group, an alkoxy group, a hydroxyl group, a cyano group and the like.

The content of repeating units having the acid-decomposable group is preferably in the range of 20 to 50 mol %, more preferably 25 to 45 mol %, based on all the repeating units of the resin (A).

Specific examples of the preferred repeating units having the acid-decomposable groups will be shown below, which however in no way limit the scope of the present invention.

In the formulae, Rx represents H, CH₃, CF₃ or CH₂OH, and each of Rxa and Rxb independently represents an alkyl group having 1 to 4 carbon atoms.

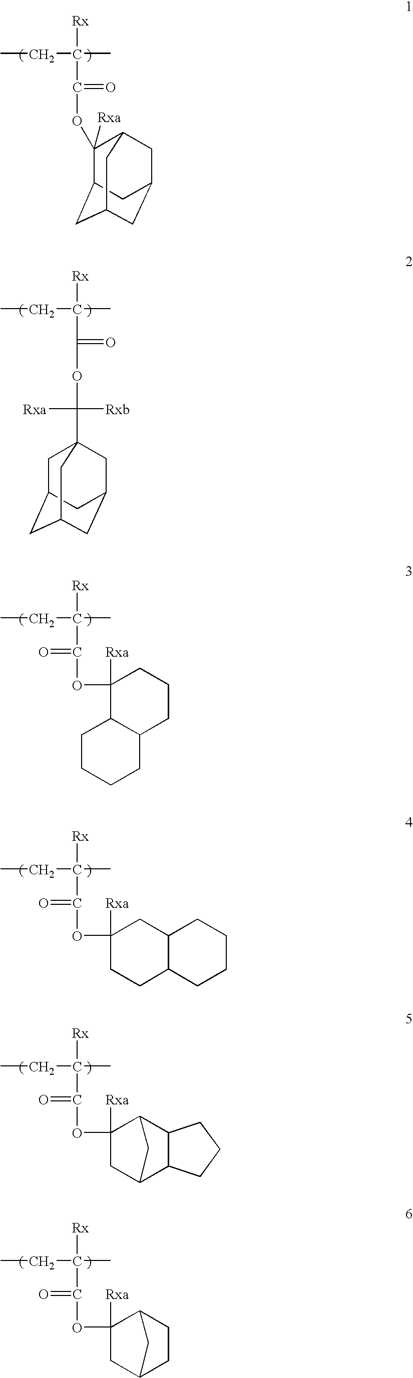

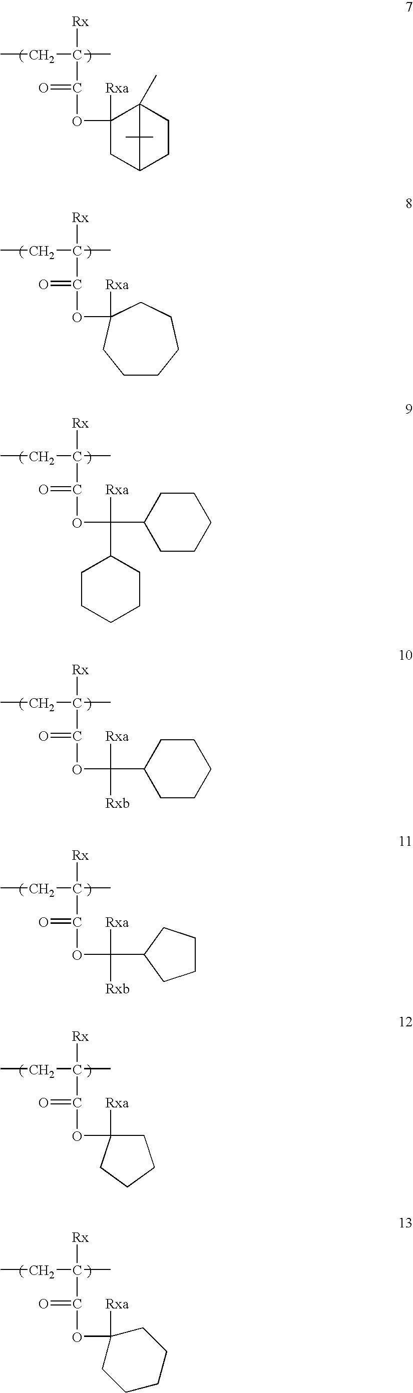

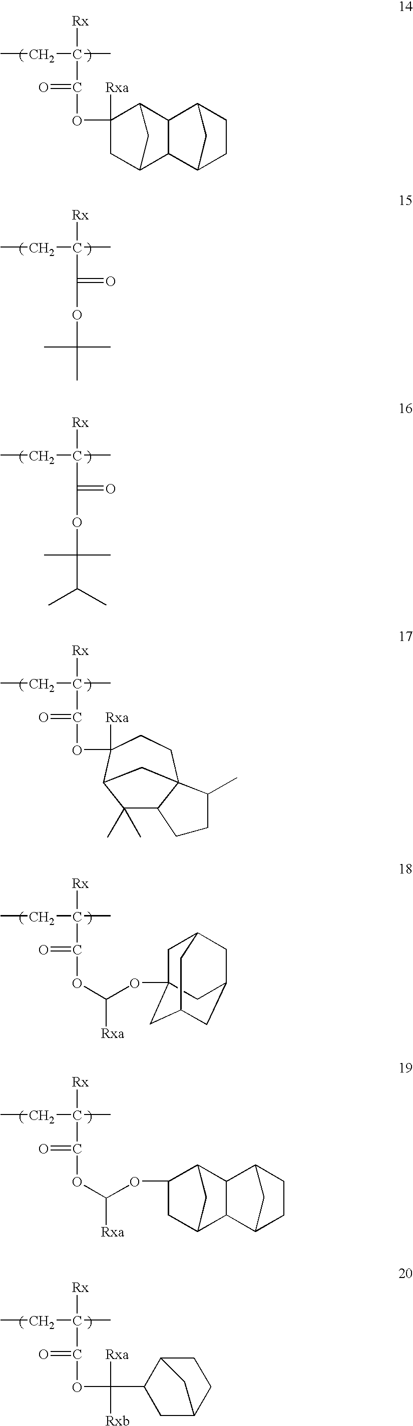

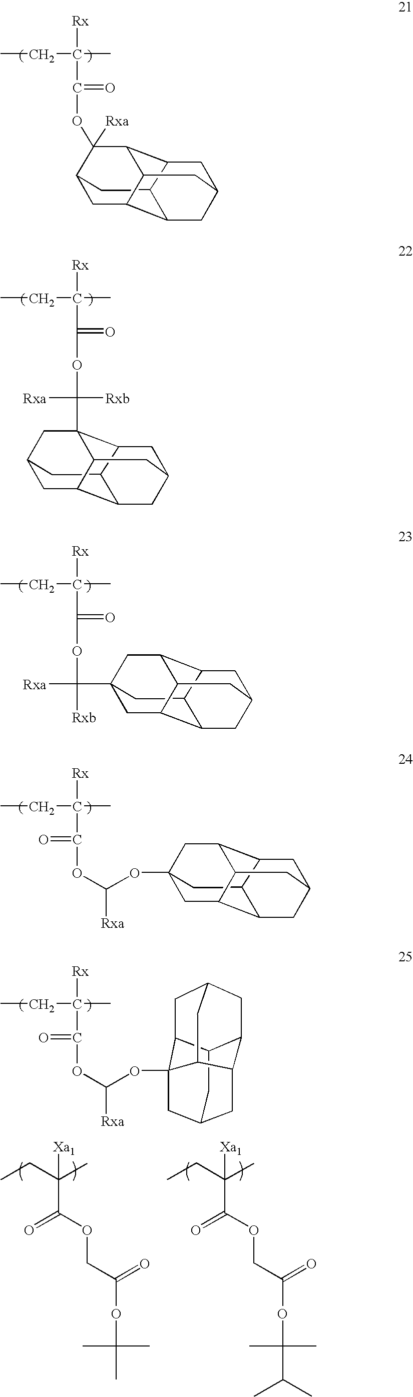

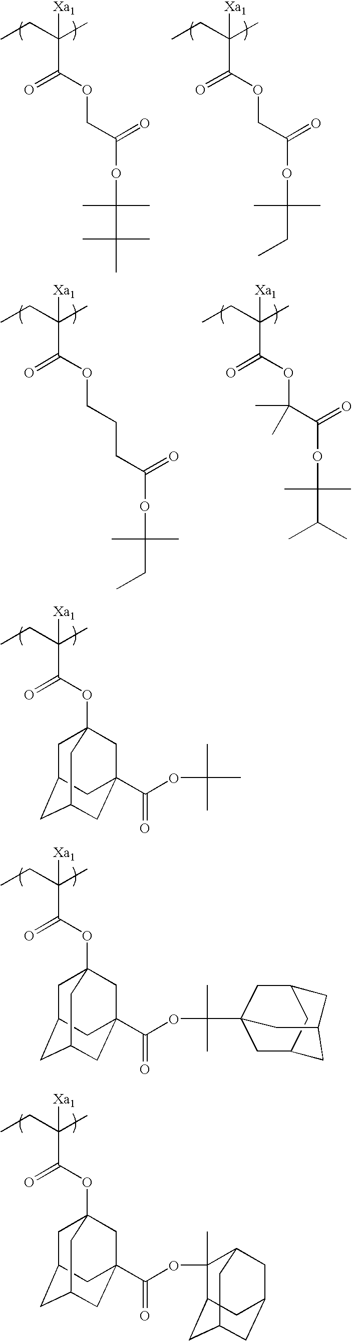

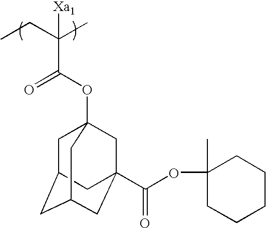

In the above formulae, Xa₁ has the same meaning as that of the general formula (AI).

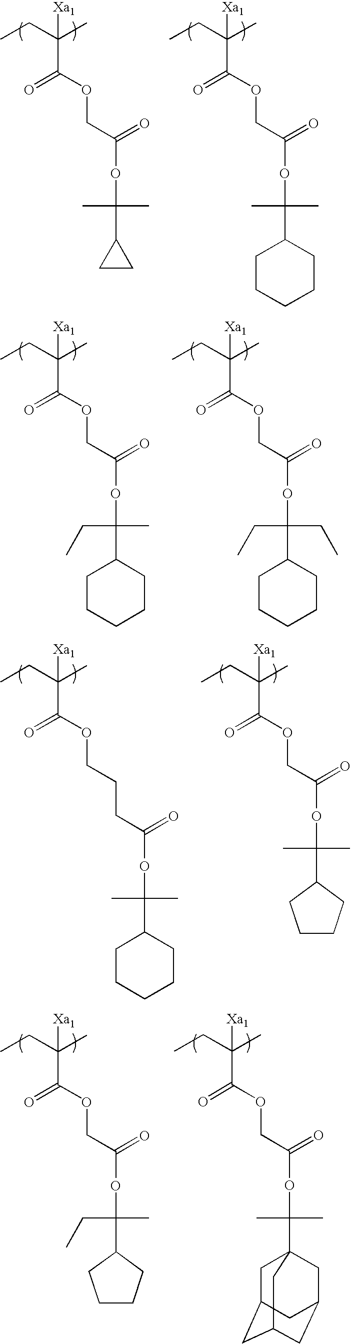

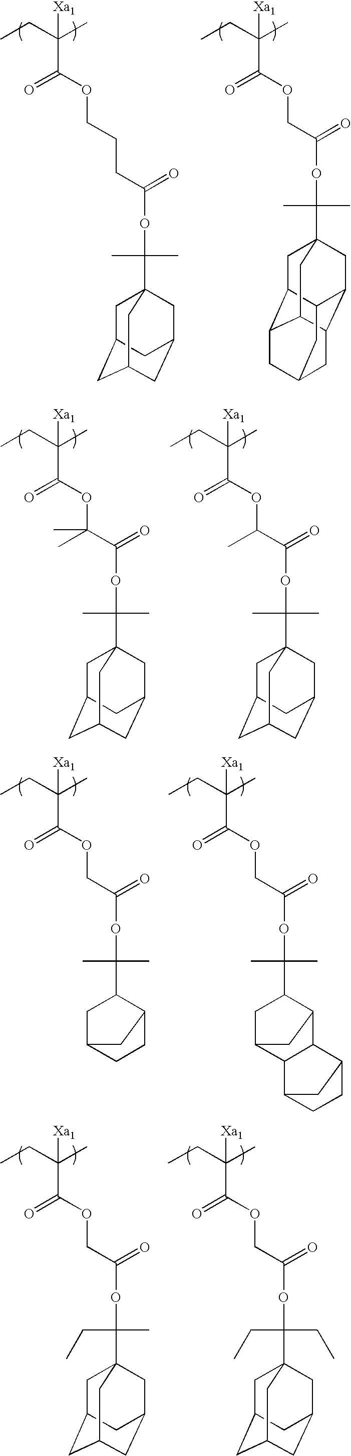

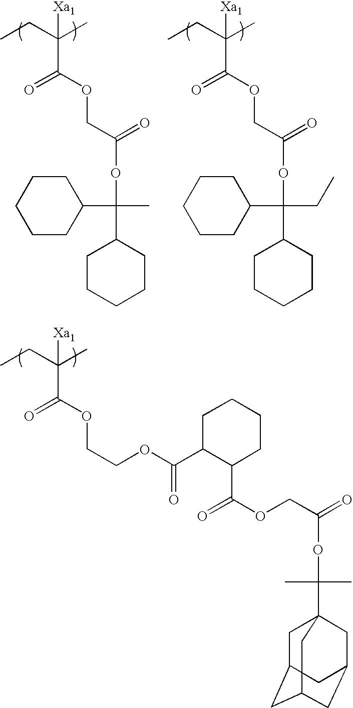

In the above formulae, Xa₁ has the same meaning as that of the general formula (AI).

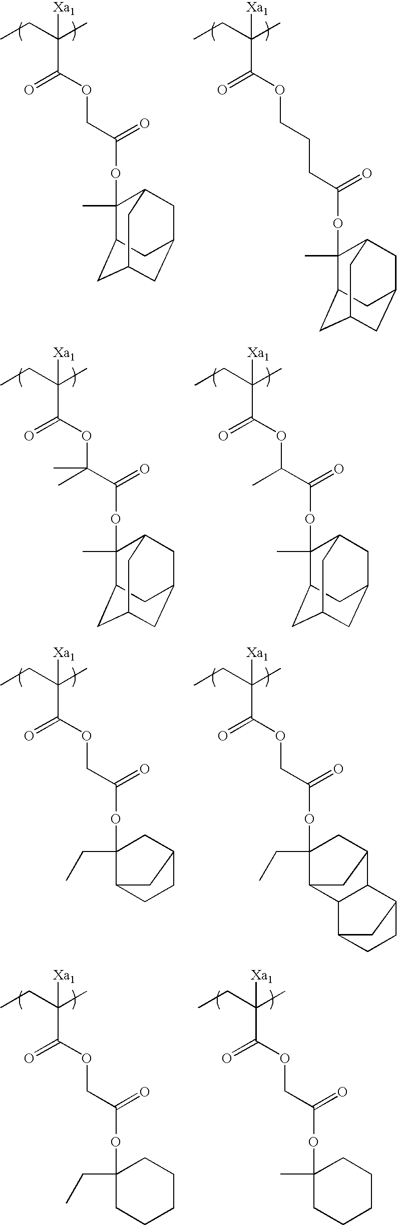

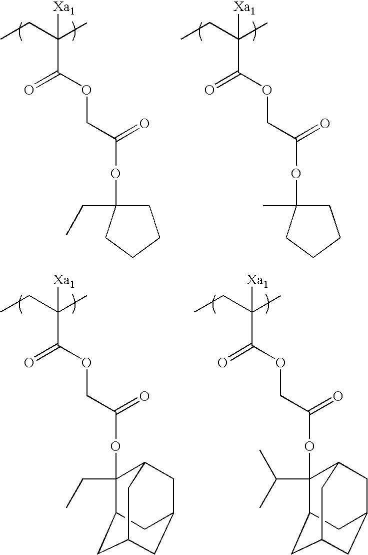

In the above formulae, Xa₁ has the same meaning as that of the general formula (AI).

It is preferred that the resin (A) further have a repeating unit having at least one group selected from among a lactone group, a hydroxyl group, a cyano group and an alkali soluble group.

The repeating unit having a lactone group that may preferably be contained in the resin (A) will now be described.

Any lactone groups can be employed as long as a lactone structure is contained therein. However, lactone structures of 5 to 7-membered ring are preferred, and in particular, those resulting from condensation of lactone structures of 5 to 7-membered ring with other cyclic structures effected in a fashion to form a bicyclo structure or spiro structure are preferred. The possession of the repeating unit having the lactone structure represented by any of the following general formulae (LC1-1) to (LC1-16) is more preferred. The lactone structures may be directly bonded to the principal chain. Preferred lactone structures are those of the formulae (LC1-1), (LC1-4), (LC1-5), (LC1-6), (LC1-13) and (LC1-14). The use of these specified lactone structures would ensure improvement in line edge roughness and development defect.

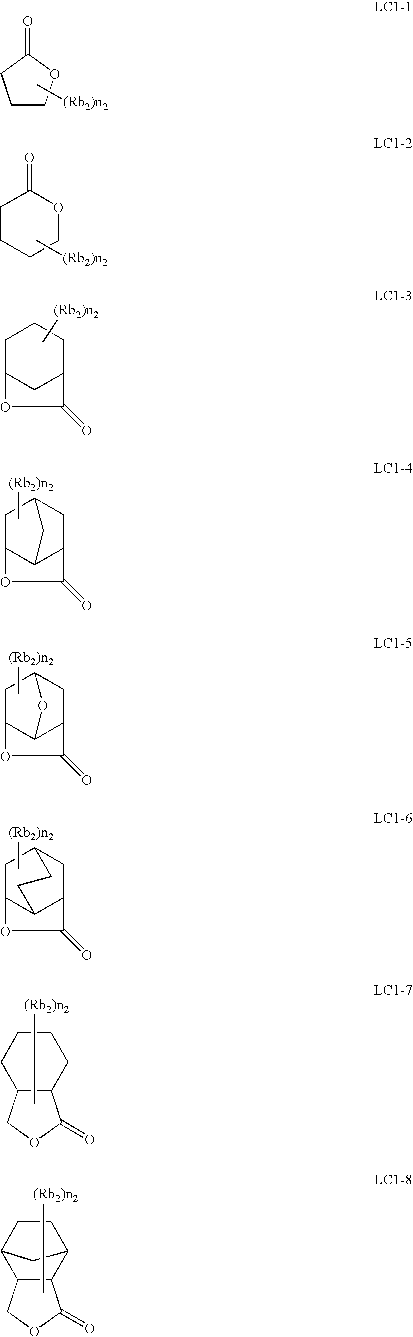

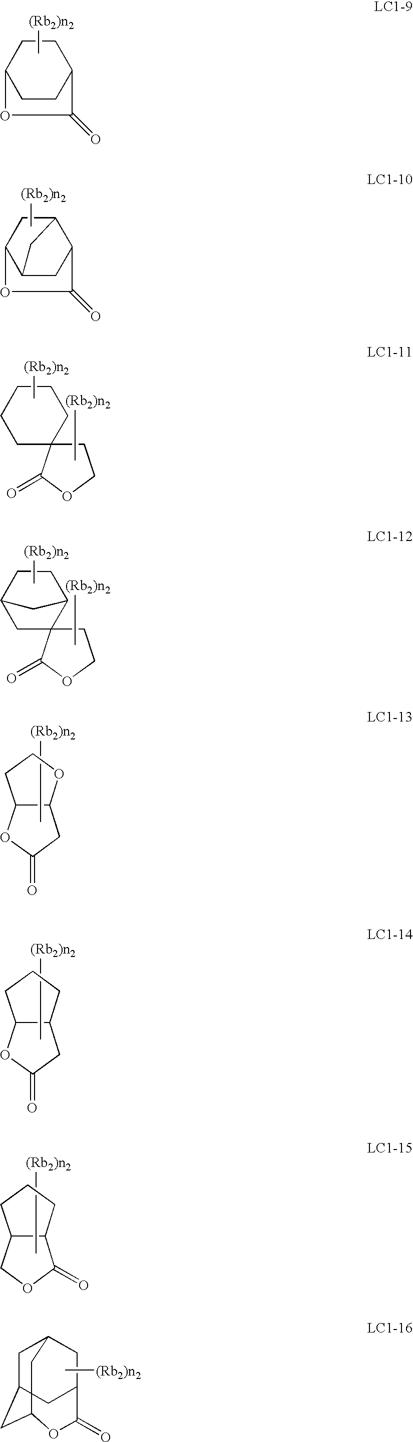

The inclusion of a substituent (Rb₂) on the portion of the lactone structure is optional. As a preferred substituent (Rb₂), there can be mentioned an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, an acid-decomposable group or the like. Of these, an alkyl group having 1 to 4 carbon atoms, a cyano group and an acid-decomposable group are more preferred. In the formulae, n₂ is an integer of 0 to 4. When n₂ is 2 or greater, the plurally present substituents (Rb₂) may be identical with or different from each other. Further, the plurally present substituents (Rb₂) may be bonded with each other to thereby form a ring.

As the repeating unit with lactone structure represented by any of the general formulae (LC1-1) to (LC1-16), there can be mentioned the repeating units represented by the following general formula (AI).

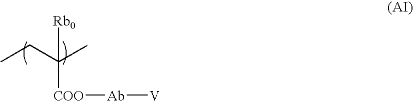

In the general formula (AI),

Rb₀ represents a hydrogen atom, a halogen atom or an alkyl group having 1 to 4 carbon atoms. As a preferred substituent optionally included in the alkyl group represented by Rb₀, there can be mentioned a hydroxyl group or a halogen atom. As the halogen atom represented by Rb₀, there can be mentioned a fluorine atom, a chlorine atom, a bromine atom or an iodine atom. The Rb₀ is preferably a hydrogen atom or a methyl group.

Ab represents a single bond, an alkylene group, a bivalent connecting group with an alicyclic hydrocarbon structure of a single ring or multiple rings, an ether group, an ester group, a carbonyl group, or a bivalent connecting group resulting from a combination thereof. A single bond and a bivalent connecting group of the formula -Ab₁-CO₂— are preferred. Ab₁ is a linear or branched alkylene group or a cycloalkylene group of a single ring or multiple rings, being preferably a methylene group, an ethylene group, a cyclohexylene group, an adamantylene group or a norbornylene group.

V represents a group with a structure represented by any of the general formulae (LC1-1) to (LC1-16).

The repeating unit having a lactone group is generally present in the form of optical isomers. Any optical isomer may be used. It is both appropriate to use a single type of optical isomer alone or a plurality of optical isomers in the form of a mixture. When a single type of optical isomer is mainly used, the optical purity (ee) thereof is preferably 90 or higher, more preferably 95 or higher.

The content of the repeating unit having a lactone group based on all the repeating units of the resin (A) is preferably in the range of 15 to 60 mol %, more preferably 20 to 50 mol % and still more preferably 30 to 50 mol %.

Examples of the repeating units having a lactone group will now be shown, which however in no way limit the scope of the present invention. In the formulae, Rx represents H, CH₃, CH₂OH or CF₃.

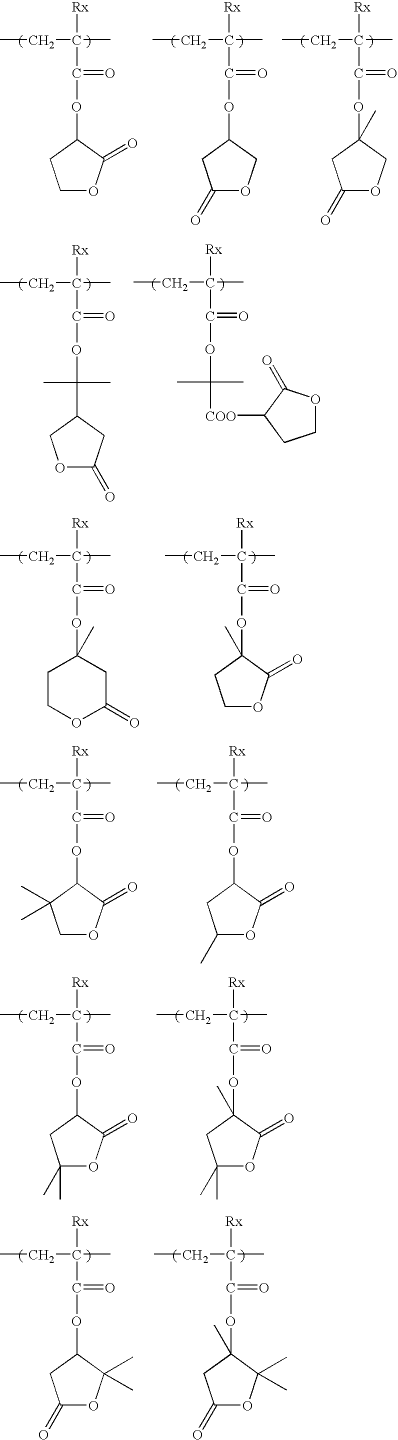

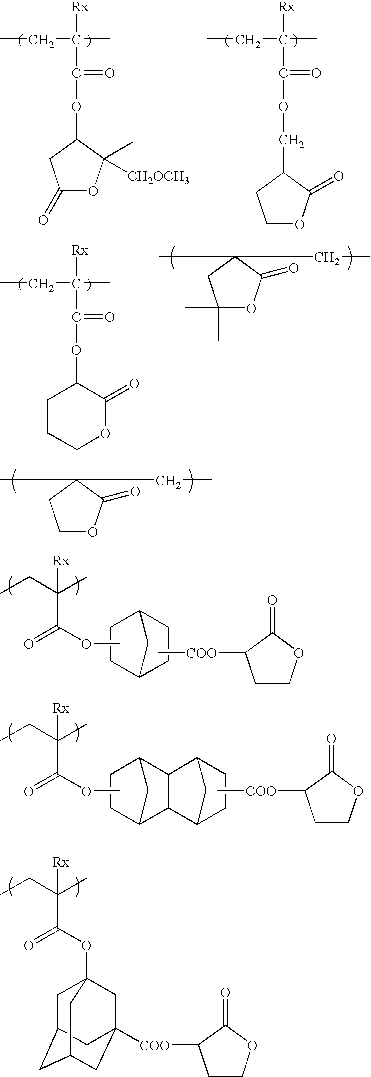

In the formulae, Rx represents H, CH₃, CH₂OH or CF₃.

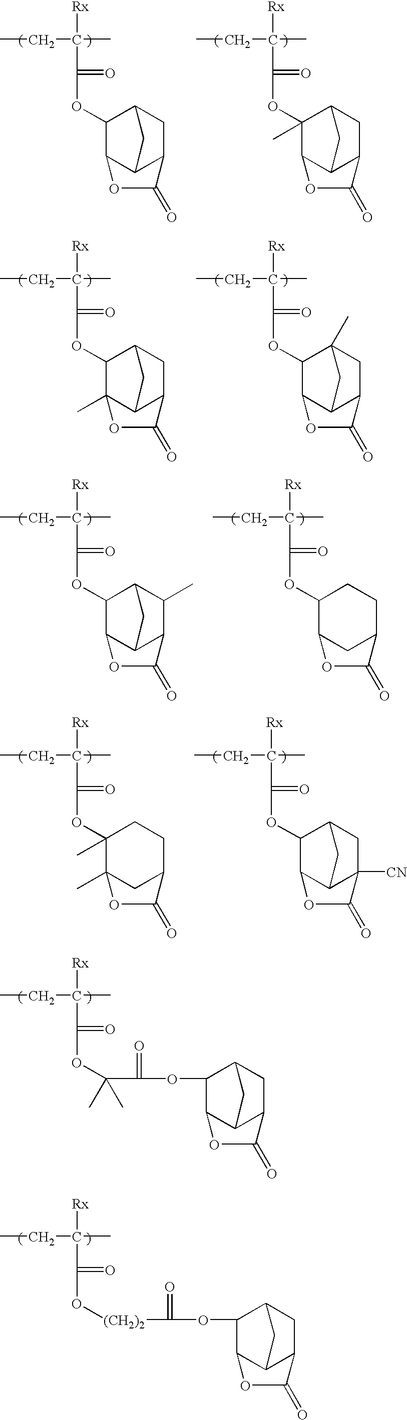

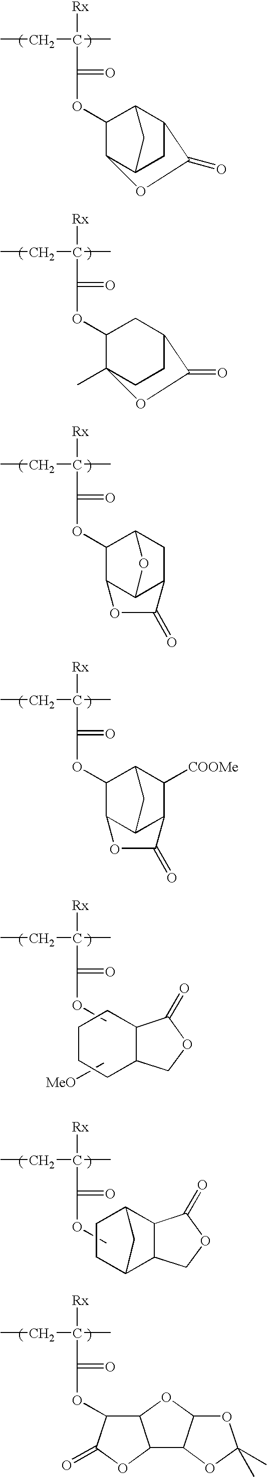

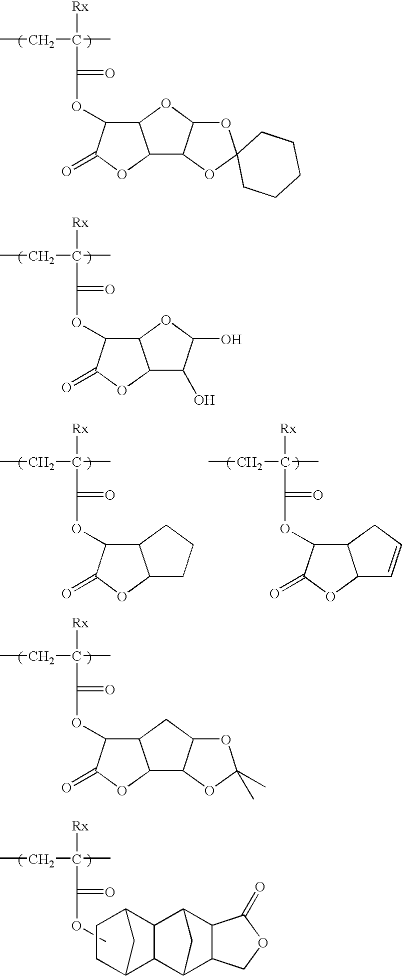

In the formulae, Rx represents H, CH₃, CH₂OH or CF₃.

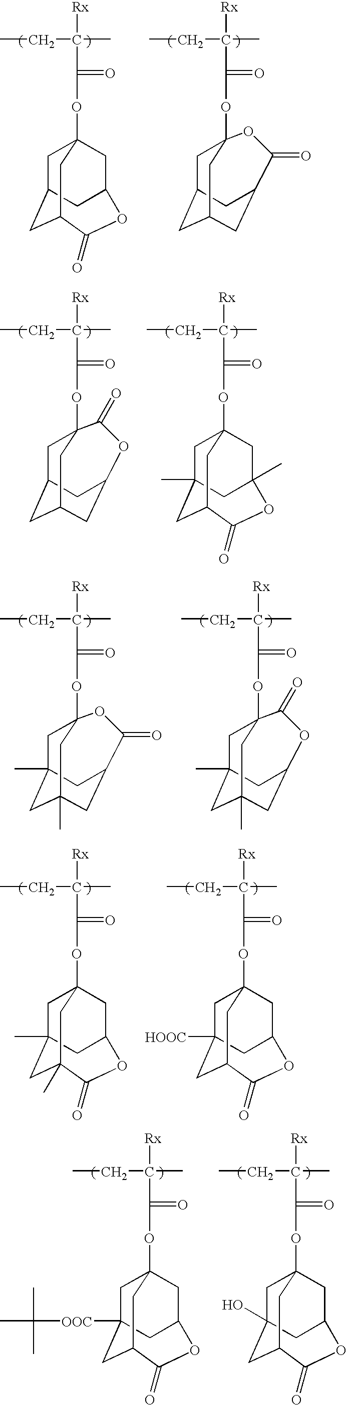

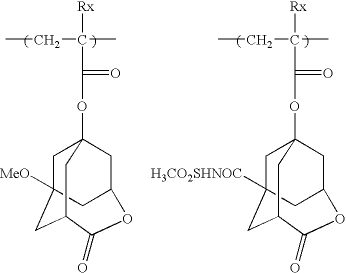

In the formulae, R represents H, CH₃, CH₂OH or CF₃.

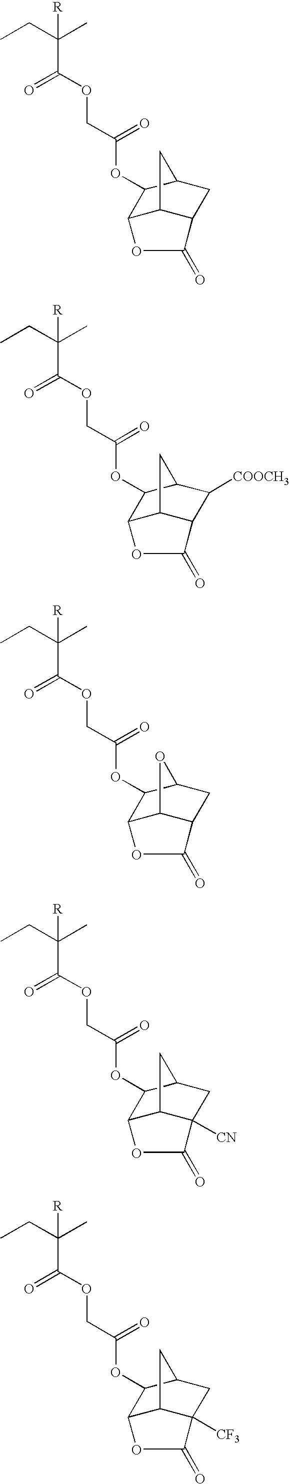

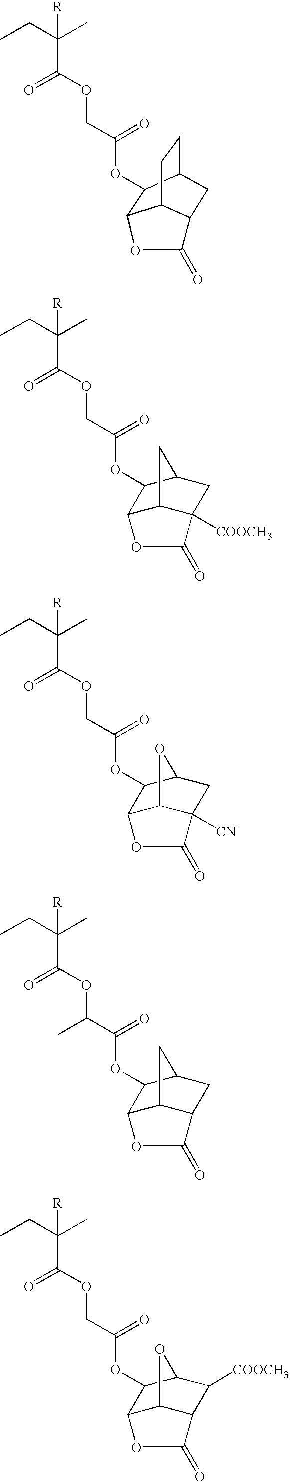

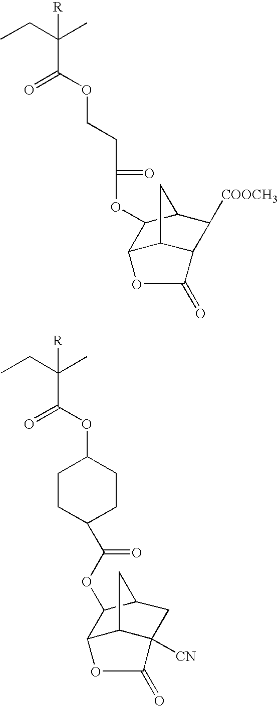

The especially preferred repeating units having a lactone group will be shown below. An improvement in pattern profile and optical density dependence can be attained by selection of the most appropriate lactone group.

In the formulae, Rx represents H, CH₃, CH₂OH or CF₃.

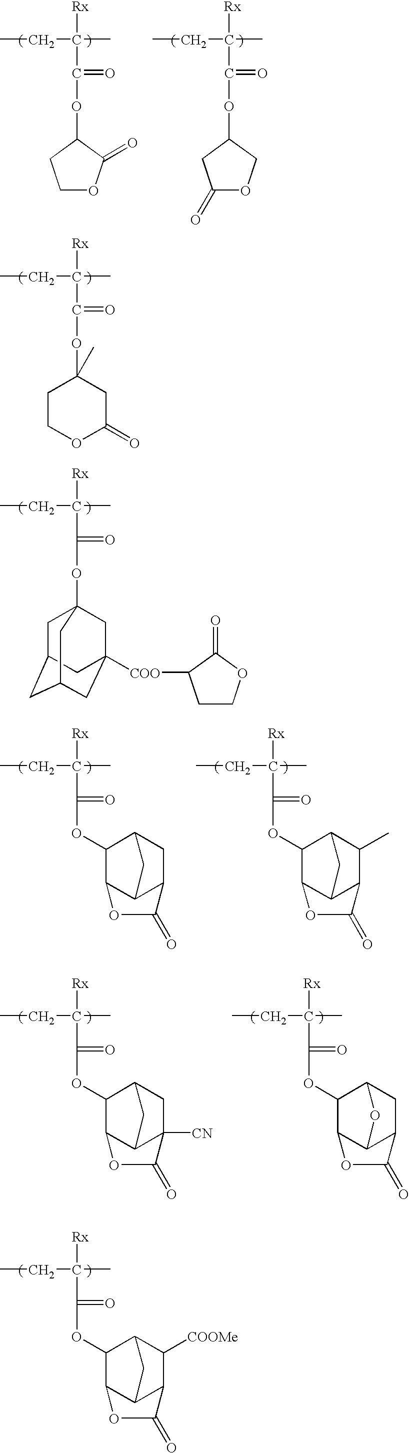

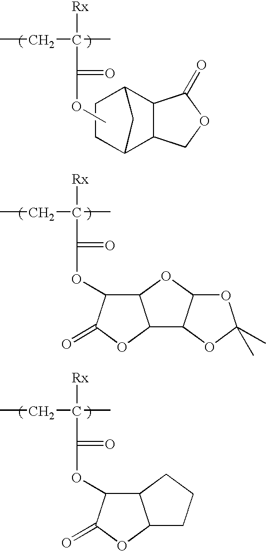

The repeating unit having a hydroxyl group or a cyano group that can be preferably contained in the resin (A) will now be described. The inclusion of this repeating unit in the resin (A) would realize enhancements of adhesion to substrate and developer affinity. The repeating unit having a hydroxyl group or a cyano group is preferably a repeating unit having an alicyclic hydrocarbon structure substituted with a hydroxyl group or a cyano group. In the alicyclic hydrocarbon structure substituted with a hydroxyl group or a cyano group, the alicyclic hydrocarbon structure preferably consists of an adamantyl group, a diamantyl group or a norbornane group. As preferred alicyclic hydrocarbon structures substituted with a hydroxyl group or a cyano group, there can be mentioned partial structures of the following general formulae (VIIa) to (VIId).

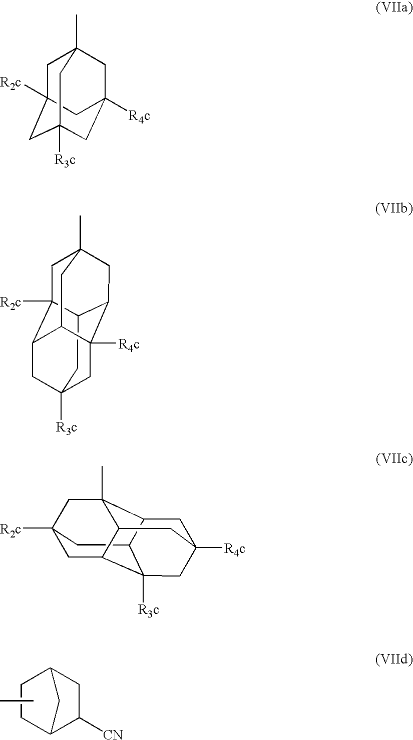

In the general formulae (VIIa) to (VIIc),

each of R₂c to R₄c independently represents a hydrogen atom, a hydroxyl group or a cyano group, provided that at least one of the R₂c to R₄c represents a hydroxyl group or a cyano group. Preferably, one or two of the R₂c to R₄c are hydroxyl groups and the remainder is a hydrogen atom. In the general formula (VIIa), more preferably, two of the R₂c to R₄c are hydroxyl groups and the remainder is a hydrogen atom.

As repeating units having any of the partial structures of the formulae (VIIa) to (VIId), there can be mentioned those of the following general formulae (AIIa) to (AIId).

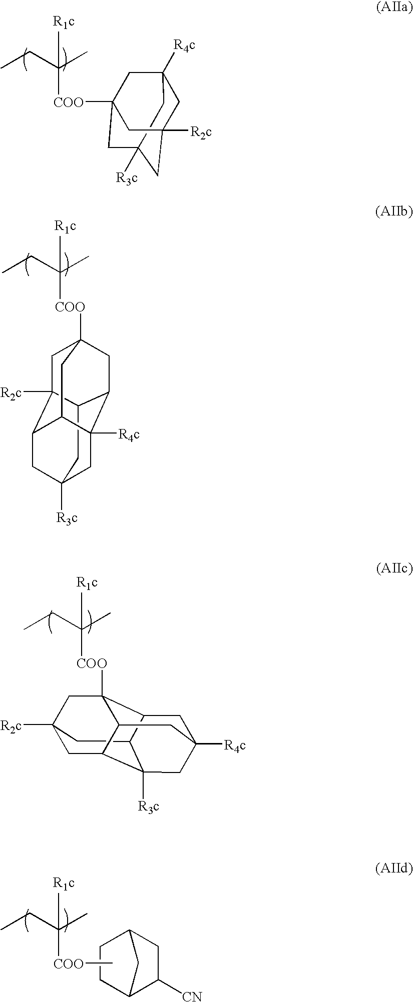

In the general formulae (AIIa) to (AIId),

R₁c represents a hydrogen atom, a methyl group, a trifluoromethyl group or a hydroxymethyl group.

R₂c to R₄c have the same meaning as those of the general formulae (VIIa) to (VIIc).

The content of any of the repeating units having an alicyclic hydrocarbon structure substituted with a hydroxyl group or a cyano group, based on all the repeating units of the resin (A), is preferably in the range of 5 to 40 mol %, more preferably 5 to 30 mol % and still more preferably 10 to 25 mol %.

Specific examples of the repeating units having a hydroxyl group or a cyano group will be shown below, which however in no way limit the scope of the present invention.

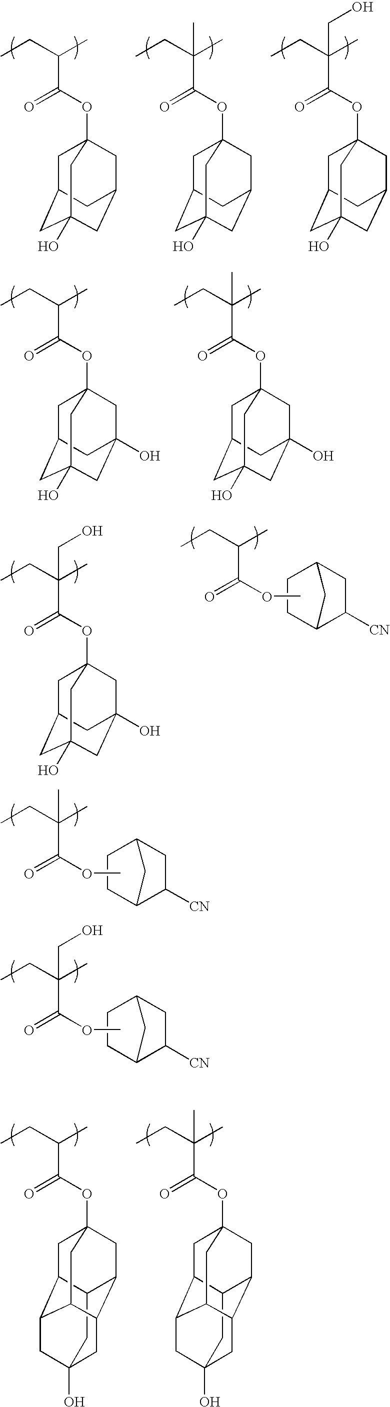

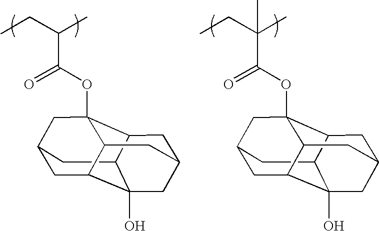

The repeating unit having an alkali-soluble group that can be preferably contained in the resin (A) will now be described. As the alkali-soluble group, there can be mentioned a carboxyl group, a sulfonamido group, a sulfonylimido group, a bisulfonylimido group or an aliphatic alcohol substituted at its α-position with an electron-withdrawing group (for example, a hexafluoroisopropanol group). The inclusion of a repeating unit having a carboxyl group is more preferred. The incorporation of the repeating unit having an alkali-soluble group would increase the resolving power in contact hole usage. The repeating unit having an alkali-soluble group is preferably any of a repeating unit wherein the alkali-soluble group is directly bonded to a principal chain of a resin, such as repeating units of an acrylic acid or methacrylic acid, a repeating unit wherein the alkali-soluble group is bonded via a connecting group to the principal chain of a resin and a repeating unit wherein the alkali-soluble group is introduced in a terminal of a polymer chain by the use of a chain transfer agent or polymerization initiator having the alkali-soluble group in the stage of polymerization. The connecting group may have a cyclohydrocarbon structure of a single ring or multiple rings. The use of a repeating unit of acrylic acid or methacrylic acid is especially preferred.

The content of the repeating unit having an alkali-soluble group based on all the repeating units of the resin (A) is preferably in the range of 0 to 20 mol %, more preferably 3 to 15 mol % and still more preferably 5 to 10 mol %.

Specific examples of the repeating units having the alkali-soluble group will be shown below, which however in no way limit the scope of the present invention.

In the formulae, Rx represents H, CH₃, CF₃, or CH₂OH.

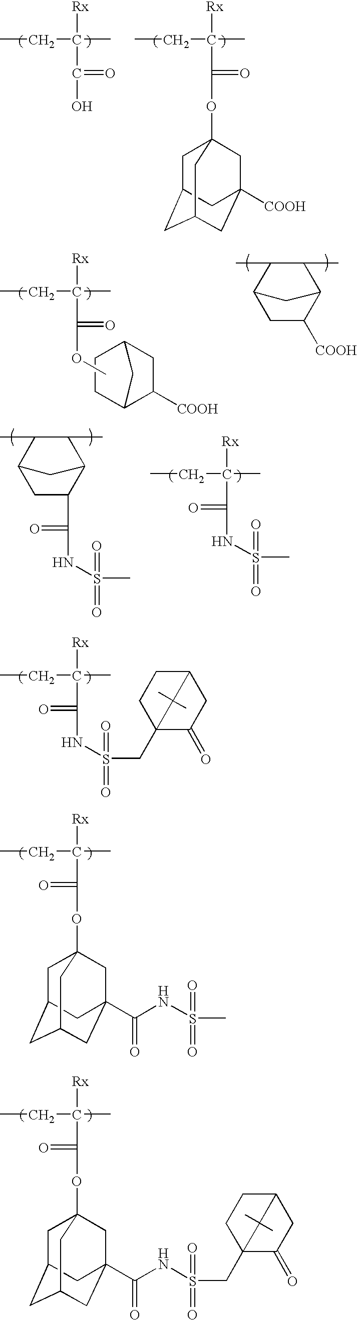

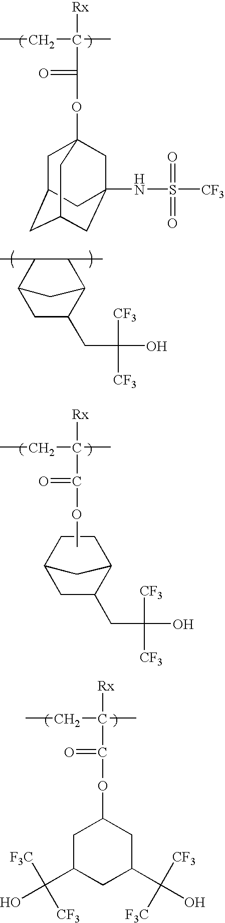

The resin (A) may further have a repeating unit having an alicyclic hydrocarbon structure and not exhibiting any acid decomposability. This would reduce any leaching of low-molecular components from a resist film into a liquid for liquid immersion at the time of liquid immersion exposure, being also advantageous from the viewpoint of dry etching resistance. As specific examples thereof, there can be mentioned repeating units of the following general formula (III).

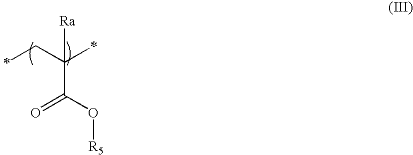

In the general formula (III), R₅ represents a hydrocarbon group having at least one cyclic structure in which neither a hydroxyl group nor a cyano group is contained.

Ra represents a hydrogen atom, an alkyl group or a group of the formula —CH₂—O—Ra₂ in which Ra₂ represents a hydrogen atom, an alkyl group or an acyl group. As the Ra group, there can be mentioned, for example, a hydrogen atom, a methyl group, a hydroxymethyl group, a trifluoromethyl group or the like.

The cyclic structures included in R₅ include a monocyclic hydrocarbon group and a polycyclic hydrocarbon group. As the monocyclic hydrocarbon group, there can be mentioned, for example, a cycloalkyl group having 3 to 12 carbon atoms, such as a cyclopentyl group, a cyclohexyl group, a cycloheptyl group or a cyclooctyl group, or a cycloalkenyl group having 3 to 12 carbon atoms, such as a cyclohexenyl group. Preferably, the monocyclic hydrocarbon group is a monocyclic hydrocarbon group having 3 to 7 carbon atoms. A cyclopentyl group and a cyclohexyl group are more preferred.

The polycyclic hydrocarbon groups include ring-assembly hydrocarbon groups and crosslinked-ring hydrocarbon groups. Examples of the ring-assembly hydrocarbon groups include a bicyclohexyl group, a perhydronaphthalene group and the like. As crosslinked-ring hydrocarbon rings, there can be mentioned, for example, bicyclic hydrocarbon rings, such as pinane, bornane, norpinane, norbornane and bicyclooctane rings (e.g., bicyclo[2.2.2]octane ring or bicyclo[3.2.1]octane ring); tricyclic hydrocarbon rings, such as homobledane, adamantane, tricyclo[5.2.1.0^{2,6}]decane and tricyclo[4.3.1.1^{2,5}]undecane rings; and tetracyclic hydrocarbon rings, such as tetracyclo[4.4.0.1^{2,5}.1^{7,10}]dodecane and perhydro-1,4-methano-5,8-methanonaphthalene rings. Further, the crosslinked-ring hydrocarbon rings include condensed-ring hydrocarbon rings, for example, condensed rings resulting from condensation of multiple 5- to 8-membered cycloalkanes, such as perhydronaphthalene (decalin), perhydroanthracene, perhydrophenanthrene, perhydroacenaphthene, perhydrofluorene, perhydroindene and perhydrophenarene rings.

As preferred crosslinked-ring hydrocarbon rings, there can be mentioned, for example, a norbornyl group, an adamantyl group, a bicyclooctanyl group and a tricyclo[5,2,1,0^{2,6}]decanyl group. As more preferred crosslinked-ring hydrocarbon rings, there can be mentioned a norbornyl group and an adamantyl group.

These alicyclic hydrocarbon groups may have substituents. As preferred substituents, there can be mentioned, for example, a halogen atom, an alkyl group, a hydroxyl group protected by a protective group and an amino group protected by a protective group. The halogen atom is preferably a bromine, chlorine or fluorine atom, and the alkyl group is preferably a methyl, ethyl, butyl or t-butyl group. The alkyl group may further have a substituent. As the optionally included further substituent, there can be mentioned a halogen atom, an alkyl group, a hydroxyl group protected by a protective group or an amino group protected by a protective group.

As the protective group, there can be mentioned, for example, an alkyl group, a cycloalkyl group, an aralkyl group, a substituted methyl group, a substituted ethyl group, an alkoxycarbonyl group or an aralkyloxycarbonyl group. Preferred alkyl groups include alkyl groups having 1 to 4 carbon atoms. Preferred substituted methyl groups include methoxymethyl, methoxythiomethyl, benzyloxymethyl, t-butoxymethyl and 2-methoxyethoxymethyl groups. Preferred substituted ethyl groups include 1-ethoxyethyl and 1-methyl-1-methoxyethyl groups. Preferred acyl groups include aliphatic acyl groups having 1 to 6 carbon atoms, such as formyl, acetyl, propionyl, butyryl, isobutyryl, valeryl and pivaloyl groups. Preferred alkoxycarbonyl groups include alkoxycarbonyl groups having 1 to 4 carbon atoms and the like.

The content of any of repeating units of the general formula (III) having neither a hydroxyl group nor a cyano group, based on all the repeating units of the resin (A), is preferably in the range of 0 to 40 mol %, more preferably 0 to 20 mol %.

Specific examples of the repeating units of the general formula (III) will be shown below, which however in no way limit the scope of the present invention. In the formulae, Ra represents H, CH₃, CH₂OH, or CF₃.

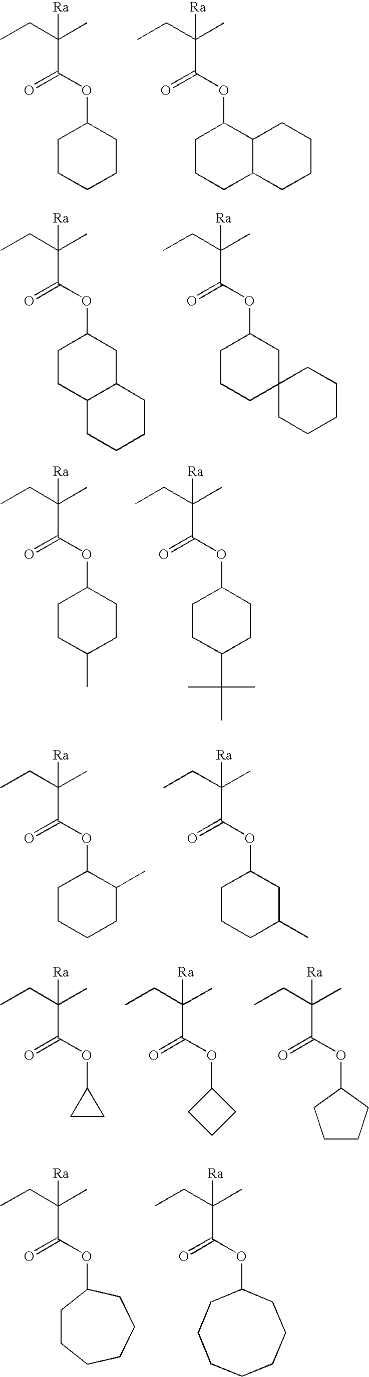

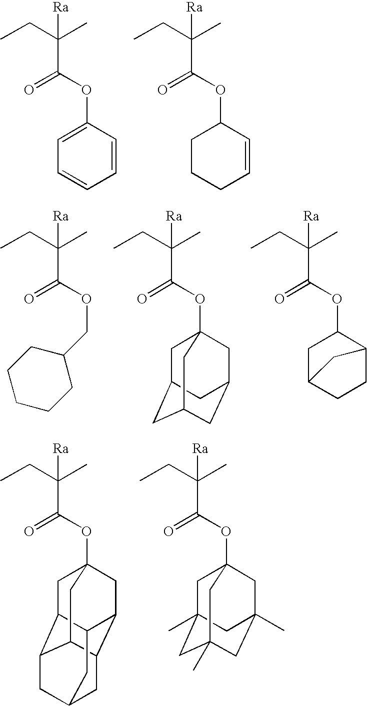

The resin (A) may have, in addition to the foregoing repeating structural units, various repeating structural units for the purpose of regulating the dry etching resistance, standard developer adaptability, substrate adhesion, resist profile and generally required properties of resists such as resolving power, heat resistance and sensitivity.

As such repeating structural units, there can be mentioned those corresponding to the following monomers, which however are nonlimiting.

Such repeating structural units would permit fine regulation of the properties required to have by the resin (A), especially:

(1) solubility in applied solvents,

(2) film forming easiness (glass transition temperature),

(3) alkali developability,

(4) film thinning (selection of hydrophilicity/hydrophobicity and alkali-soluble group),

(5) adhesion of unexposed area to substrate,

(6) dry etching resistance, etc.

As appropriate monomers, there can be mentioned, for example, a compound having an unsaturated bond capable of addition polymerization, selected from among acrylic esters, methacrylic esters, acrylamides, methacrylamides, allyl compounds, vinyl ethers, vinyl esters and the like.

In addition, any unsaturated compound capable of addition polymerization that is copolymerizable with monomers corresponding to the above various repeating structural units may be one that is copolymerized.

The molar ratios of individual repeating structural units contained in the resin (A) are appropriately determined from the viewpoint of regulation of not only resist dry etching resistance but also standard developer adaptability, substrate adhesion, resist profile and generally required properties of resists such as resolving power, heat resistance and sensitivity.

When the positive resist composition for use in the present invention is one for ArF exposure, it is preferred that the resin (A) have no aromatic group from the viewpoint of transparency to ArF beams.

In the resin (A), preferably, all the repeating units consist of (meth)acrylate repeating units. If this is so, use can be made of any of a resin wherein all the repeating units consist of methacrylate repeating units, a resin wherein all the repeating units consist of acrylate repeating units and a resin wherein all the repeating units consist of methacrylate repeating units and acrylate repeating units. However, it is preferred that acrylate repeating units account for 50 mol % or less of all the repeating units. It is more preferred to employ a copolymer containing 20 to 50 mol % of (meth)acrylate repeating units having an acid-decomposable group represented by the general formula (AI), 20 to 50 mol % of (meth)acrylate repeating units having a lactone group, 5 to 30 mol % of (meth)acrylate repeating units having an alicyclic hydrocarbon structure substituted with a hydroxyl group or a cyano group, 0 to 20 mol % of any of the repeating units of the general formula (III) and 0 to 20 mol % of other (meth)acrylate repeating units.

In the event of exposure of the positive resist composition for use in the present invention to KrF excimer laser beams, electron beams, X-rays or high-energy light rays of 50 nm or less wavelength (EUV, etc.), it is preferred that the resin (A) have not only the repeating units of the general formula (AI) but also hydroxystyrene repeating units. More preferably, the resin (A) has hydroxystyrene repeating units, hydroxystyrene repeating units protected by an acid-decomposable group and acid-decomposable repeating units of a (meth)acrylic acid tertiary alkyl ester, etc.

As preferred repeating units having an acid-decomposable group, there can be mentioned, for example, repeating units derived from t-butoxycarbonyloxystyrene, a 1-alkoxyethoxystyrene and a (meth)acrylic acid tertiary alkyl ester. Repeating units derived from a 2-alkyl-2-adamantyl (meth)acrylate and a dialkyl(1-adamantyl)methyl (meth)acrylate are more preferred.

The resin (A) can be synthesized by customary techniques (for example, radical polymerization). As customary synthetic methods, there can be mentioned, for example, a batch polymerization method in which a monomer species and an initiator are dissolved in a solvent and heated so as to accomplish polymerization, and a dropping polymerization method in which a solution of monomer species and initiator is added by dropping to a heated solvent over a period of 1 to 10 hours. The dropping polymerization method is preferred. As a reaction solvent, there can be mentioned, for example, an ether, such as tetrahydrofuran, 1,4-dioxane or diisopropyl ether; a ketone, such as methyl ethyl ketone or methyl isobutyl ketone; an ester solvent, such as ethyl acetate; an amide solvent, such as dimethylformamide or dimethylacetamide; or a later described solvent capable of dissolving the composition for use in the present invention, such as propylene glycol monomethyl ether acetate, propylene glycol monomethyl ether or cyclohexanone. It is preferred that the polymerization be performed with the use of the same solvent as employed in the positive resist composition for use in the present invention. This would inhibit any particle generation during storage.

The polymerization reaction is preferably carried out in an atmosphere of an inert gas, such as nitrogen or argon. The polymerization is initiated by the use of commercially available radical initiator (azo initiator, peroxide, etc.) as a polymerization initiator. Among radical initiators, an azo initiator is preferred. An azo initiator having an ester group, a cyano group or a carboxyl group is especially preferred. As preferred initiators, there can be mentioned azobisisobutyronitrile, azobisdimethylvaleronitrile, dimethyl 2,2′-azobis(2-methylpropionate) and the like. According to necessity, supplementation of an initiator or divided addition thereof may be effected. After the completion of reaction, the reaction mixture is poured into a solvent. The desired polymer is recovered according to a method for powder or solid recovery, etc. The concentration during the reaction is in the range of 5 to 50 mass %, preferably 10 to 30 mass %. The reaction temperature is generally in the range of 10° to 150° C., preferably 30° to 120° C. and more preferably 60° to 100° C.

After the completion of the reaction, the mixture is allowed to stand still to cool to room temperature and purified. In the purification, use is made of customary methods, such as a liquid-liquid extraction method in which residual monomers and oligomer components are removed by water washing or by the use of a combination of appropriate solvents, a method of purification in solution form such as ultrafiltration capable of extraction of only components of a given molecular weight or below, a re-precipitation method in which a resin solution is dropped into a poor solvent to thereby coagulate the resin in the poor solvent and thus remove residual monomers, etc., and a method of purification in solid form such as washing of a resin slurry obtained by filtration with the use of a poor solvent. For example, the reaction solution is brought into contact with a solvent wherein the resin is poorly soluble or insoluble (poor solvent) amounting to 10 or less, preferably 10 to 5 times the volume of the reaction solution to thereby precipitate the resin as a solid.

The solvent for use in the operation of precipitation or re-precipitation from a polymer solution (precipitation or re-precipitation solvent) is not limited as long as the solvent is a poor solvent for the polymer. Use can be made of any polymer appropriately selected from among a hydrocarbon, a halogenated hydrocarbon, a nitro compound, an ether, a ketone, an ester, a carbonate, an alcohol, a carboxylic acid, water, a mixed solvent containing these solvents and the like, according to the type of polymer. Of these, it is preferred to employ a solvent containing at least an alcohol (especially methanol or the like) or water as the precipitation or re-precipitation solvent.

The amount of precipitation or re-precipitation solvent used can be appropriately selected taking efficiency, yield, etc. into account, and is generally in the range of 100 to 10,000 parts by mass, preferably 200 to 2000 parts by mass and more preferably 300 to 1000 parts by mass per 100 parts by mass of the polymer solution.

The temperature at which the precipitation or re-precipitation is carried out can be appropriately selected taking efficiency and operation easiness into account, and is generally in the range of about 0° to 50° C., preferably about room temperature (for example, about 20° to 35° C.). The operation of precipitation or re-precipitation can be carried out by a publicly known method, such as a batch or continuous method, with the use of a customary mixing vessel, such as an agitation vessel.

The polymer obtained by precipitation or re-precipitation is generally subjected to customary solid/liquid separation, such as filtration or centrifugal separation, and dried before use. The filtration is carried out with the use of a filter medium ensuring solvent resistance, preferably under pressure. The drying is performed at about 30° to 100° C., preferably about 30° to 50° C. at ordinary pressure or reduced pressure (preferably reduced pressure).

Optionally, after the resin precipitation and separation, the resin may be once more dissolved in a solvent and brought into contact with a solvent, the resin being poorly soluble or insoluble. Specifically, the method may include the steps of, after the completion of the polymerization reaction, bringing the polymer into contact with a solvent wherein the polymer is poorly soluble or insoluble to thereby attain resin precipitation (step a), separating the resin from the solution (step b), re-dissolving the resin in a solvent to thereby obtain a resin solution (A) (step c), thereafter bringing the resin solution (A) into contact with a solvent wherein the resin is poorly soluble or insoluble amounting to less than 10 times (preferably 5 times or less) the volume of the resin solution (A) to thereby attain resin solid precipitation (step d) and separating the precipitated resin (step e).

The weight average molecular weight of the resin (A) in terms of polystyrene molecular weight as measured by GPC is preferably in the range of 1000 to 200,000, more preferably 2000 to 20,000, still more preferably 3000 to 15,000 and especially preferably 3000 to 10,000. The regulation of the weight average molecular weight to 1000 to 200,000 would prevent deterioration of heat resistance and dry etching resistance and also prevent deterioration of developability and increase of viscosity, which would otherwise lead to a poor film forming property.

Use is made of the resin whose degree of dispersal (molecular weight distribution) is generally in the range of 1 to 3, preferably 1 to 2.6, more preferably 1 to 2 and especially preferably 1.4 to 1.7. The smaller the molecular weight distribution, the better the resolving power and resist profile and the smoother the side wall of the resist pattern, resulting in a better roughness.

In the positive resist composition for use in the present invention, the ratio of the resin (A) to the whole composition is preferably in the range of 50 to 99.99 mass %, more preferably 60 to 99.0 mass %, based on the total solid content.

In the present invention, the resins (A) may be used either individually or in combination.

Specific examples of the polymers that can be employed in the present invention will be shown below, which however in no way limit the scope of the present invention.

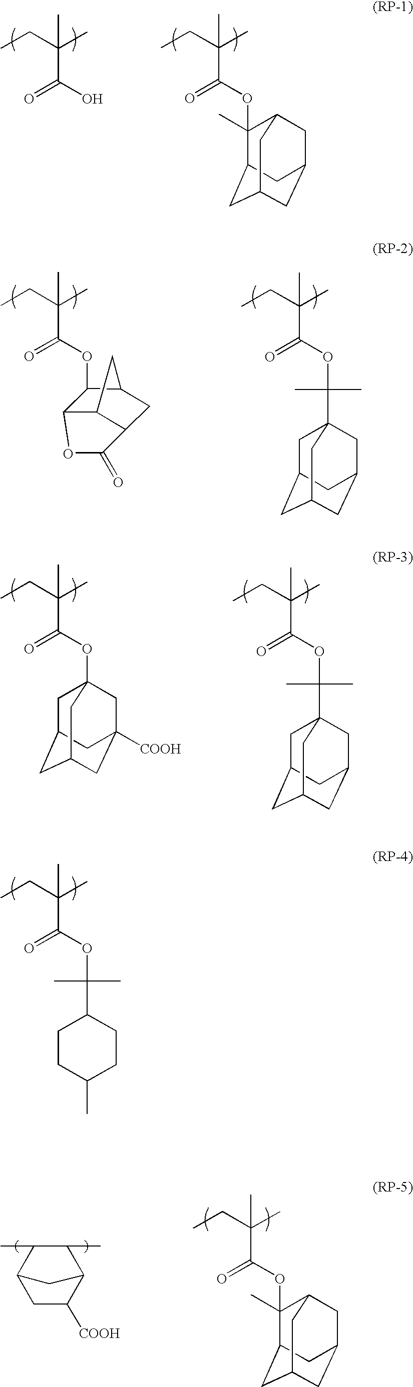

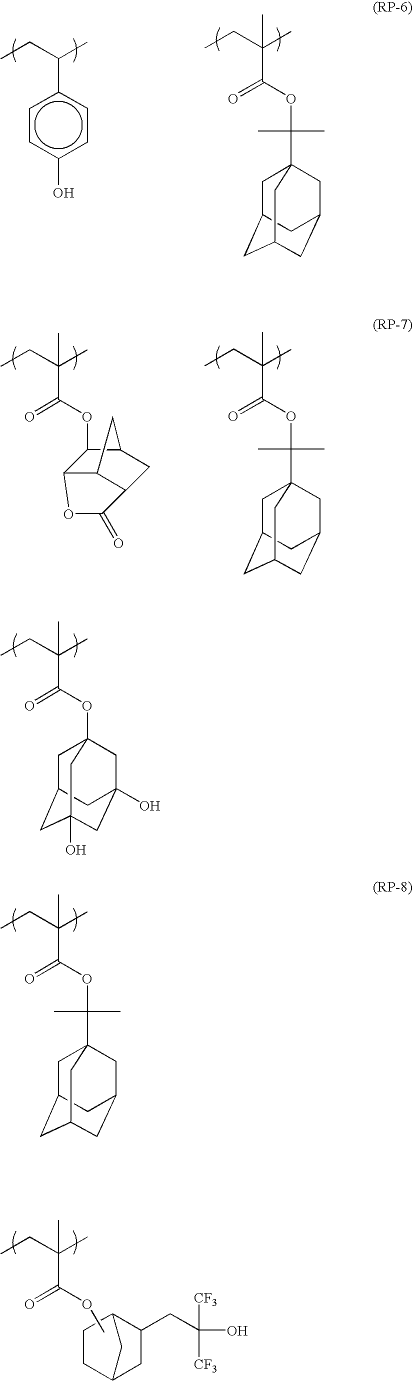

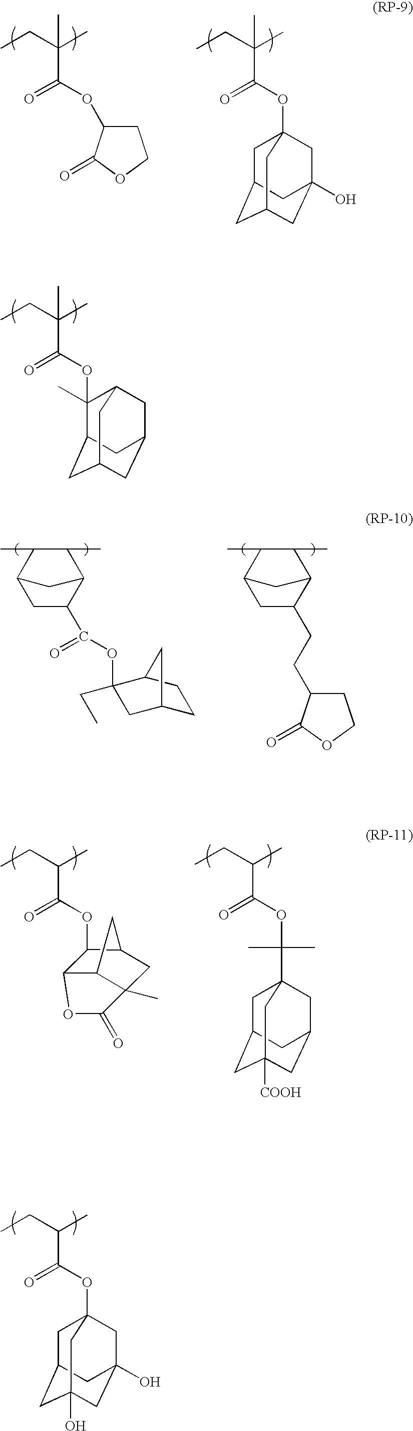

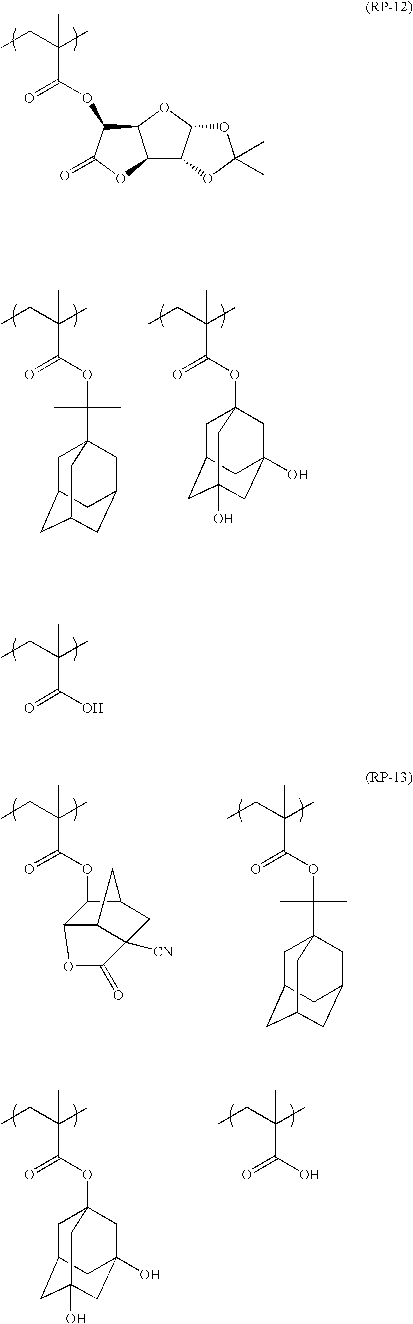

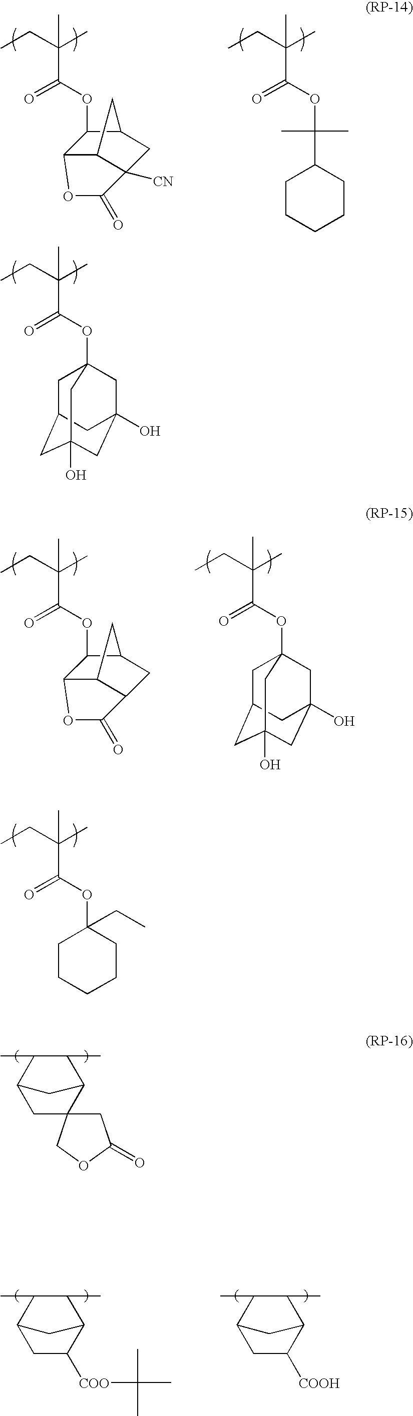

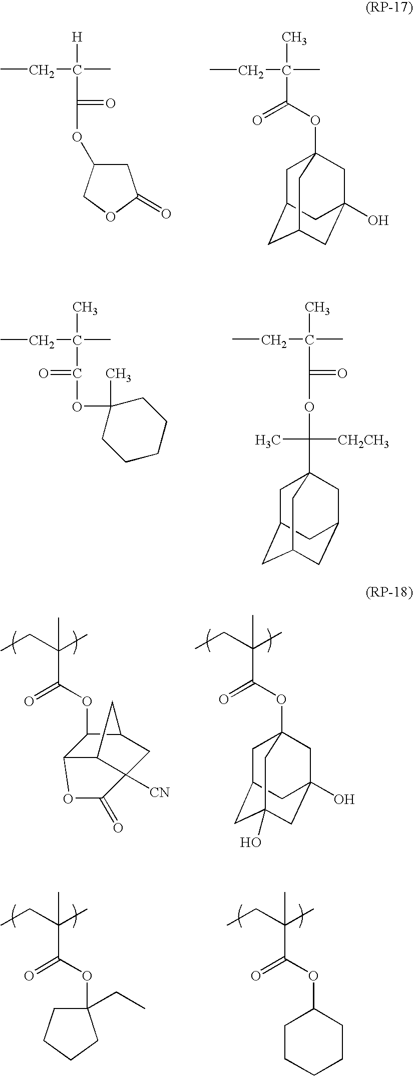

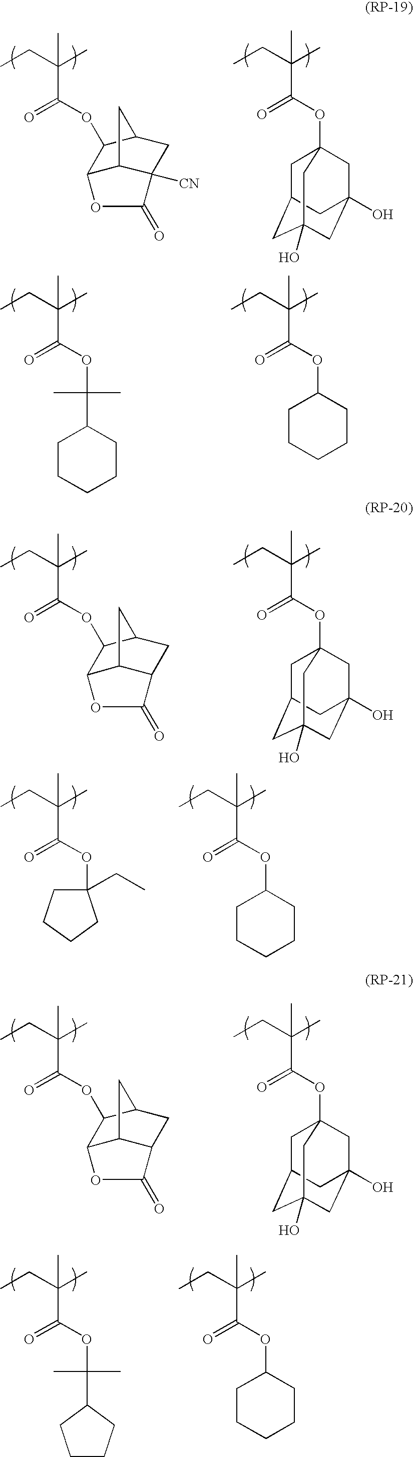

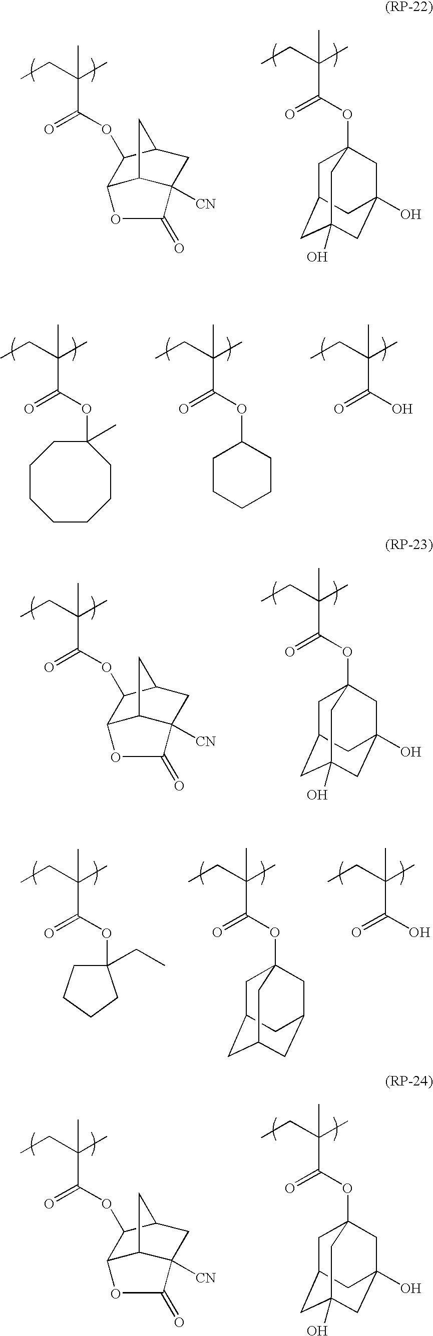

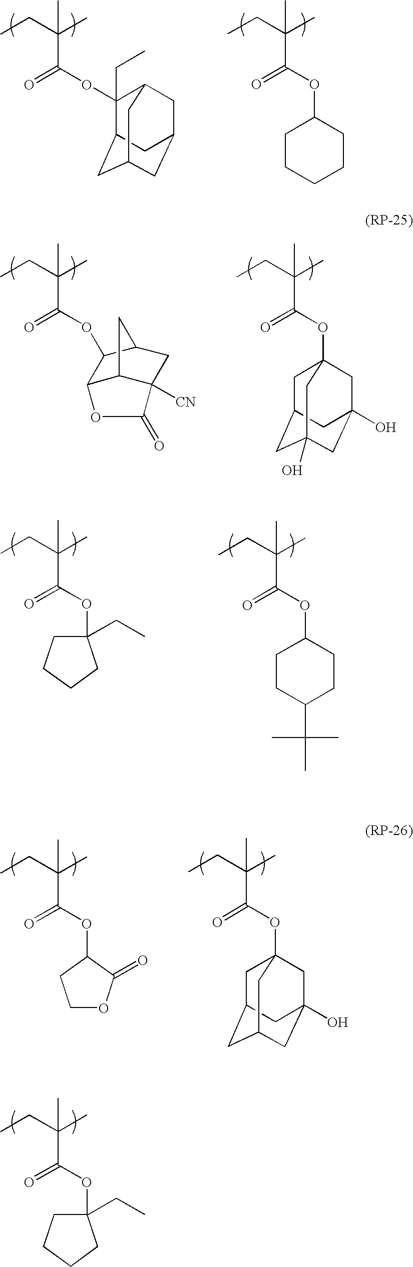

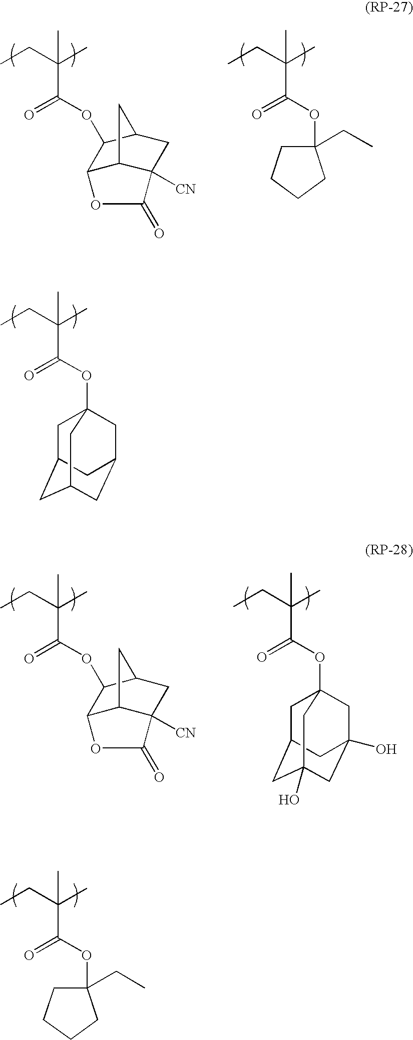

[2] Compound that when Irradiated with Actinic Rays or Radiation, Generates an Acid (Component (B))

The positive photosensitive composition for use in the present invention contains a compound that when irradiated with actinic rays or radiation, generates an acid (hereinafter also referred to as “acid generator”).

As the acid generator, use can be made of a member appropriately selected from among a photoinitiator for photocationic polymerization, a photoinitiator for photoradical polymerization, a photo-achromatic agent and photo-discoloring agent for dyes, any of publicly known compounds that when irradiated with actinic rays or radiation, generate an acid, are employed in microresists, etc., and mixtures thereof.

For example, there can be mentioned a diazonium salt, a phosphonium salt, a sulfonium salt, an iodonium salt, an imide sulfonate, an oxime sulfonate, diazosulfone, disulfone or o-nitrobenzyl sulfonate.

Further, use can be made of compounds obtained by introducing any of these groups or compounds that when irradiated with actinic rays or radiation, generate an acid in a polymer principal chain or side chain, for example, compounds described in U.S. Pat. No. 3,849,137, DE 3914407, JP-A's 63-26653, 55-164824, 62-69263, 63-146038, 63-163452, 62-153853, 63-146029, etc.

Furthermore, use can be made of compounds that when irradiated with light, generate an acid described in U.S. Pat. No. 3,779,778 and EP 126,712.

As preferred compounds among the acid generators, there can be mentioned those of the following general formulae (ZI), (ZII) and (ZIII).

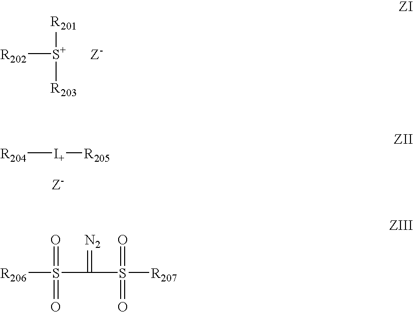

In the above general formula (ZI),

each of R₂₀₁, R₂₀₂ and R₂₀₃ independently represents an organic group.

The number of carbon atoms of any of the organic groups represented by R₂₀₁, R₂₀₂ and R₂₀₃ is generally in the range of 1 to 30, preferably 1 to 20.

Two of R₂₀₁ to R₂₀₃ may be bonded with each other to thereby form a ring structure, and the ring within the same may contain an oxygen atom, a sulfur atom, an ester bond, an amido bond or a carbonyl group. As a group formed by bonding of two of R₂₀₁ to R₂₀₃, there can be mentioned an alkylene group (for example, a butylene group or a pentylene group).

Z⁻ represents a nonnucleophilic anion.

As the nonnucleophilic anion represented by Z⁻, there can be mentioned, for example, a sulfonate anion, a carboxylate anion, a sulfonylimido anion, a bis(alkylsulfonyl)imido anion, a tris(alkylsulfonyl)methide anion or the like.

The nonnucleophilic anion means an anion whose capability of inducing a nucleophilic reaction is extremely low and means an anion capable of inhibiting any temporal decomposition by intramolecular nucleophilic reaction. This would realize an enhancement of the temporal stability of resist.

As the sulfonate anion, there can be mentioned, for example, an aliphatic sulfonate anion, an aromatic sulfonate anion, a camphor sulfonate anion or the like.

As the carboxylate anion, there can be mentioned, for example, an aliphatic carboxylate anion, an aromatic carboxylate anion, an aralkyl carboxylate anion or the like.

The aliphatic moiety of the aliphatic sulfonate anion may be an alkyl group or a cycloalkyl group, preferably an alkyl group having 1 to 30 carbon atoms or a cycloalkyl group having 3 to 30 carbon atoms. As such, there can be mentioned, for example, a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, a boronyl group or the like.

As a preferred aromatic group of the aromatic sulfonate anion, there can be mentioned an aryl group having 6 to 14 carbon atoms, for example, a phenyl group, a tolyl group, a naphthyl group or the like.

The alkyl group, cycloalkyl group and aryl group of the aliphatic sulfonate anion and aromatic sulfonate anion may have a substituent. As the substituent of the alkyl group, cycloalkyl group and aryl group of the aliphatic sulfonate anion and aromatic sulfonate anion, there can be mentioned, for example, a nitro group, a halogen atom (fluorine atom, chlorine atom, bromine atom or iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), a cycloalkylalkyloxyalkyloxy group (preferably having 8 to 20 carbon atoms) or the like. The aryl group and ring structure included in these groups may further have an alkyl group (preferably having 1 to 15 carbon atoms) as its substituent.

As the aliphatic moiety of the aliphatic carboxylate anion, there can be mentioned the same alkyl groups and cycloalkyl groups as mentioned with respect to the aliphatic sulfonate anion.

As the aromatic group of the aromatic carboxylate anion, there can be mentioned the same aryl groups as mentioned with respect to the aromatic sulfonate anion.

As a preferred aralkyl group of the aralkyl carboxylate anion, there can be mentioned an aralkyl group having 6 to 12 carbon atoms, for example, a benzyl group, a phenethyl group, a naphthylmethyl group, a naphthylethyl group or the like.

The alkyl group, cycloalkyl group, aryl group and aralkyl group of the aliphatic carboxylate anion, aromatic carboxylate anion and aralkyl carboxylate anion may have a substituent. As the substituent of the alkyl group, cycloalkyl group, aryl group and aralkyl group of the aliphatic carboxylate anion, aromatic carboxylate anion and aralkyl carboxylate anion, there can be mentioned, for example, the same halogen atom, alkyl group, cycloalkyl group, alkoxy group, alkylthio group, etc. as mentioned with respect to the aromatic sulfonate anion.

As the sulfonylimido anion, there can be mentioned, for example, a saccharin anion.

The alkyl group of the bis(alkylsulfonyl)imido anion and tris(alkylsulfonyl)methide anion is preferably an alkyl group having 1 to 5 carbon atoms. As such, there can be mentioned, for example, a methyl group, an ethyl group, a propyl group, an isopropyl group, an n-butyl group, an isobutyl group, a sec-butyl group, a pentyl group, a neopentyl group or the like. As a substituent of these alkyl groups, there can be mentioned a halogen atom, an alkyl group substituted with a halogen atom, an alkoxy group, an alkylthio group, an alkyloxysulfonyl group, an aryloxysulfonyl group, a cycloalkylaryloxysulfonyl group or the like. An alkyl group substituted with a fluorine atom is preferred.

As other nonnucleophilic anions, there can be mentioned, for example, phosphorus fluoride, boron fluoride, antimony fluoride and the like.

The nonnucleophilic anion represented by Z⁻ is preferably selected from among an aliphatic sulfonate anion substituted at its α-position of sulfonic acid with a fluorine atom, an aromatic sulfonate anion substituted with a fluorine atom or a group having a fluorine atom, a bis(alkylsulfonyl)imido anion whose alkyl group is substituted with a fluorine atom and a tris(alkylsulfonyl)methide anion whose alkyl group is substituted with a fluorine atom. More preferably, the nonnucleophilic anion is a perfluorinated aliphatic sulfonate anion having 4 to 8 carbon atoms, a benzene sulfonate anion having a fluorine atom, a bis(alkylsulfonyl)imido anion whose alkyl group is substituted with a fluorine atom or a tris(alkylsulfonyl)methide anion whose alkyl group is substituted with a fluorine atom.

As the organic groups represented by R₂₀₁, R₂₀₂ and R₂₀₃, there can be mentioned, for example, groups corresponding to the later-described compounds of the general formulae (ZI-1), (ZI-2) and (ZI-3).

The organic groups may consist of compounds with two or more of the structures of the general formula (ZI). For example, the compounds may be those of a structure wherein at least one of R₂₀₁ to R₂₀₃ of a compound of the general formula (ZI) is bonded with at least one of R₂₀₁ to R₂₀₃ of another compound of the general formula (ZI).

As preferred components represented by the formula (ZI), there can be mentioned the below-described compounds of the formulae (ZI-1), (ZI-2) and (ZI-3).

The compounds (ZI-1) are arylsulfonium compounds of the general formula (ZI) wherein at least one of R₂₀₁ to R₂₀₃ is an aryl group, namely, compounds containing an arylsulfonium as a cation.

In the arylsulfonium compounds, all of the R₂₀₁ to R₂₀₃ may be aryl groups. It is also appropriate if the R₂₀₁ to R₂₀₃ are an aryl group in part and an alkyl group or a cycloalkyl group in the remainder.

As the arylsulfonium compounds, there can be mentioned, for example, a triarylsulfonium compound, a diarylalkylsulfonium compound, an aryldialkylsulfonium compound, a diarylcycloalkylsulfonium compound or an aryldicycloalkylsulfonium compound.

The aryl group of the arylsulfonium compounds is preferably a phenyl group or a naphthyl group, more preferably a phenyl group. The aryl group may be one having a heterocyclic structure containing an oxygen atom, nitrogen atom, sulfur atom or the like. As the aryl group having a heterocyclic structure, there can be mentioned, for example, a pyrrole residue (group formed by loss of one hydrogen atom from pyrrole), a furan residue (group formed by loss of one hydrogen atom from furan), a thiophene residue (group formed by loss of one hydrogen atom from thiophene), an indole residue (group formed by loss of one hydrogen atom from indole), a benzofuran residue (group formed by loss of one hydrogen atom from benzofuran), a benzothiophene residue (group formed by loss of one hydrogen atom from benzothiophene) or the like. When any of the arylsulfonium compounds has two or more aryl groups, the two or more aryl groups may be identical with or different from each other.

The alkyl group or cycloalkyl group included in the arylsulfonium compounds according to necessity is preferably a linear or branched alkyl group having 1 to 15 carbon atoms or a cycloalkyl group having 3 to 15 carbon atoms. As such, there can be mentioned, for example, a methyl group, an ethyl group, a propyl group, an n-butyl group, a sec-butyl group, a t-butyl group, a cyclopropyl group, a cyclobutyl group, a cyclohexyl group or the like.

The aryl group, alkyl group or cycloalkyl group represented by R₂₀₁ to R₂₀₃ may have as a substituent an alkyl group (for example, 1 to 15 carbon atoms), a cycloalkyl group (for example, 3 to 15 carbon atoms), an aryl group (for example, 6 to 14 carbon atoms), an alkoxy group (for example, 1 to 15 carbon atoms), a halogen atom, a hydroxyl group or a phenylthio group. Preferred substituents are a linear or branched alkyl group having 1 to 12 carbon atoms, a cycloalkyl group having 3 to 12 carbon atoms and a linear, branched or cyclic alkoxy group having 1 to 12 carbon atoms. More preferred substituents are an alkyl group having 1 to 4 carbon atoms and an alkoxy group having 1 to 4 carbon atoms. The substituents may be included in any one of the three R₂₀₁ to R₂₀₃, or alternatively may be included in all three of R₂₀₁ to R₂₀₃. When R₂₀₁ to R₂₀₃ represent an aryl group, the substituent preferably lies at the p-position of the aryl group.

Now, the compounds of the formula (ZI-2) will be described.

The compounds of the formula (ZI-2) are compounds of the formula (ZI) wherein each of R₂₀₁ to R₂₀₃ independently represents an organic group having no aromatic ring. The aromatic rings include an aromatic ring having a heteroatom.

Each of the organic groups having no aromatic ring represented by R₂₀₁ to R₂₀₃ generally has 1 to 30 carbon atoms, preferably 1 to 20 carbon atoms.

Preferably, each of R₂₀₁ to R₂₀₃ independently represents an alkyl group, a cycloalkyl group, an allyl group or a vinyl group. More preferred groups are a linear or branched 2-oxoalkyl group, a 2-oxocycloalkyl group and an alkoxycarbonylmethyl group. An especially preferred one is a linear or branched 2-oxoalkyl group.

As preferred alkyl groups and cycloalkyl groups represented by R₂₀₁ to R₂₀₃, there can be mentioned a linear or branched alkyl group having 1 to 10 carbon atoms (for example, a methyl group, an ethyl group, a propyl group, a butyl group or a pentyl group) and a cycloalkyl group having 3 to 10 carbon atoms (a cyclopentyl group, a cyclohexyl group or a norbornyl group). As more preferred alkyl groups, there can be mentioned a 2-oxoalkyl group and an alkoxycarbonylmethyl group. As a more preferred cycloalkyl group, there can be mentioned a 2-oxocycloalkyl group.

The 2-oxoalkyl group may be linear or branched. A preferred group is one having >C═O at the 2-position of the alkyl group.

A preferred 2-oxocycloalkyl group is one having >C═O at the 2-position of the cycloalkyl group.

As preferred alkoxy groups of the alkoxycarbonylmethyl group, there can be mentioned alkoxy groups having 1 to 5 carbon atoms (a methoxy group, an ethoxy group, a propoxy group, a butoxy group and a pentoxy group).

The R₂₀₁ to R₂₀₃ may be further substituted with a halogen atom, an alkoxy group (for example, 1 to 5 carbon atoms), a hydroxyl group, a cyano group or a nitro group.

Now, the compounds (ZI-3) will be described.

The compounds (ZI-3) are those represented by the following general formula (ZI-3) which have a phenacylsulfonium salt structure.

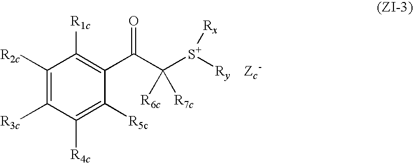

In the general formula (ZI-3),

each of R_{1c} to R_{5c} independently represents a hydrogen atom, an alkyl group, a cycloalkyl group, an alkoxy group or a halogen atom.

Each of R_{6c} and R_{7c} independently represents a hydrogen atom, an alkyl group or a cycloalkyl group.

Each of Rₓ and R_{y} independently represents an alkyl group, a cycloalkyl group, an allyl group or a vinyl group.

Any two or more of R_{1c} to R_{5c}, and R_{6c} and R_{7c}, and Rₓ and R_{y} may be bonded with each other to thereby form a ring structure. This ring structure may contain an oxygen atom, a sulfur atom, an ester bond or an amido bond. As the group formed by bonding of any two or more of R_{1c} to R_{5c}, and R_{6c} and R_{7c}, and Rₓ and R_{y}, there can be mentioned a butylene group, a pentylene group or the like.

Zc⁻ represents a nonnucleophilic anion. There can be mentioned the same nonnucleophilic anions as mentioned with respect to the Z⁻ of the general formula (ZI).

The alkyl groups represented by R_{1c} to R_{7c} may be linear or branched. As such, there can be mentioned, for example, an alkyl group having 1 to 20 carbon atoms, preferably a linear or branched alkyl group having 1 to 12 carbon atoms (for example, a methyl group, an ethyl group, a linear or branched propyl group, a linear or branched butyl group or a linear or branched pentyl group). As the cycloalkyl group, there can be mentioned, for example, a cycloalkyl group having 3 to 10 carbon atoms (for example, a cyclopentyl group or a cyclohexyl group).

The alkoxy groups represented by R_{1c} to R_{5c} may be linear, or branched, or cyclic. As such, there can be mentioned, for example, an alkoxy group having 1 to 10 carbon atoms, preferably a linear or branched alkoxy group having 1 to 5 carbon atoms (for example, a methoxy group, an ethoxy group, a linear or branched propoxy group, a linear or branched butoxy group or a linear or branched pentoxy group) and a cycloalkoxy group having 3 to 8 carbon atoms (for example, a cyclopentyloxy group or a cyclohexyloxy group).

Preferably, any one of R_{1c} to R_{5c} is a linear or branched alkyl group, a cycloalkyl group or a linear, branched or cyclic alkoxy group. More preferably, the sum of carbon atoms of R_{1c} to R_{5c} is in the range of 2 to 15. Accordingly, there can be attained an enhancement of solvent solubility and inhibition of particle generation during storage.

As the alkyl groups and cycloalkyl groups represented by Rₓ and R_{y}, there can be mentioned the same alkyl groups and cycloalkyl groups as mentioned with respect to R_{1c} to R_{7c}. Among them, a 2-oxoalkyl group, a 2-oxocycloalkyl group and an alkoxycarbonylmethyl group are preferred.

As the 2-oxoalkyl group and 2-oxocycloalkyl group, there can be mentioned groups having >C═O at the 2-position of the alkyl group and cycloalkyl group represented by R_{1c} to R_{7c}.

Regarding the alkoxy group of the alkoxycarbonylmethyl group, there can be mentioned the same alkoxy groups as mentioned with respect to R_{1c} to R_{5c}.

Each of Rₓ and R_{y} represents an alkyl group or cycloalkyl group having preferably 4 or more carbon atoms, more preferably 6 or more carbon atoms and still more preferably 8 or more carbon atoms.

Now, the general formulae (ZII) and (ZIII) will be described.

In the general formulae (ZII) and (ZIII),

each of R₂₀₄ to R₂₀₇ independently represents an aryl group, an alkyl group or a cycloalkyl group.

The aryl group represented by each of R₂₀₄ to R₂₀₇ is preferably a phenyl group or a naphthyl group, more preferably a phenyl group. The aryl groups represented by R₂₀₄ to R₂₀₇ may be those having a heterocyclic structure containing an oxygen atom, nitrogen atom, sulfur atom or the like. As the aryl group having a heterocyclic structure, there can be mentioned, for example, a pyrrole residue (group formed by loss of one hydrogen atom from pyrrole), a furan residue (group formed by loss of one hydrogen atom from furan), a thiophene residue (group formed by loss of one hydrogen atom from thiophene), an indole residue (group formed by loss of one hydrogen atom from indole), a benzofuran residue (group formed by loss of one hydrogen atom from benzofuran), a benzothiophene residue (group formed by loss of one hydrogen atom from benzothiophene) or the like.

As preferred alkyl groups and cycloalkyl groups represented by R₂₀₄ to R₂₀₇, there can be mentioned a linear or branched alkyl group having 1 to 10 carbon atoms (for example, a methyl group, an ethyl group, a propyl group, a butyl group or a pentyl group) and a cycloalkyl group having 3 to 10 carbon atoms (a cyclopentyl group, a cyclohexyl group or a norbornyl group).

The aryl group, alkyl group and cycloalkyl group represented by R₂₀₄ to R₂₀₇ may have a substituent. As the substituent that may be included in the aryl group, alkyl group and cycloalkyl group represented by R₂₀₄ to R₂₀₇, there can be mentioned, for example, an alkyl group (for example, 1 to 15 carbon atoms), a cycloalkyl group (for example, 3 to 15 carbon atoms), an aryl group (for example, 6 to 15 carbon atoms), an alkoxy group (for example, 1 to 15 carbon atoms), a halogen atom, a hydroxyl group, a phenylthio group or the like.

Z⁻ represents a nonnucleophilic anion. As such, there can be mentioned the same nonnucleophilic anions as mentioned with respect to the Z⁻ of the general formula (ZI).

As the acid generators, there can be further mentioned the compounds of the following general formulae (ZIV), (ZV) and (ZVI).

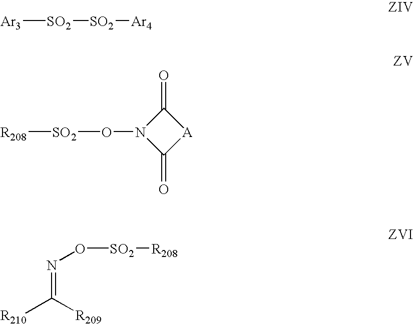

In the general formulae (ZIV) to (ZVI),

each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Among the acid generators, the compounds of the general formulae (ZI) to (ZIII) are more preferred.

As a preferred acid generator, there can be mentioned a compound that generates an acid having one sulfonate group or imido group. As a more preferred acid generator, there can be mentioned a compound that generates a monovalent perfluoroalkanesulfonic acid, a compound that generates a monovalent aromatic sulfonic acid substituted with a fluorine atom or fluorine-atom-containing group, or a compound that generates a monovalent imidic acid substituted with a fluorine atom or fluorine-atom-containing group. As a still more preferred acid generator, there can be mentioned any of sulfonium salts of fluorinated alkanesulfonic acid, fluorinated benzenesulfonic acid, fluorinated imidic acid and fluorinated methide acid. With respect to practicable acid generators, it is especially preferred that the generated acid be a fluorinated alkanesulfonic acid, fluorinated benzenesulfonic acid or fluorinated imidic acid of −1 or below pKa. In the use thereof, an enhancement of sensitivity is attained.

Especially preferred examples of the acid generators will be shown below, which however in no way limit the scope of the present invention.

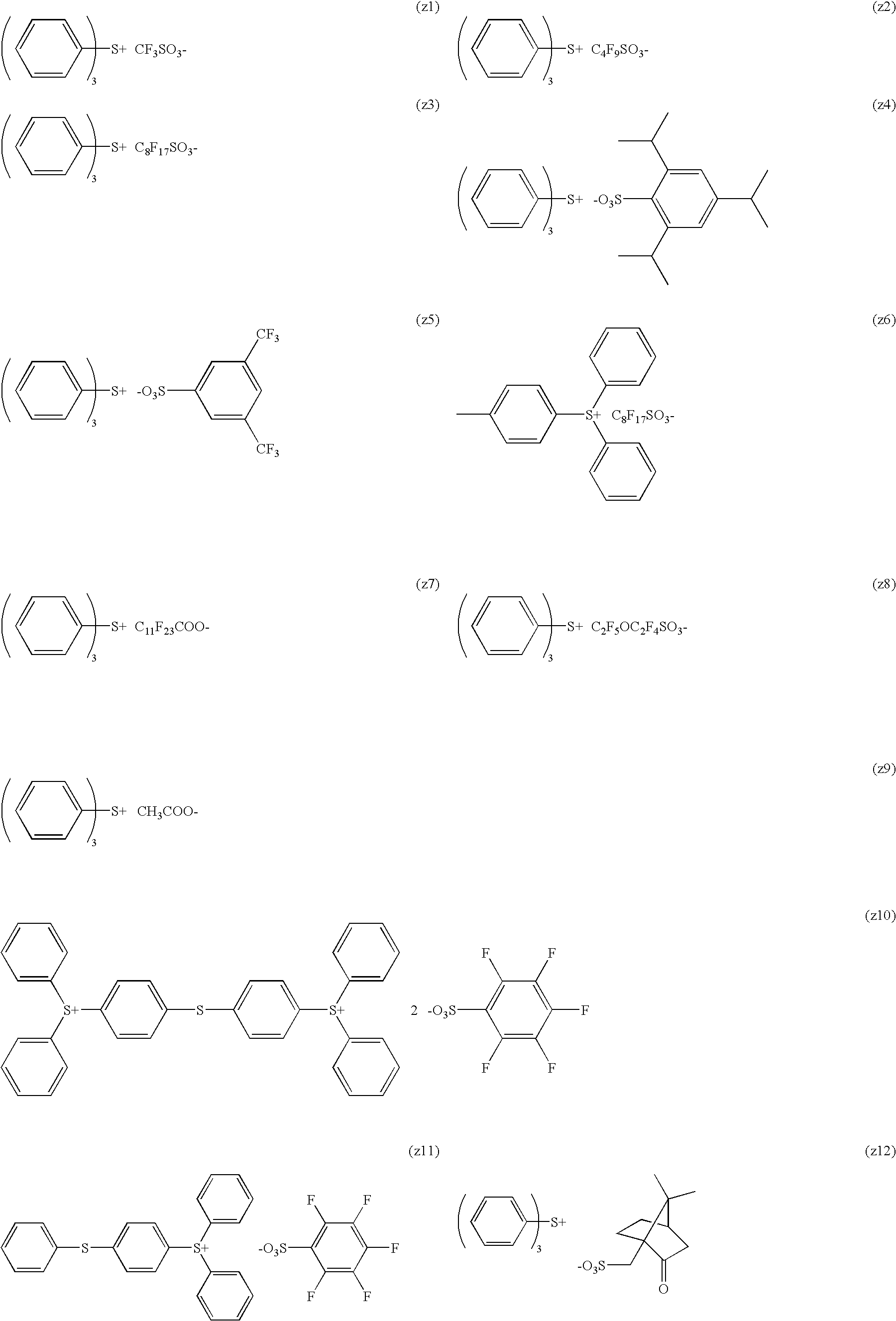

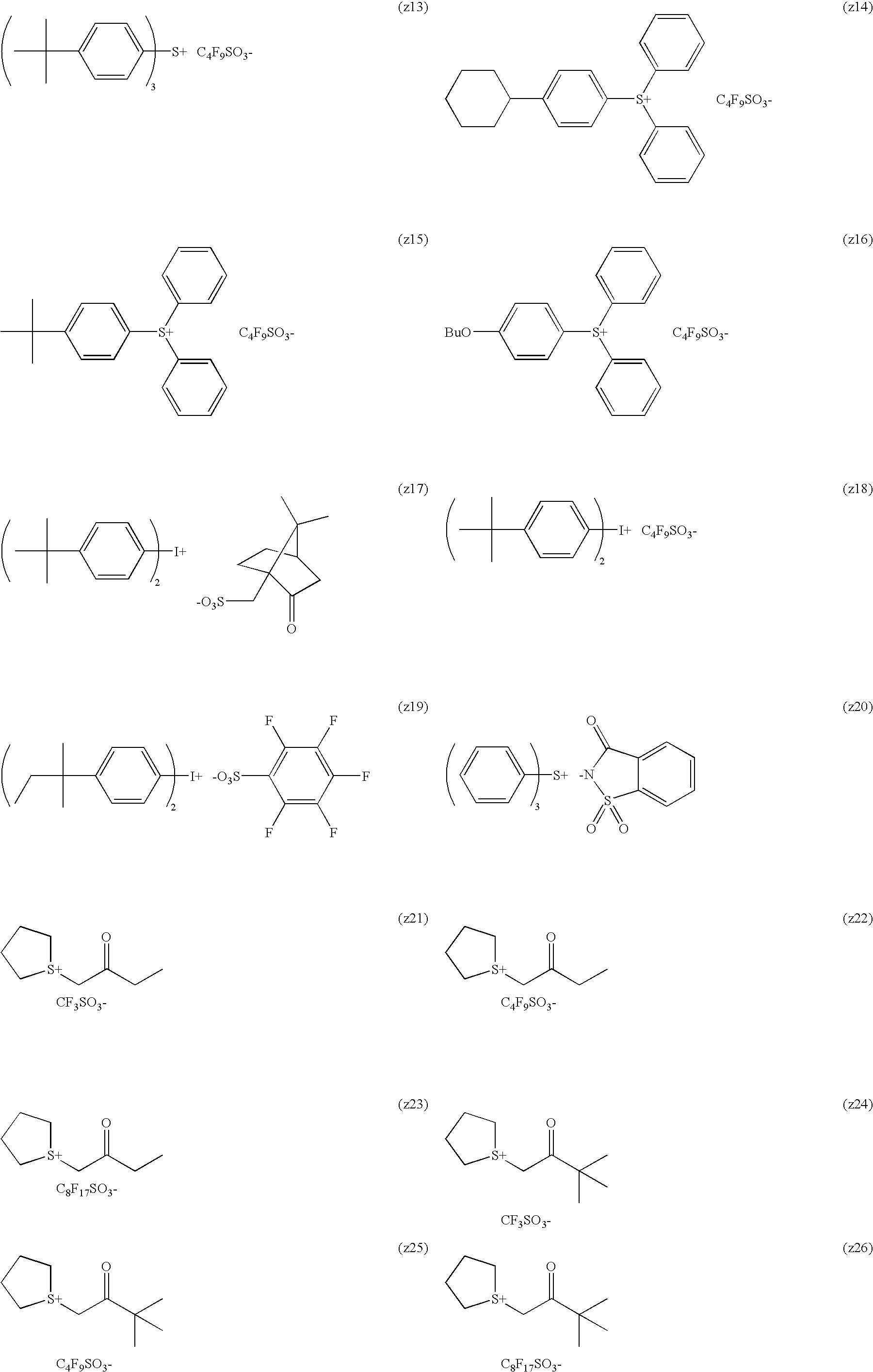

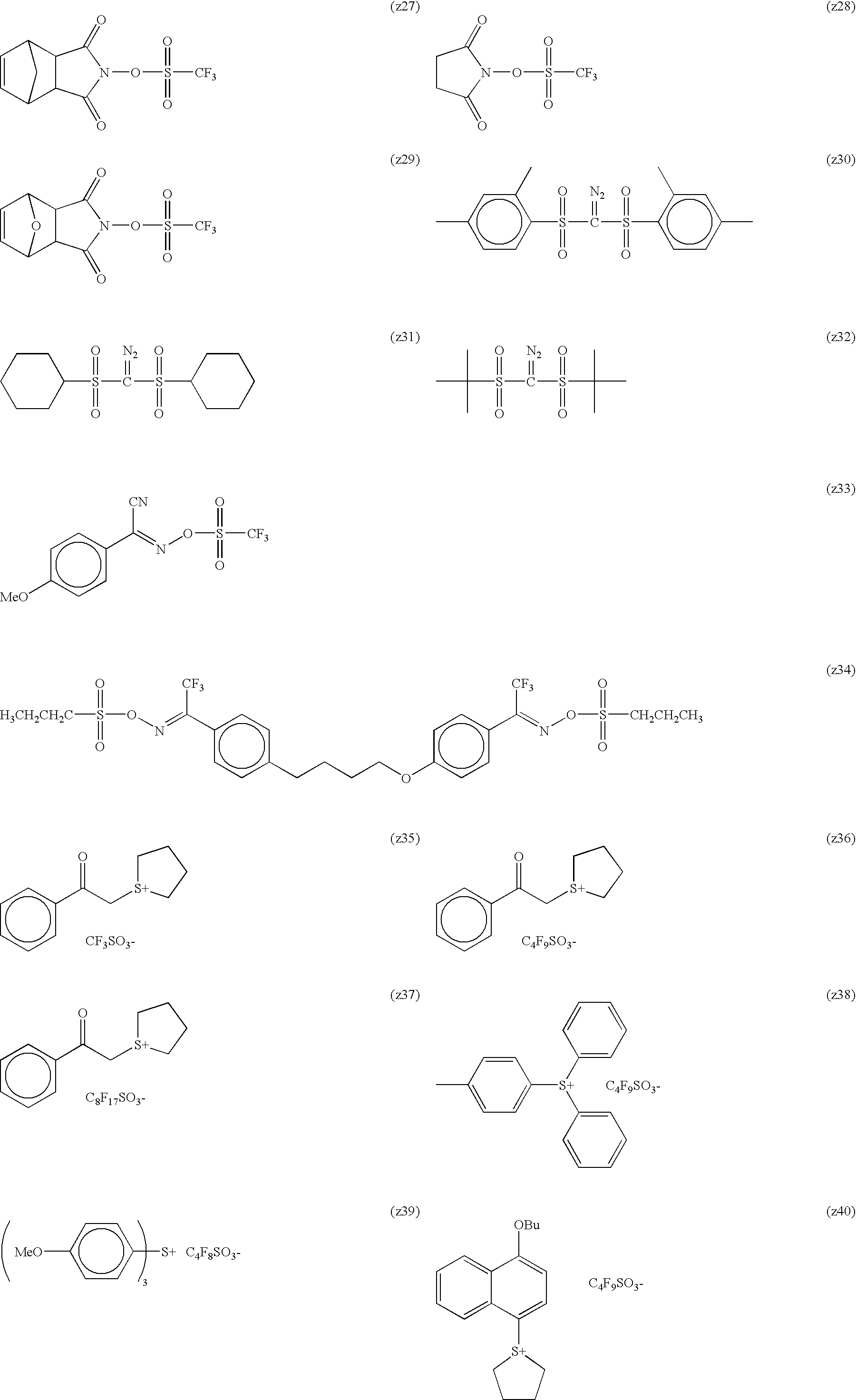

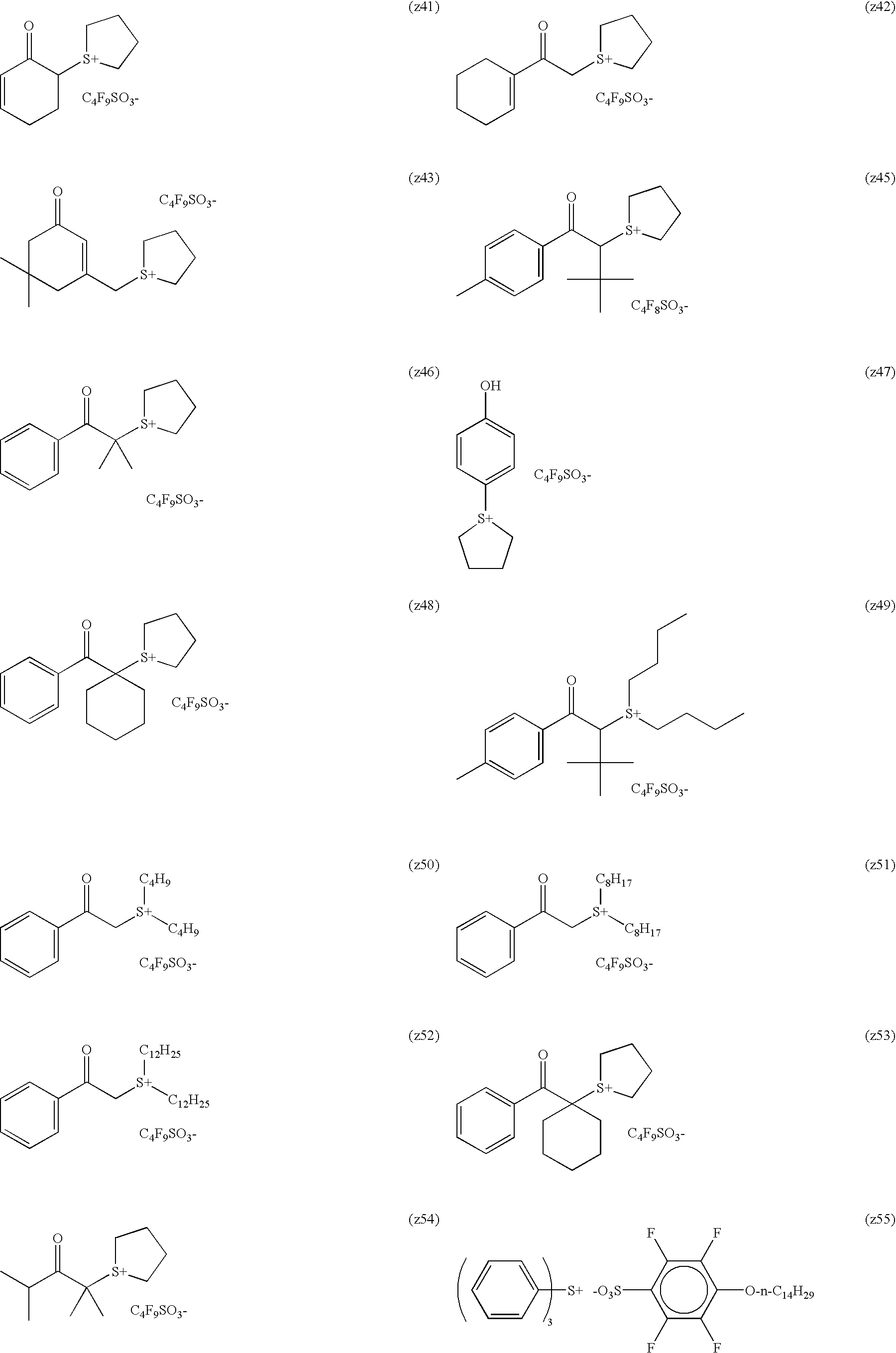

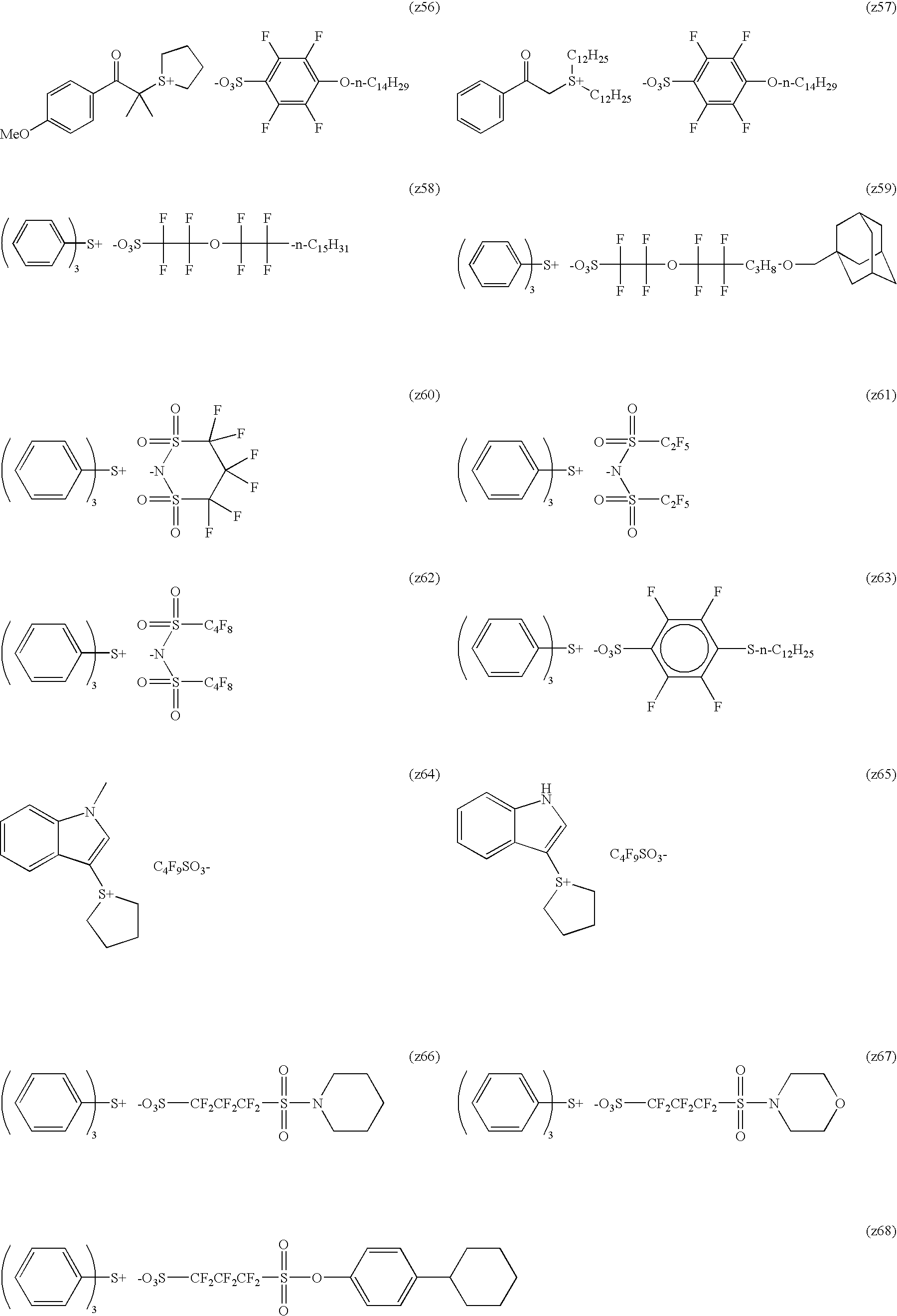

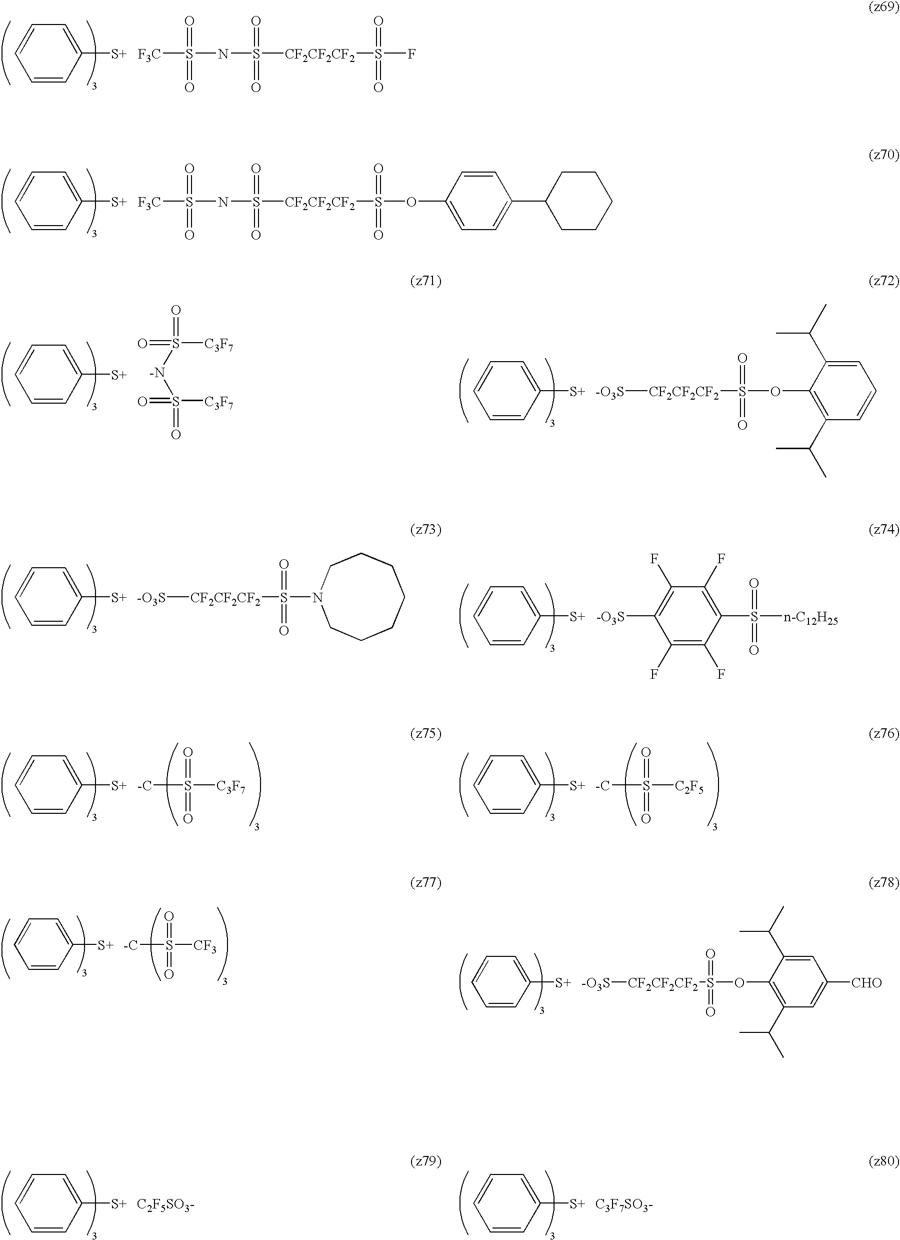

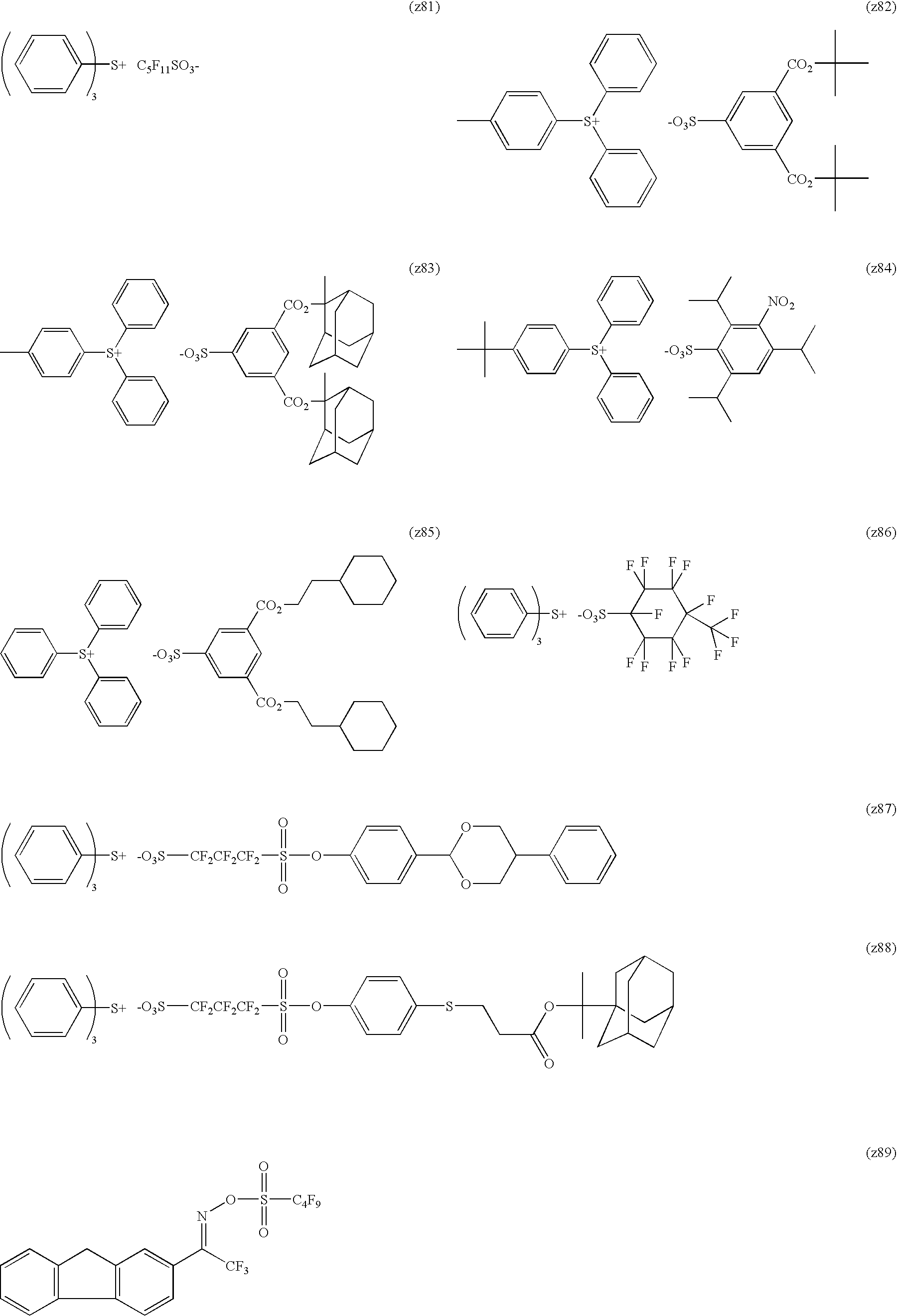

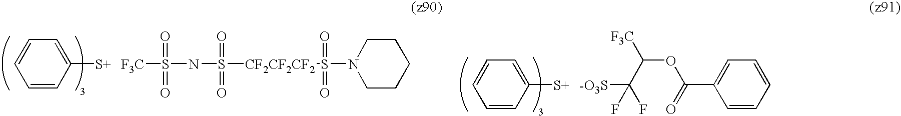

The acid generators can be used either individually or in combination.

The content of acid generator in the positive photosensitive composition is preferably in the range of 0.1 to 20 mass %, more preferably 0.5 to 10 mass % and still more preferably 1 to 7 mass % based on the total solid content of the positive photosensitive composition.

[3] Basic Compound

The positive resist composition for use in the present invention preferably contains a basic compound so as to decrease any performance alteration over time from exposure to heating.

As preferred basic compounds, there can be mentioned the compounds having the structures of the following formulae (A) to (E).

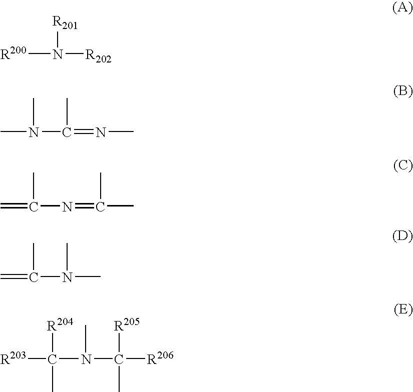

In the general formulae (A) and (E),

R²⁰⁰, R²⁰¹ and R²⁰² may be identical with or different from each other and each represent a hydrogen atom, an alkyl group (preferably having 1 to 20 carbon atoms), a cycloalkyl group (preferably having 3 to 20 carbon atoms) or an aryl group (having 6 to 20 carbon atoms). R²⁰¹ and R²⁰² may be bonded with each other to thereby form a ring.

With respect to the above alkyl group, as a preferred substituted alkyl group, there can be mentioned an aminoalkyl group having 1 to 20 carbon atoms, a hydroxyalkyl group having 1 to 20 carbon atoms or a cyanoalkyl group having 1 to 20 carbon atoms.

R²⁰³, R²⁰⁴, R²⁰⁵ and R²⁰⁶ may be identical with or different from each other and each represent an alkyl group having 1 to 20 carbon atoms.

It is more preferred that in these general formulae (A) and (E) the alkyl group be unsubstituted.

As preferred compounds, there can be mentioned guanidine, aminopyrrolidine, pyrazole, pyrazoline, piperazine, aminomorpholine, aminoalkylmorpholine, piperidine and the like. Further, as preferred compounds, there can be mentioned compounds with an imidazole structure, a diazabicyclo structure, an onium hydroxide structure, an onium carboxylate structure, a trialkylamine structure, an aniline structure or a pyridine structure, alkylamine derivatives having a hydroxyl group and/or an ether bond, aniline derivatives having a hydroxyl group and/or an ether bond and the like.

As the compounds with an imidazole structure, there can be mentioned imidazole, 2,4,5-triphenylimidazole, benzimidazole, 2-phenylbenzoimidazole and the like. As the compounds with a diazabicyclo structure, there can be mentioned 1,4-diazabicyclo[2,2,2]octane, 1,5-diazabicyclo[4,3,0]non-5-ene, 1,8-diazabicyclo[5,4,0]undec-7-ene and the like. As the compounds with an onium hydroxide structure, there can be mentioned tetrabutylammonium hydroxide, triarylsulfonium hydroxide, phenacylsulfonium hydroxide, and sulfonium hydroxides having a 2-oxoalkyl group such as triphenylsulfonium hydroxide, tris(t-butylphenyl)sulfonium hydroxide, bis(t-butylphenyl)iodonium hydroxide, phenacylthiophenium hydroxide, 2-oxopropylthiophenium hydroxide and the like. As the compounds with an onium carboxylate structure, there can be mentioned those having a carboxylate at the anion moiety of the compounds with an onium hydroxide structure, for example, acetate, adamantane-1-carboxylate, perfluoroalkyl carboxylate and the like. As the compounds with a trialkylamine structure, there can be mentioned tri(n-butyl)amine, tri(n-octyl)amine and the like. As the aniline compounds, there can be mentioned 2,6-diisopropylaniline, N,N-dimethylaniline, N,N-dibutylaniline, N,N-dihexylaniline and the like. As the alkylamine derivatives having a hydroxyl group and/or an ether bond, there can be mentioned ethanolamine, diethanolamine, triethanolamine, N-phenyldiethanolamine, tris(methoxyethoxyethyl)amine and the like. As the aniline derivatives having a hydroxyl group and/or an ether bond, there can be mentioned N,N-bis(hydroxyethyl)aniline and the like.

As preferred basic compounds, there can be further mentioned an amine compound having a phenoxy group, an ammonium salt compound having a phenoxy group, an amine compound having a sulfonic ester group and an ammonium salt compound having a sulfonic ester group.

As the amine compound, use can be made of primary, secondary and tertiary amine compounds. An amine compound having at least one alkyl group bonded to the nitrogen atom thereof is preferred. Among the amine compounds, a tertiary amine compound is more preferred. Of the amine compounds, as long as at least one alkyl group (preferably having 1 to 20 carbon atoms) is bonded to the nitrogen atom, a cycloalkyl group (preferably having 3 to 20 carbon atoms) or an aryl group (preferably having 6 to 12 carbon atoms) besides the alkyl group may be bonded to the nitrogen atom. Of the amine compounds, it is preferred that the alkyl chain contain an oxygen atom, thereby forming an oxyalkylene group. The number of oxyalkylene groups in each molecule is one or more, preferably 3 to 9, and more preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

As the ammonium salt compound, use can be made of primary, secondary, tertiary and quaternary ammonium salt compounds. An ammonium salt compound having at least one alkyl group bonded to the nitrogen atom thereof is preferred. Of the ammonium salt compounds, as long as at least one alkyl group (preferably having 1 to 20 carbon atoms) is bonded to the nitrogen atom, a cycloalkyl group (preferably having 3 to 20 carbon atoms) or an aryl group (preferably having 6 to 12 carbon atoms) besides the alkyl group may be bonded to the nitrogen atom. Of the ammonium salt compounds, it is preferred that the alkyl chain contain an oxygen atom, thereby forming an oxyalkylene group. The number of oxyalkylene groups in each molecule is one or more, preferably 3 to 9, and more preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group. As the anion of the ammonium salt compounds, there can be mentioned a halogen atom, a sulfonate, a borate, a phosphate or the like. Of these, a halogen atom and a sulfonate are preferred. Among halogen atoms, chloride, bromide and iodide are especially preferred. Among sulfonates, an organic sulfonate having 1 to 20 carbon atoms is especially preferred. As the organic sulfonate, there can be mentioned an aryl sulfonate and an alkyl sulfonate having 1 to 20 carbon atoms. The alkyl group of the alkyl sulfonate may have a substituent. As the substituent, there can be mentioned, for example, fluorine, chlorine, bromine, an alkoxy group, an acyl group, an aryl group or the like. As specific examples of the alkyl sulfonates, there can be mentioned methane sulfonate, ethane sulfonate, butane sulfonate, hexane sulfonate, octane sulfonate, benzyl sulfonate, trifluoromethane sulfonate, pentafluoroethane sulfonate, nonafluorobutane sulfonate and the like. As the aryl group of the aryl sulfonate, there can be mentioned a benzene ring, a naphthalene ring or an anthracene ring. The benzene ring, naphthalene ring or anthracene ring may have a substituent. As preferred substituents, there can be mentioned a linear or branched alkyl group having 1 to 6 carbon atoms and a cycloalkyl group having 3 to 6 carbon atoms. As specific examples of the linear or branched alkyl groups and cycloalkyl groups, there can be mentioned methyl, ethyl, n-propyl, isopropyl, n-butyl, i-butyl, t-butyl, n-hexyl, cyclohexyl and the like. As other substituents, there can be mentioned an alkoxy group having 1 to 6 carbon atoms, a halogen atom, cyano, nitro, an acyl group, an acyloxy group and the like.

The amine compound having a phenoxy group or ammonium salt compound having a phenoxy group is one having a phenoxy group at the end of the alkyl group of the amine compound or ammonium salt compound opposed to the nitrogen atom. The phenoxy group may have a substituent. As the substituent of the phenoxy group, there can be mentioned, for example, an alkyl group, an alkoxy group, a halogen atom, a cyano group, a nitro group, a carboxyl group, a carboxylic ester group, a sulfonic ester group, an aryl group, an aralkyl group, an acyloxy group, an aryloxy group or the like. The substitution position of the substituent may be any of 2- to 6-positions. The number of substituents is optional within the range of 1 to 5.

It is preferred that at least one oxyalkylene group be included between the phenoxy group and the nitrogen atom. The number of oxyalkylene groups in each molecule is one or more, preferably 3 to 9, and more preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

The sulfonic ester group of the amine compound having a sulfonic ester group or ammonium salt compound having a sulfonic ester group may be any of an alkylsulfonic ester, a cycloalkylsulfonic ester and an arylsulfonic ester. In the alkylsulfonic ester, the alkyl group preferably has 1 to 20 carbon atoms. In the cycloalkylsulfonic ester, the cycloalkyl group preferably has 3 to 20 carbon atoms. In the arylsulfonic ester, the aryl group preferably has 6 to 12 carbon atoms. The alkylsulfonic ester, cycloalkylsulfonic ester and arylsulfonic ester may have substituents. As preferred substituents, there can be mentioned a halogen atom, a cyano group, a nitro group, a carboxyl group, a carboxylic ester group and a sulfonic ester group.

It is preferred that at least one oxyalkylene group be included between the sulfonic ester group and the nitrogen atom. The number of oxyalkylene groups in each molecule is one or more, preferably 3 to 9, and more preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

These basic compounds are used either individually or in combination.

The amount of basic compound used is generally in the range of 0.001 to 10 mass %, preferably 0.01 to 5 mass % based on the total solid content of the positive resist composition.

With respect to the ratio of acid generator to basic compound used in the composition, preferably, acid generator/basic compound (molar ratio)=2.5 to 300. The reason for this is that the molar ratio is preferred to be 2.5 or higher from the viewpoint of sensitivity and resolving power. The molar ratio is preferred to be 300 or below from the viewpoint of inhibition of resolving power deterioration due to thickening of the resist pattern over time from exposure to the heating treatment. The acid generator/basic compound (molar ratio) is more preferably in the range of 5.0 to 200, still more preferably 7.0 to 150.

[4] Surfactant

The positive resist composition for use in the present invention preferably further contains a surfactant, and more preferably contains any one, or two or more members, of fluorinated and/or siliconized surfactants (fluorinated surfactant, siliconized surfactant and surfactant containing both fluorine and silicon atoms).

The positive resist composition for use in the present invention when containing the above surfactant would, in the use of an exposure light source of 250 nm or below, especially 220 nm or below, realize favorable sensitivity and resolving power and produce a resist pattern of less adhesion and development defects.

As the fluorinated and/or siliconized surfactants, there can be mentioned, for example, those described in JP-A's-62-36663, 61-226746, 61-226745, 62-170950, 63-34540, 7-230165, 8-62834, 9-54432, 9-5988 and 2002-277862 and U.S. Pat. Nos. 5,405,720, 5,360,692, 5,529,881, 5,296,330, 5,436,098, 5,576,143, 5,294,511 and 5,824,451. Any of the following commercially available surfactants can be used as is.

As useful commercially available surfactants, there can be mentioned, for example, fluorinated surfactants/siliconized surfactants, such as Eftop EF301 and EF303 (produced by Shin-Akita Kasei Co., Ltd.), Florad FC 430, 431 and 4430 (produced by Sumitomo 3M Ltd.), Megafac F171, F173, F176, F189, F113, F110, F177, F120 and R08 (produced by Dainippon Ink & Chemicals, Inc.), Surflon S-382, SC101, 102, 103, 104, 105 and 106 (produced by Asahi Glass Co., Ltd.), Troy Sol S-366 (produced by Troy Chemical Co., Ltd.), GF-300 and GF-150 (produced by TOAGOSEI CO., LTD.), Sarfron S-393 (produced by SEIMI CHEMICAL CO., LTD.), Eftop EF121, EF122A, EF122B, RF122C, EF125M, EF135M, EF351, EF352, EF801, EF802 and EF601 (produced by JEMCO INC.), PF636, PF656, PF6320 and PF6520 (produced by OMNOVA), and FTX-204G, 208G, 218G, 230G, 204D, 208D, 212D, 218D and 222D (produced by NEOS). Further, polysiloxane polymer KP-341 (produced by Shin-Etsu Chemical Co., Ltd.) can be employed as the siliconized surfactant.

As the surfactant, besides the above publicly known surfactants, use can be made of a surfactant based on a polymer having a fluorinated aliphatic group derived from a fluorinated aliphatic compound produced by a telomerization technique (also called a telomer process) or an oligomerization technique (also called an oligomer process). The fluorinated aliphatic compound can be synthesized by the process described in JP-A-2002-90991.

The polymer having a fluorinated aliphatic group is preferably a copolymer from a monomer having a fluorinated aliphatic group and a poly(oxyalkylene) acrylate and/or poly(oxyalkylene) methacrylate, which copolymer may have an irregular distribution or may result from block copolymerization. As the poly(oxyalkylene) group, there can be mentioned a poly(oxyethylene) group, a poly(oxypropylene) group, a poly(oxybutylene) group or the like. Further, use can be made of a unit having alkylene groups of different chain lengths in a single chain, such as poly(oxyethylene-oxypropylene-oxyethylene block concatenation) or poly(oxyethylene-oxypropylene block concatenation). Moreover, the copolymer from a monomer having a fluorinated aliphatic group and a poly(oxyalkylene) acrylate (or methacrylate) is not limited to two-monomer copolymers and may be a three or more monomer copolymer obtained by simultaneous copolymerization of two or more different monomers having a fluorinated aliphatic group, two or more different poly(oxyalkylene) acrylates (or methacrylates), etc.

For example, as a commercially available surfactant, there can be mentioned Megafac F178, F-470, F-473, F-475, F-476 or F-472 (produced by Dainippon Ink & Chemicals, Inc.). Further, there can be mentioned a copolymer from an acrylate (or methacrylate) having a C₆F₁₃ group and a poly(oxyalkylene) acrylate (or methacrylate), a copolymer from an acrylate (or methacrylate) having a C₃F₇ group, poly(oxyethylene) acrylate (or methacrylate) and poly(oxypropylene) acrylate (or methacrylate), or the like.

In the present invention, surfactants other than the fluorinated and/or siliconized surfactants can also be employed. In particular, there can be mentioned, for example, nonionic surfactants including a polyoxyethylene alkyl ether such as polyoxyethylene lauryl ether, polyoxyethylene stearyl ether, polyoxyethylene cetyl ether or polyoxyethylene oleyl ether, a polyoxyethylene alkylaryl ether such as polyoxyethylene octylphenol ether or polyoxyethylene nonylphenol ether, a polyoxyethylene-polyoxypropylene block copolymer, a sorbitan fatty acid ester such as sorbitan monolaurate, sorbitan monopalmitate, sorbitan monostearate, sorbitan monooleate, sorbitan trioleate or sorbitan tristearate, a polyoxyethylene sorbitan fatty acid ester such as polyoxyethylene sorbitan monolaurate, polyoxyethylene sorbitan monopalmitate, polyoxyethylene sorbitan monostearate, polyoxyethylene sorbitan trioleate or polyoxyethylene sorbitan tristearate, or the like.

These surfactants may be used either individually or in combination.

The amount of surfactant used is preferably in the range of 0.0001 to 2 mass %, more preferably 0.001 to 1 mass % based on the total solid content of the positive resist composition.

[5] Solvent

As the solvent being useful in the preparation of the positive resist composition through dissolution of the above-mentioned individual components, there can be mentioned, for example, organic solvents, such as an alkylene glycol monoalkyl ether carboxylate, an alkylene glycol monoalkyl ether, an alkyl lactate, an alkyl alkoxypropionate, a cyclolactone (preferably having 4 to 10 carbon atoms), an optionally cyclized monoketone compound (preferably having 4 to 10 carbon atoms), an alkylene carbonate, an alkyl alkoxyacetate and an alkyl pyruvate.

As preferred alkylene glycol monoalkyl ether carboxylates, there can be mentioned, for example, propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate and ethylene glycol monoethyl ether acetate.

As preferred alkylene glycol monoalkyl ethers, there can be mentioned, for example, propylene glycol monomethyl ether, propylene glycol monoethyl ether, propylene glycol monopropyl ether, propylene glycol monobutyl ether, ethylene glycol monomethyl ether and ethylene glycol monoethyl ether.

As preferred alkyl lactates, there can be mentioned, for example, methyl lactate, ethyl lactate, propyl lactate and butyl lactate.

As preferred alkyl alkoxypropionates, there can be mentioned, for example, ethyl 3-ethoxypropionate, methyl 3-methoxypropionate, methyl 3-ethoxypropionate and ethyl 3-methoxypropionate.

As preferred cyclolactones, there can be mentioned, for example, β-propiolactone, β-butyrolactone, γ-butyrolactone, α-methyl-γ-butyrolactone, β-methyl-γ-butyrolactone, γ-valerolactone, γ-caprolactone, γ-octanoic lactone and α-hydroxy-γ-butyrolactone.

As preferred optionally cyclized monoketone compounds, there can be mentioned, for example, 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone and 3-methylcycloheptanone.

As preferred alkylene carbonates, there can be mentioned, for example, propylene carbonate, vinylene carbonate, ethylene carbonate and butylene carbonate.

As preferred alkyl alkoxyacetates, there can be mentioned, for example, acetic acid 2-methoxyethyl ester, acetic acid 2-ethoxyethyl ester, acetic acid 2-(2-ethoxyethoxy)ethyl ester, acetic acid 3-methoxy-3-methylbutyl ester and acetic acid 1-methoxy-2-propyl ester.

As preferred alkyl pyruvates, there can be mentioned, for example, methyl pyruvate, ethyl pyruvate and propyl pyruvate.

As a preferably employable solvent, there can be mentioned a solvent having a boiling point of 130° C. or above measured at ordinary temperature under ordinary pressure. For example, there can be mentioned cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, acetic acid 2-ethoxyethyl ester, acetic acid 2-(2-ethoxyethoxy)ethyl ester or propylene carbonate.

In the present invention, these solvents may be used either individually or in combination.

In the present invention, a mixed solvent consisting of a mixture of a solvent having a hydroxyl group in its structure and a solvent having no hydroxyl group may be used as the organic solvent.

As the solvent having a hydroxyl group, there can be mentioned, for example, ethylene glycol, ethylene glycol monomethyl ether, ethylene glycol monoethyl ether, propylene glycol, propylene glycol monomethyl ether, propylene glycol monoethyl ether, ethyl lactate or the like. Of these, propylene glycol monomethyl ether and ethyl lactate are especially preferred.

As the solvent having no hydroxyl group, there can be mentioned, for example, propylene glycol monomethyl ether acetate, ethyl ethoxypropionate, 2-heptanone, γ-butyrolactone, cyclohexanone, butyl acetate, N-methylpyrrolidone, N,N-dimethylacetamide, dimethyl sulfoxide or the like. Of these, propylene glycol monomethyl ether acetate, ethyl ethoxypropionate, 2-heptanone, γ-butyrolactone, cyclohexanone and butyl acetate are especially preferred. Propylene glycol monomethyl ether acetate, ethyl ethoxypropionate and 2-heptanone are most preferred.

The mixing ratio (mass) of a solvent having a hydroxyl group and solvent having no hydroxyl group is in the range of 1/99 to 99/1, preferably 10/90 to 90/10 and more preferably 20/80 to 60/40. The mixed solvent containing 50 mass % or more of solvent having no hydroxyl group is especially preferred from the viewpoint of uniform applicability.

It is preferred that the solvent be a mixed solvent consisting of two or more types of solvents containing propylene glycol monomethyl ether acetate.

3. Second Resist

Among those described above as the first resist, an appropriate one can be employed as the second resist for use in the formation of the second resist pattern. However, it is preferred that substantially the same resin as employed in the first resist be employed in the second resist from the viewpoint of allowing the dry etching resistance of the second resist pattern to be equivalent to that of the first resist pattern. Further, from the viewpoint of allowing the first resist and the second resist to form patterns of substantially the same characteristics with the use of a practical semiconductor device mask having patterns of various sizes and configurations, it is most preferred that the first resist and the second resist consist of exactly the same resists.

Now, the process for accomplishing formation of the first resist pattern, freezing by chemical treatment of the first resist pattern and formation of the second resist pattern will be described.

<Formation of First Resist Pattern>

In the present invention, the first resist composition in the use thereof is first filtered and then applied onto the following given support. The filter medium for use in the filtration preferably consists of a polytetrafluoroethylene, polyethylene or nylon having a pore size of 0.1 μm or less, especially 0.05 μm or less and more especially 0.03 μm or less.

The resist composition having been filtered is applied onto a substrate, such as one for use in the production of precision integrated circuit elements (e.g., silicon/silicon dioxide coating), by appropriate application means, such as a spinner or coater, and dried to thereby form a resist film. In the stage of drying, it is preferred to perform heating (prebaking). The thickness of the resist film is preferably regulated so as to fall within the range of 30 to 200 nm, more preferably 40 to 180 nm.

When the resist composition is applied by a spinner, the rotating speed thereof is generally in the range of 500 to 3000 rpm, preferably 800 to 2000 rpm and more preferably 1000 to 1500 rpm.

Prior to the formation of the resist film, the substrate may be coated with an antireflection film.

As the antireflection film, use can be made of not only an inorganic film of titanium, titanium dioxide, titanium nitride, chromium oxide, carbon, amorphous silicon or the like but also an organic film composed of a light absorber and a polymer material. Also, as the organic antireflection film, use can be made of commercially available organic antireflection films, such as the DUV30 Series and DUV40 Series produced by Brewer Science Inc., and AR-2, AR-3 and AR-5 produced by Shipley Co., Ltd.

[Dry Exposure System]

The resist film is exposed through a given mask to actinic rays or radiation, preferably baked (heated), and developed and rinsed. Accordingly, a desirable pattern can be obtained.

As the actinic rays or radiation, there can be mentioned infrared rays, visible light, ultraviolet rays, far ultraviolet rays, X-rays, electron beams or the like. Of them, preferred use is made of far ultraviolet rays of especially 250 nm or less, more especially 220 nm or less and still more especially 1 to 200 nm wavelength. In particular, ArF excimer laser, F₂ excimer laser, EUV (13 nm) and electron beams are preferred. ArF excimer laser is more preferred.

[Liquid Immersion Exposure]

In the event of liquid immersion exposure, the resist film is exposed through a mask for pattern formation or the like and through a liquid for liquid immersion to light (liquid immersion exposure). For example, the exposure is carried out in the state that the interstice between resist film and optical lens is filled with a liquid for liquid immersion. After the exposure, according to necessity, the resist film is washed, preferably followed by spinning so as to remove any liquid for liquid immersion. As actinic rays or radiation, there can be mentioned infrared rays, visible light, ultraviolet rays, far ultraviolet rays, X-rays, electron beams or the like. Of them, preferred use is made of far ultraviolet rays of especially 250 nm or less, more especially 220 nm or less and still more especially 1 to 200 nm wavelength. In particular, ArF excimer laser, F₂ excimer laser, EUV (13 nm) and electron beams are preferred. ArF excimer laser is more preferred.

The liquid for liquid immersion for use in the liquid immersion exposure will be described below.

The liquid for liquid immersion preferably consists of a liquid being transparent in exposure wavelength whose refractive index variation depending on temperature is as low as possible. Especially, in the use of an ArF excimer laser (wavelength: 193 nm) as an exposure light source, however, preferred use is made of water from not only the above viewpoints but also the viewpoints of easy procurement and easy handling.

In the use of water as the liquid for liquid immersion, a slight proportion of additive (liquid) that would not dissolve the resist layer on a wafer and would be negligible with respect to its influence on an optical coat for an under surface of a lens element may be added in order to not only decrease the surface tension of water but also increase a surface activating power. The additive is preferably an aliphatic alcohol with a refractive index approximately equal to that of water, for example, methanol, ethanol, isopropanol or the like. This additive would realize such an advantage that even when the additive component is evaporated from the water to thereby cause a change of content concentration, the change of refractive index of the liquid as a whole can be minimized. On the other hand, when a substance being opaque in 193 nm rays or an impurity whose refractive index is greatly different from that of water is mixed in, the mixing could cause a distortion of optical image projected on the resist film. Accordingly, it is preferred to use distilled water as the liquid immersion water. Further, use may be made of pure water having been filtered through an ion exchange membrane or the like.

Desirably, the electrical resistance of the water is 18.3 MQcm or higher, and the TOC (organic matter concentration) thereof is 20 ppb or below. Prior deaeration of the water is desired.

Increasing the refractive index of the liquid for liquid immersion would enable an enhancement of lithography performance. From this viewpoint, an additive suitable for refractive index increase may be added to the water, or heavy water (D₂O) may be used in place of water.

For the prevention of direct contact of the resist film with the liquid for liquid immersion, a film highly insoluble in the liquid for liquid immersion (hereinafter also referred to as a “top coat”) may be provided between the resist film and the liquid for liquid immersion. The functions to be fulfilled by the top coat include applicability to an upper layer portion of the resist (uniform applicability), transparency in radiation, especially rays of 193 nm wavelength, and being highly insoluble in the liquid for liquid immersion.

From the viewpoint of transparency in rays of 193 nm wavelength, the top coat preferably consists of a polymer containing no aromatic moiety. As such, there can be mentioned, for example, a hydrocarbon polymer, an acrylic ester polymer, polymethacrylic acid, polyacrylic acid, polyvinyl ether, a siliconized polymer, a fluoropolymer or the like.

At the detachment of the top coat, use may be made of a developer, or a separate peeling agent may be used. The peeling agent preferably consists of a solvent of lower permeation into the resist film. Detachability caused by an alkali developer is preferred from the viewpoint of simultaneous attainment of the detachment step with the development processing step for the resist. The top coat is preferred to be acidic from the viewpoint of detachment with the use of an alkali developer. However, from the viewpoint of non-intermixability with the resist, the top coat may be neutral or alkaline.

In the event of liquid immersion exposure, in place of the top coat or in cooperation with the top coat, any of the later-described hydrophobic resins (HR) may be added to the resist composition before formation of a resist film and subsequent liquid immersion exposure.

This would bring about uneven localization of the hydrophobic resin (HR) on the surface layer of the resist film. When the liquid immersion medium is water, there would be attained an improvement of receding contact angle on the surface of the resist film with reference to water upon formation of the resist film and accordingly an enhancement of liquid immersion water follow property. The hydrophobic resin (HR) is a resin whose addition would realize an improvement of receding contact angle on the surface, preferably a resin having at least either a fluorine atom or a silicon atom. The receding contact angle of the resist film is preferably in the range of 60° to 90°, more preferably 70° or greater. The amount of resin added can be appropriately regulated so that the receding contact angle of the resist film falls within the above range. However, the addition amount is preferably in the range of 0.1 to 10 mass %, more preferably 0.1 to 5 mass % based on the total solid content of the resist composition. Although the hydrophobic resin (HR) is unevenly localized on any interface, as different from the surfactant, the hydrophobic resin does not necessarily have to have a hydrophilic group in its molecule and does not need to contribute toward uniform mixing of polar/nonpolar substances.

When the hydrophobic resin (HR) is a resin having at least either a fluorine atom or a silicon atom, it is preferably a resin having a fluorine-atom-including alkyl group, a fluorine-atom-having cycloalkyl group or a fluorine-atom-including aryl group.

The fluorine-atom-including alkyl group (preferably having 1 to 10 carbon atoms, more preferably 1 to 4 carbon atoms) is a linear or branched alkyl group having at least one hydrogen atom thereof substituted with a fluorine atom. Other substituents may also be contained.

The fluorine-atom-including cycloalkyl group is a cycloalkyl group of a single ring or multiple rings having at least one hydrogen atom thereof substituted with a fluorine atom. Other substituents may also be included.

As the fluorine-atom-including aryl group, there can be mentioned one having at least one hydrogen atom of an aryl group, such as a phenyl or naphthyl group, thereof substituted with a fluorine atom. Other substituents may also be included.

As preferred fluorine-atom-including alkyl groups, fluorine-atom-including cycloalkyl groups and fluorine-atom-including aryl groups, there can be mentioned groups of the following general formulae (F2) to (F4), which however in no way limit the scope of the present invention.

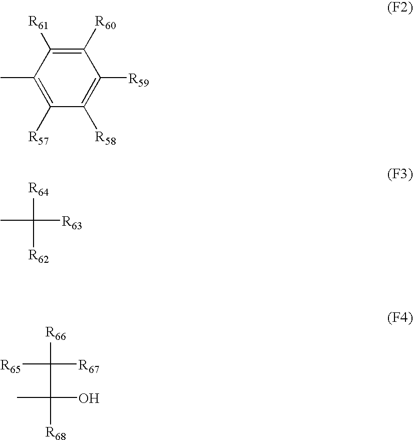

In the general formulae (F2) to (F4),

each of R₅₇ to R₆₈ independently represents a hydrogen atom, a fluorine atom or an alkyl group, provided that at least one of each of R₅₇-R₆₁, R₆₂-R₆₄ and R₆₅-R₆₈ represents a fluorine atom or an alkyl group (preferably having 1 to 4 carbon atoms) having at least one hydrogen atom thereof substituted with a fluorine atom. It is preferred that all of R₅₇-R₆₁ and R₆₅-R₆₇ represent fluorine atoms. Each of R₆₂, R₆₃ and R₆₈ preferably represents an alkyl group (especially having 1 to 4 carbon atoms) having at least one hydrogen atom thereof substituted with a fluorine atom, more preferably a perfluoroalkyl group having 1 to 4 carbon atoms. R₆₂ and R₆₃ may be bonded with each other to thereby form a ring.

As specific examples of the groups of the general formula (F2), there can be mentioned, for example, a p-fluorophenyl group, a pentafluorophenyl group, a 3,5-di(trifluoromethyl)phenyl group and the like.

Specific examples of the groups of the general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group and the like. Of these, a hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred. A hexafluoroisopropyl group and a heptafluoroisopropyl group are more preferred.

As specific examples of the groups of the general formula (F4), there can be mentioned, for example, —C(CF₃)₂OH, —C(C₂F₅)₂OH, —C(CF₃)(CH₃)OH, —CH(CF₃)OH and the like. —C(CF₃)₂OH is preferred.

The hydrophobic resin (HR) is preferably a resin having an alkylsilyl structure (preferably a trialkylsilyl group) or a cyclosiloxane structure as a partial structure having a silicon atom.

As the alkylsilyl structure or cyclosiloxane structure, there can be mentioned, for example, any of the groups of the following general formulae (CS-1) to (CS-3) or the like.

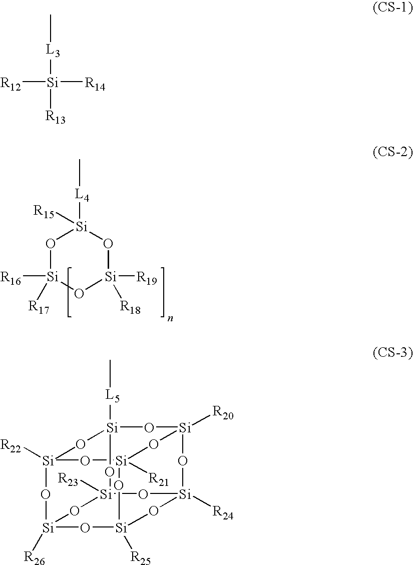

In the general formulae (CS-1) to (CS-3),

each of R₁₂ to R₂₆ independently represents a linear or branched alkyl group (preferably having 1 to 20 carbon atoms) or a cycloalkyl group (preferably having 3 to 20 carbon atoms).

Each of L₃ to L₅ represents a single bond or a bivalent connecting group. As the bivalent connecting group, there can be mentioned any one or a combination of two or more groups selected from the group consisting of an alkylene group, a phenylene group, an ether group, a thioether group, a carbonyl group, an ester group, an amido group, a urethane group and a urea group.

In the formulae, n is an integer of 1 to 5.

Moreover, the hydrophobic resin (HR) may have at least one group selected from among the following groups (x) to (z):

(x) an alkali soluble group,

(y) a group that is decomposed by the action of an alkali developer, resulting in an increase of solubility in the alkali developer, and

(z) a group that is decomposed by the action of an acid.

As the alkali soluble group (x), there can be mentioned, for example, any of groups having a phenolic hydroxyl group, a carboxylate group, a fluoroalcohol group, a sulfonate group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group and a tris(alkylsulfonyl)methylene group.

As preferred alkali soluble groups, there can be mentioned a fluoroalcohol group (preferably hexafluoroisopropanol), a sulfonimido group and a bis(carbonyl)methylene group.

As the repeating unit having an alkali soluble group (x), preferred use is made of any of a repeating unit resulting from direct bonding of an alkali soluble group to a principal chain of resin like a repeating unit of an acrylic acid or methacrylic acid, a repeating unit resulting from bonding, via a connecting group, of an alkali soluble group to a principal chain of a resin and a repeating unit resulting from polymerization with the use of a chain transfer agent or polymerization initiator having an alkali soluble group to thereby attain introduction in a polymer chain terminal.

The content of repeating units having an alkali soluble group (x) is preferably in the range of 1 to 50 mol %, more preferably 3 to 35 mol % and still more preferably 5 to 20 mol % based on all the repeating units of the hydrophobic resin (HR).

As the group (y) that is decomposed by the action of an alkali developer, resulting in an increase of solubility in the alkali developer, there can be mentioned, for example, a group having a lactone structure, an acid anhydride, an acid imido group or the like. A lactone group is preferred.

As the repeating unit having a group (y) that is decomposed by the action of an alkali developer, resulting in an increase of solubility in the alkali developer, preferred use is made of both of a repeating unit resulting from bonding of a group (y) that is decomposed by the action of an alkali developer, resulting in an increase of solubility in the alkali developer, to a principal chain of resin like a repeating unit of an acrylic ester or methacrylic ester and a repeating unit resulting from polymerization with the use of a chain transfer agent or polymerization initiator having a group (y) capable of increase of solubility in an alkali developer to thereby attain introduction in a polymer chain terminal.

The content of repeating units having a group (y) capable of increase of solubility in an alkali developer is preferably in the range of 1 to 40 mol %, more preferably 3 to 30 mol % and still more preferably 5 to 15 mol % based on all the repeating units of the hydrophobic resin (HR).

As specific examples of the repeating units having a group (y) capable of increase of solubility in an alkali developer, there can be mentioned those similar to the repeating units having a lactone structure set forth in the section “2. First resist.”

As the repeating unit having a group (z) that is decomposed by the action of an acid in the hydrophobic resin (HR), there can be mentioned those similar to the repeating units having an acid decomposable group set forth in the section “2. First resist.” The content of repeating units having a group (z) that is decomposed by the action of an acid in the hydrophobic resin (HR) is preferably in the range of 1 to 80 mol %, more preferably 10 to 80 mol % and still more preferably 20 to 60 mol % based on all the repeating units of the hydrophobic resin (HR).

The hydrophobic resin (HR) may further have any of the repeating units of the following general formula (IV).

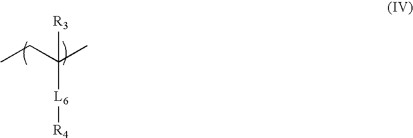

In the general formula (IV),

R₃ represents a hydrogen atom, an alkyl group, an alkyl group optionally substituted with a fluorine atom, a cyano group or a group of the formula —CH₂—O—R₂ in which R₂ represents a hydrogen atom, an alkyl group or an acyl group.

R₄ represents a group having any of an alkyl group, a cycloalkyl group, an alkenyl group and a cycloalkenyl group.

L₆ represents a single bond or a bivalent connecting group.

In the general formula (IV), the alkyl group represented by R₄ is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The bivalent connecting group represented by L₆ is preferably an alkylene group (preferably having 1 to 5 carbon atoms) or an oxy group.

When the hydrophobic resin (HR) has a fluorine atom, the content of fluorine atom is preferably in the range of 5 to 80 mass %, more preferably 10 to 80 mass %, based on the molecular weight of the hydrophobic resin (HR). The repeating unit containing a fluorine atom is preferably present in the hydrophobic resin (HR) in an amount of 10 to 100 mass %, more preferably 30 to 100 mass %.

When the hydrophobic resin (HR) has a silicon atom, the content of silicon atoms is preferably in the range of 2 to 50 mass %, more preferably 2 to 30 mass %, based on the molecular weight of the hydrophobic resin (HR). The repeating unit containing a silicon atom is preferably present in the hydrophobic resin (HR) in an amount of 10 to 100 mass %, more preferably 20 to 100 mass %.

The weight average molecular weight of the hydrophobic resin (HR) in terms of standard polystyrene molecular weight is preferably in the range of 1,000 to 100,000, more preferably 1,000 to 50,000 and still more preferably 2,000 to 15,000.

Impurities, such as metals, should naturally be in low quantities in the hydrophobic resin (HR), as in the resin (A). The content of residual monomers and oligomer components is preferably 0 to 10 mass %, more preferably 0 to 5 mass % and still more preferably 0 to 1 mass %. Accordingly, there can be obtained a resist being free from a change over time of in-liquid foreign matter, sensitivity, etc. From the viewpoint of resolving power, resist profile, side wall of resist pattern, roughness, etc., the molecular weight distribution (Mw/Mn, also referred to as the degree of dispersal) thereof is preferably in the range of 1 to 5, more preferably 1 to 3 and still more preferably 1 to 2.

A variety of commercially available products can be used as the hydrophobic resin (HR), and also the resin can be synthesized in accordance with customary methods. The methods of synthesizing and purifying the hydrophobic resin for use in the first resist and second resist can be the same as those mentioned above for the resin (A) that is decomposed by the action of an acid, resulting in an increase of solubility in an alkali developer.

Specific examples of the hydrophobic resins (HR) will be shown below. The following Table 1 will indicate the molar ratios of individual repeating units (corresponding to individual repeating units in the order from the left), weight average molecular weight and degree of dispersal with respect to each of the resins.

TABLE 1

| | |
|---|---|
| | (HR-1) |
| 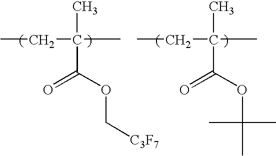 | |
| | (HR-2) |
| 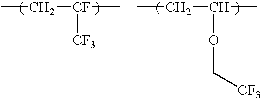 | |
| | (HR-3) |
| 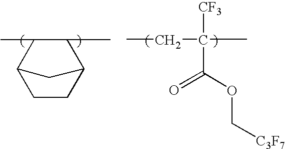 | |
| | (HR-4) |
| 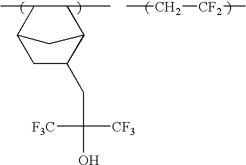 | |
| | (HR-5) |
| 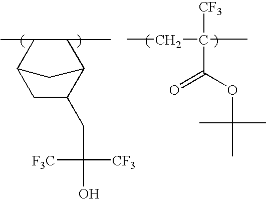 | |
| | (HR-6) |
| 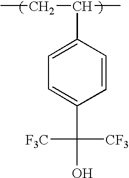 | |
| | (HR-7) |
| 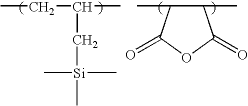 | |
| | (HR-8) |
| 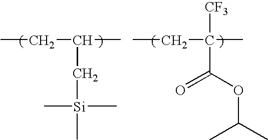 | |
| | (HR-9) |
| 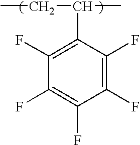 | |
| | (HR-10) |
| 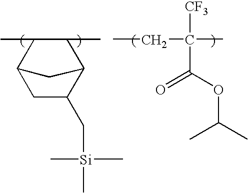 | |
| | (HR-11) |
| 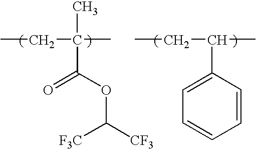 | |
| | (HR-12) |
| 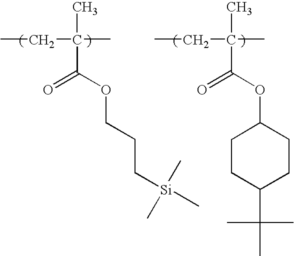 | |
| | (HR-13) |
| 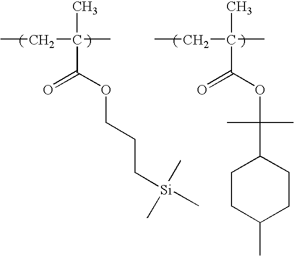 | |
| | (HR-14) |
| 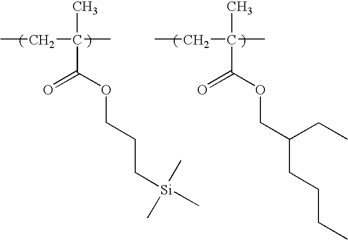 | |
| | (HR-15) |
| 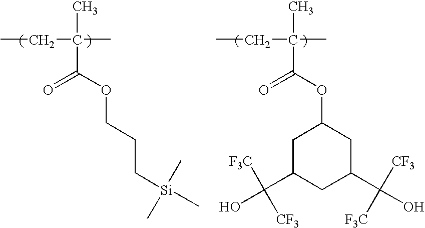 | |
| | (HR-16) |
| 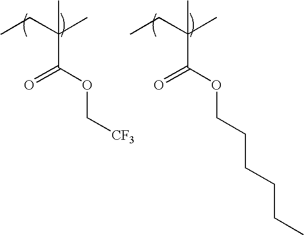 | |
| | (HR-17) |
| 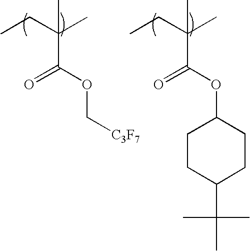 | |
| | (HR-18) |
| 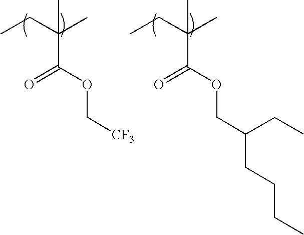 | |
| | (HR-19) |
| 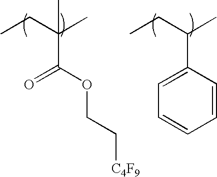 | |
| | (HR-20) |
| 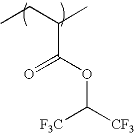 | |
| | (HR-21) |
| 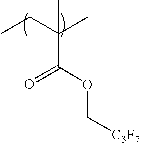 | |
| | (HR-22) |
| 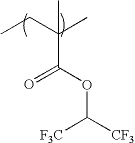 | |
| | (HR-23) |
| 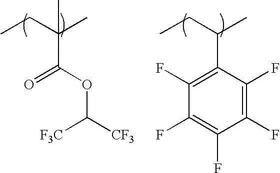 | |
| | (HR-24) |
| 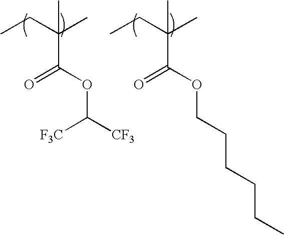 | |
| | (HR-25) |
| 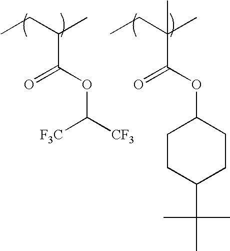 | |
| | (HR-26) |
| 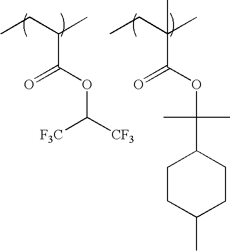 | |
| | (HR-27) |
| 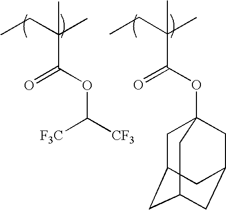 | |
| | (HR-28) |
| 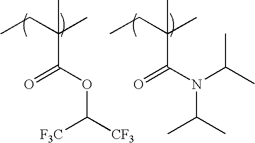 | |
| | (HR-29) |
| 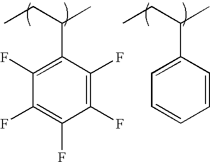 | |
| | (HR-30) |
| 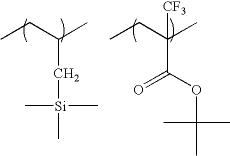 | |
| | (HR-31) |
| 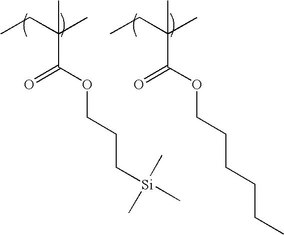 | |
| | (HR-32) |
| 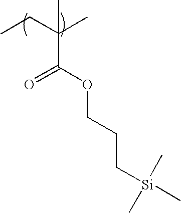 | |
| | (HR-33) |
| 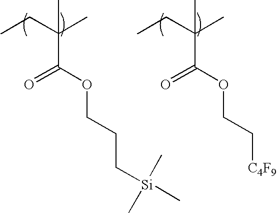 | |
| | (HR-34) |
| 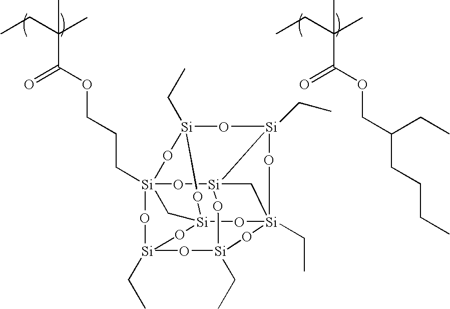 | |
| | (HR-35) |
| 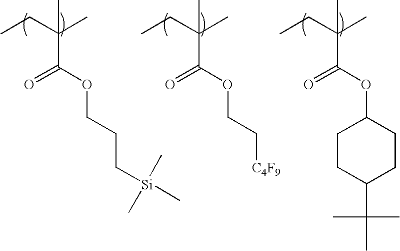 | |
| | (HR-36) |
| 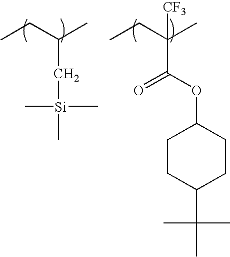 | |
| | (HR-37) |
| 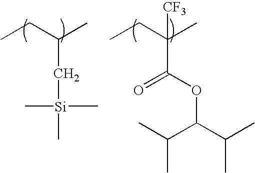 | |
| | (HR-38) |
| 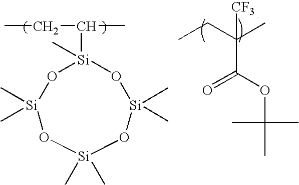 | |
| | (HR-39) |
| 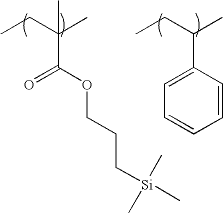 | |
| | (HR-40) |
| 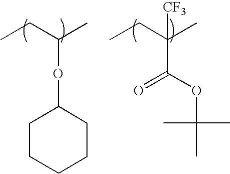 | |
| | (HR-41) |
| 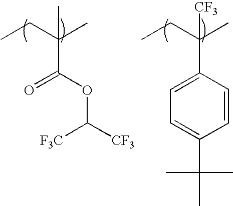 | |
| | (HR-42) |
| 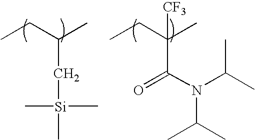 | |
| | (HR-43) |
| 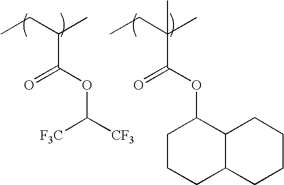 | |
| | (HR-44) |
| 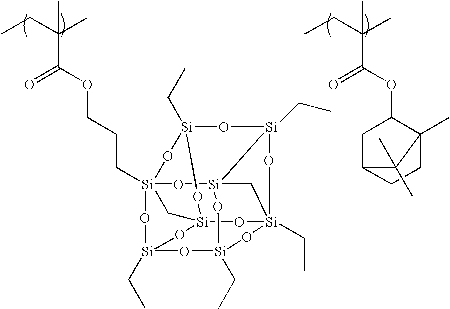 | |
| | (HR-45) |
| 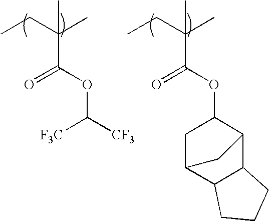 | |
| | (HR-46) |
| 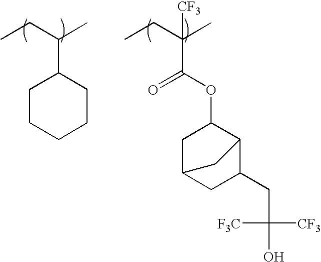 | |
| | (HR-47) |
| 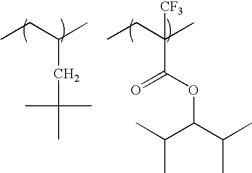 | |
| | (HR-48) |
| 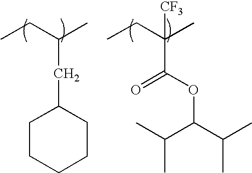 | |
| | (HR-49) |
| 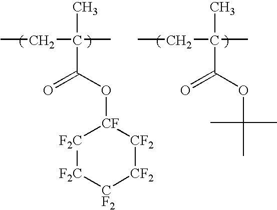 | |
| | (HR-50) |
| 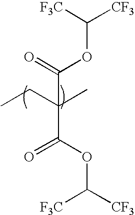 | |
| | (HR-51) |
| 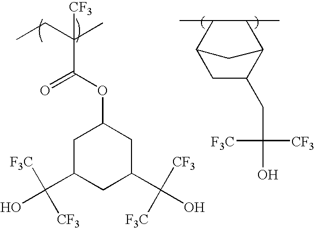 | |
| | (HR-52) |
| 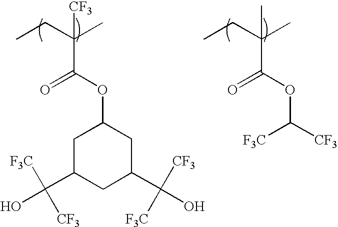 | |
| | (HR-53) |
| 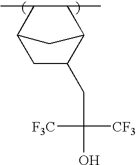 | |
| | (HR-54) |
| 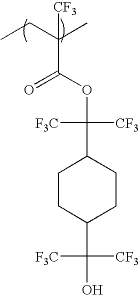 | |
| | (HR-55) |
| 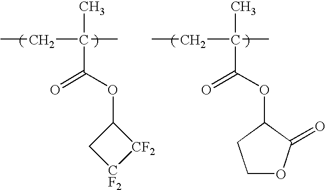 | |
| | (HR-56) |
| 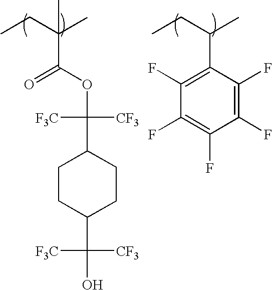 | |
| | (HR-57) |
| 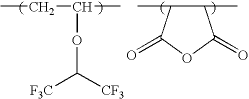 | |
| | (HR-58) |
| 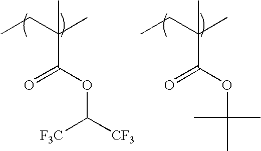 | |
| | (HR-59) |
| 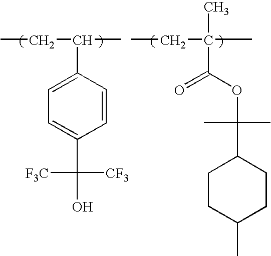 | |
| | (HR-60) |
| 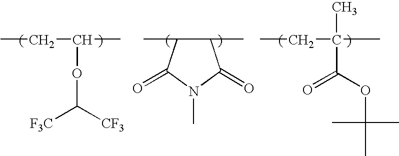 | |
| | (HR-61) |
| 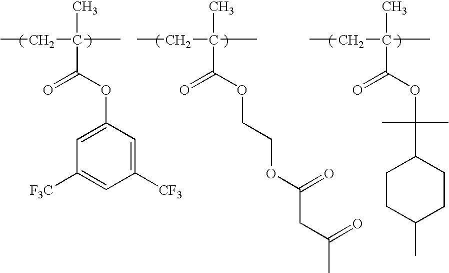 | |
| | (HR-62) |
| 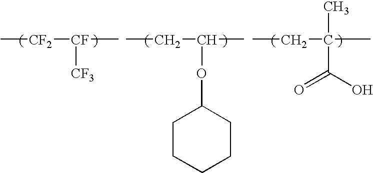 | |
| | (HR-63) |
| 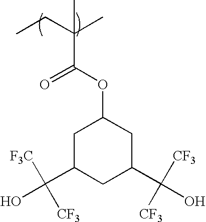 | |
| | (HR-64) |
| 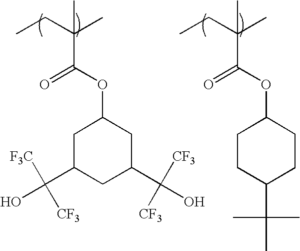 | |
| | (HR-65) |
| 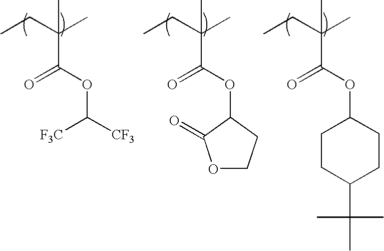 | |
| | (HR-66) |
| 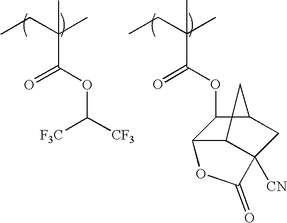 | |
| | (HR-67) |
| 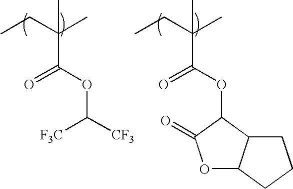 | |
| | (HR-68) |
| 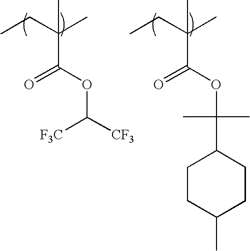 | |
| | (HR-69) |
| 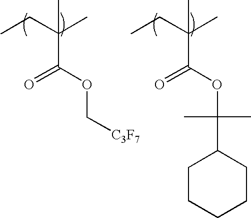 | |
| | (HR-70) |
| 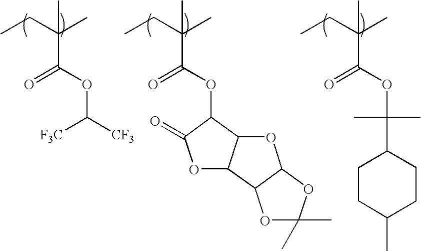 | |
| | (HR-71) |
| 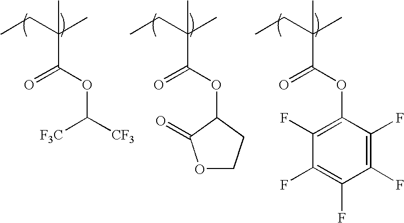 | |
| | (HR-72) |
| 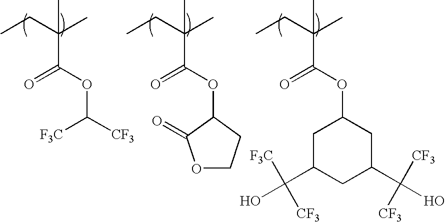 | |
| | (HR-73) |
| 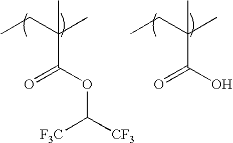 | |
| | (HR-74) |
| 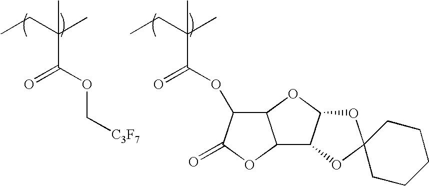 | |
| | (HR-75) |
| 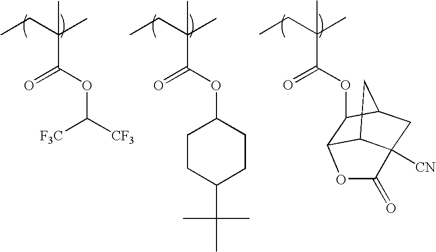 | |
| | (HR-76) |
| 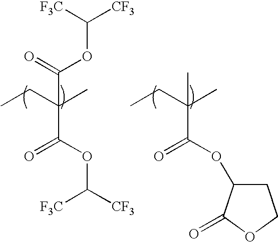 | |
| | (HR-77) |
| 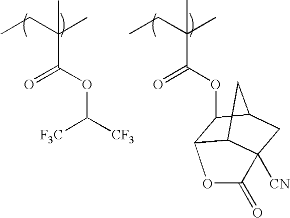 | |
| | (HR-78) |
| 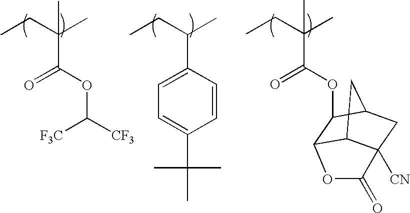 | |
| | (HR-79) |
| 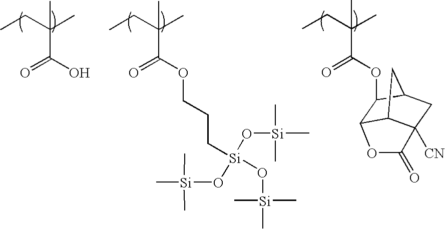 | |
| | (HR-80) |
| 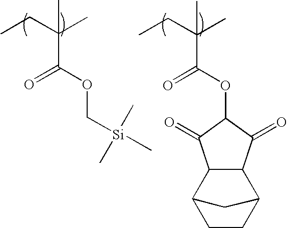 | |
| | (HR-81) |
| 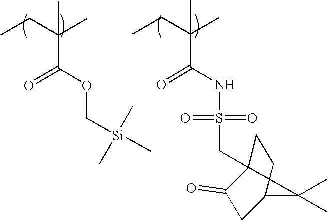 | |
| | (HR-82) |
| 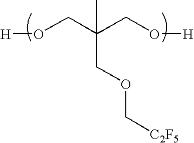 | |
| | (HR-83) |
| 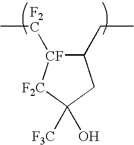 | |
| | (HR-84) |
| 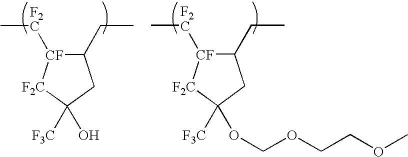 | |

| Resin | Comp. | Mw | Mw/Mn |
|---|---|---|---|
| HR-1 | 50/50 | 8800 | 2.1 |
| HR-2 | 50/50 | 5200 | 1.8 |
| HR-3 | 50/50 | 4800 | 1.9 |
| HR-4 | 50/50 | 5300 | 1.9 |
| HR-5 | 50/50 | 6200 | 1.9 |
| HR-6 | 100 | 12000 | 2.0 |
| HR-7 | 50/50 | 5800 | 1.9 |
| HR-8 | 50/50 | 6300 | 1.9 |
| HR-9 | 100 | 5500 | 2.0 |
| HR-10 | 50/50 | 7500 | 1.9 |
| HR-11 | 70/30 | 10200 | 2.2 |
| HR-12 | 40/60 | 15000 | 2.2 |
| HR-13 | 40/60 | 13000 | 2.2 |
| HR-14 | 80/20 | 11000 | 2.2 |
| HR-15 | 60/40 | 9800 | 2.2 |
| HR-16 | 50/50 | 8000 | 2.2 |
| HR-17 | 50/50 | 7600 | 2.0 |
| HR-18 | 50/50 | 12000 | 2.0 |
| HR-19 | 20/80 | 6500 | 1.8 |
| HR-20 | 100 | 6500 | 1.2 |
| HR-21 | 100 | 6000 | 1.6 |
| HR-22 | 100 | 2000 | 1.6 |
| HR-23 | 50/50 | 6000 | 1.7 |
| HR-24 | 50/50 | 8800 | 1.9 |
| HR-25 | 50/50 | 7800 | 2.0 |
| HR-26 | 50/50 | 8000 | 2.0 |
| HR-27 | 80/20 | 8000 | 1.8 |
| HR-28 | 30/70 | 7000 | 1.7 |
| HR-29 | 50/50 | 6500 | 1.6 |
| HR-30 | 50/50 | 6500 | 1.6 |
| HR-31 | 50/50 | 9000 | 1.8 |
| HR-32 | 100 | 10000 | 1.6 |
| HR-33 | 70/30 | 8000 | 2.0 |
| HR-34 | 10/90 | 8000 | 1.8 |
| HR-35 | 30/30/40 | 9000 | 2.0 |
| HR-36 | 50/50 | 6000 | 1.4 |
| HR-37 | 50/50 | 5500 | 1.5 |
| HR-38 | 50/50 | 4800 | 1.8 |
| HR-39 | 60/40 | 5200 | 1.8 |
| HR-40 | 50/50 | 8000 | 1.5 |
| HR-41 | 20/80 | 7500 | 1.8 |
| HR-42 | 50/50 | 6200 | 1.6 |
| HR-43 | 60/40 | 16000 | 1.8 |
| HR-44 | 80/20 | 10200 | 1.8 |
| HR-45 | 50/50 | 12000 | 2.6 |
| HR-46 | 50/50 | 10900 | 1.9 |
| HR-47 | 50/50 | 6000 | 1.4 |
| HR-48 | 50/50 | 4500 | 1.4 |
| HR-49 | 50/50 | 6900 | 1.9 |
| HR-50 | 100 | 2300 | 2.6 |
| HR-51 | 60/40 | 8800 | 1.5 |
| HR-52 | 68/32 | 11000 | 1.7 |
| HR-53 | 100 | 8000 | 1.4 |
| HR-54 | 100 | 8500 | 1.4 |
| HR-55 | 80/20 | 13000 | 2.1 |
| HR-56 | 70/30 | 18000 | 2.3 |
| HR-57 | 50/50 | 5200 | 1.9 |
| HR-58 | 50/50 | 10200 | 2.2 |
| HR-59 | 60/40 | 7200 | 2.2 |
| HR-60 | 32/32/36 | 5600 | 2.0 |
| HR-61 | 30/30/40 | 9600 | 1.6 |
| HR-62 | 40/40/20 | 12000 | 2.0 |
| HR-63 | 100 | 6800 | 1.6 |
| HR-64 | 50/50 | 7900 | 1.9 |
| HR-65 | 40/30/30 | 5600 | 2.1 |
| HR-66 | 50/50 | 6800 | 1.7 |
| HR-67 | 50/50 | 5900 | 1.6 |
| HR-68 | 49/51 | 6200 | 1.8 |
| HR-69 | 50/50 | 8000 | 1.9 |
| HR-70 | 30/40/30 | 9600 | 2.3 |
| HR-71 | 30/40/30 | 9200 | 2.0 |
| HR-72 | 40/29/31 | 3200 | 2.1 |
| HR-73 | 90/10 | 6500 | 2.2 |
| HR-74 | 50/50 | 7900 | 1.9 |
| HR-75 | 20/30/50 | 10800 | 1.6 |
| HR-76 | 50/50 | 2200 | 1.9 |
| HR-77 | 50/50 | 5900 | 2.1 |
| HR-78 | 40/20/30/10 | 14000 | 2.2 |
| HR-79 | 50/50 | 5500 | 1.8 |
| HR-80 | 50/50 | 10600 | 1.9 |
| HR-81 | 50/50 | 8600 | 2.3 |
| HR-82 | 100 | 15000 | 2.1 |
| HR-83 | 100 | 6900 | 2.5 |
| HR-84 | 50/50 | 9900 | 2.3 |

After the foregoing dry exposure or liquid immersion exposure, post-baking (post-heating) is preferably carried out, followed by development and rinsing. Accordingly, a favorable pattern can be obtained.

In the development step, an alkali developer is usually employed. As the alkali developer for the resist composition, use can be made of any of alkaline aqueous solutions of an inorganic alkali such as sodium hydroxide, potassium hydroxide, sodium carbonate, sodium silicate, sodium metasilicate or aqueous ammonia, a primary amine such as ethylamine or n-propylamine, a secondary amine such as diethylamine or di-n-butylamine, a tertiary amine such as triethylamine or methyldiethylamine, an alcoholamine such as dimethylethanolamine or triethanolamine, a quaternary ammonium salt such as tetramethylammonium hydroxide or tetraethylammonium hydroxide, a cycloamine such as pyrrole or piperidine, or the like.

Before the use of the above alkali developer, appropriate amounts of an alcohol and a surfactant may be added thereto.

The alkali concentration of the alkali developer is generally in the range of 0.1 to 20 mass %.

The pH value of the alkali developer is generally in the range of 10.0 to 15.0.

Pure water is usually employed as a rinse liquid. Before the use thereof, an appropriate amount of surfactant may be added thereto.

The development operation or rinse operation may be followed by the operation for removing any developer or rinse liquid adhering onto the pattern by the use of a supercritical fluid.

Further, the rinse operation or operation with a supercritical fluid may be followed by the heating operation for removing any water remaining in the pattern.

<Chemical Treatment of First Resist Pattern>

The formation of a first resist pattern by the use of the foregoing process is followed by a chemical treatment (freezing treatment) of the first resist pattern by the use of the treating agent according to the present invention.

[Washing with Acid]

First, the first resist pattern is preferably washed with a solution containing an acid other than the treating agent of the present invention. The acid for use in the washing is preferably an acid of 4 or below pKa. The use of this relatively strong acid would attain returning of the acidic functional group (e.g., carboxyl group) of the first resist pattern that has been neutralized by the alkali developer and thus has been ionized to an acidic group, so that the chemical species contained in the surface treating agent of the present invention can be efficiently adsorbed on the resist pattern.

In practice, the pKa value of the acid for use in the washing can be actually measured through the determination of an acid dissociation constant at 25° C. using an infinitely diluted aqueous solution. Alternatively, the value based on values quoted in publicly available literature values and Hammett's substituent constant can be determined by calculation with the use of a software package (for example, Advanced Chemistry Development (ACD/Labs) Software V8.14 for Solaris (1994-2007 ACD/Labs)).

As specific examples of the acids that can be employed in the washing, there can be mentioned an inorganic acid, such as hydrochloric acid, sulfuric acid, nitric acid or phosphoric acid, and an organic acid, such as a carboxylic acid, a sulfonic acid, a sulfonylimide acid or a methide acid.

As the carboxylic acid, there can be mentioned, for example, an alkyl carboxylic acid such as acetic acid or propionic acid, a fluoroalkyl carboxylic acid such as a perfluoroalkyl carboxylic acid having 1 to 8 carbon atoms, or an aromatic carboxylic acid such as benzoic acid or pentafluorobenzoic acid.

As the sulfonic acid, there can be mentioned, for example, an alkyl sulfonic acid such as butanesulfonic acid, hexanesulfonic acid or a perfluoroalkyl sulfonic acid having 1 to 8 carbon atoms, or an aromatic sulfonic acid such as p-toluenesulfonic acid or pentafluorobenzenesulfonic acid.

As the sulfonylimide acid, there can be mentioned, for example, a disulfonylimide acid, such as a bis(alkylsulfonyl)imide acid having 1 to 8 carbon atoms, a bis(perfluoroalkylsulfonyl)imide acid having 1 to 8 carbon atoms, a 5 to 8-membered ring cyclodisulfonylimide acid or a 5 to 8-membered ring cyclodisulfonylimide acid having a fluoroalkylene chain.

As the methide acid, there can be mentioned, for example, a trisulfonymethide acid, such as a tris(alkylsulfonyl)methide acid having 1 to 8 carbon atoms or a tris(fluoroalkylsulfonyl)methide acid having 1 to 8 carbon atoms.

Of these, a perfluoroalkyl carboxylic acid, a sulfonic acid, an imide acid and a methide acid are preferred. A perfluoroalkyl sulfonic acid, an aromatic sulfonic acid, an imide acid and a methide acid are more preferred. An aromatic sulfonic acid is especially preferred.

The solvent of this solution is not limited as long as no resist pattern is dissolved therein but acids are dissolved therein. For example, there can be mentioned water or any of the solvents for use in the treating agent of the present invention. Preferred use is made of any of the solvents for use in the treating agent of the present invention.

The concentration of acid is in the range of 0.1 to 10 mol %, preferably 0.5 to 5 mol % and more preferably 0.5 to 3 mol %.

In a preferred method of treatment, the acid solution is puddled over the substrate having the first resist pattern formed thereon, and after a while the substrate is rotated to thereby shake off the acid solution. The resultant substrate is washed with a solvent.

The time during which by the puddling of the acid solution the acid solution is in contact with the resist pattern is to be 5 sec or longer. Generally, the longer the time, the more favorable the washing effect. However, from the viewpoint of throughput, the time is preferably 3 min or less, more preferably 2 min or less and most preferably 1 min or less.

With respect to the solvent for use in the washing of the substrate with a solvent in order to remove any excess acid from the substrate, it is preferred to employ the same solvent as used in the acid solution.

The washing method for any excess acid is preferably one in which while the substrate is rotated at a speed of 50 to 500 rpm, the solvent is spouted toward the center of the substrate at a flow rate of 0.5 to 5 ml/sec for 5 to 30 sec and thereafter the substrate is rotated at a speed of 500 to 3000 rpm for 10 to 60 sec to thereby shake off the solvent. The washing method is not limited to this.

Further, in order to uniformize the density of an acidic functional group over the whole pattern, a heating step may be added before or after the washing. When the heating step is added, the step is more effective before the washing than after the washing. The heating temperature is in the range of 40° to 150° C., preferably 500 to 140° C. and more preferably 60° to 130° C. The heating time is in the range of 20 to 180 sec, preferably 30 to 120 sec and more preferably 40 to 90 sec.

[Chemical Treatment]

The method of chemically treating the first resist pattern with the use of the treating agent of the present invention will be described below.

As the method for bringing the treating agent into contact with the resist pattern, there can be mentioned the method in which the resist pattern is immersed in the treating agent and the method in which the treating agent is applied onto the resist pattern.

In the employment of the immersion method, it is preferred to adopt the method in which the treating agent is puddled on the substrate having the first resist pattern formed thereon.

The time during which by the puddling of the treating agent on the substrate the treating agent is in contact with the resist pattern is to be 5 sec or longer. Generally, the longer the time, the more favorable the treatment effect. However, from the viewpoint of throughput, the time is preferably 3 min or less, more preferably 2 min or less and most preferably 1 min or less.

In the stage of treating agent immersion or application, the temperature within the treating apparatus and the temperature of the treating agent can be increased over room temperature in order to ensure progress of the reaction. However, from the viewpoint of safety, the temperature is preferably 50° C. or below.

After contact with the treating agent, preferably, the substrate is washed with a solvent in order to remove any excess chemical species from the substrate. If this is done, it is preferred to employ the same solvent as used in the treating agent.

The washing method is preferably one in which while the substrate is rotated at a speed of 50 to 500 rpm, the solvent is spouted toward the center of the substrate at a flow rate of 0.5 to 5 ml/sec for 5 to 30 sec and thereafter the substrate is rotated at a speed of 500 to 3000 rpm for 10 to 60 sec to thereby shake off the solvent. The washing method is not limited to this.

With respect to the method of applying the treating agent on the resist pattern, spin coating is preferably employed.

Preferably, the application of the treating agent is carried out by the method in which while the substrate is rotated at a speed of 50 to 500 rpm, the solvent is spouted toward the center of the substrate at a flow rate of 0.5 to 5 ml/sec for 0.5 to 5 sec and thereafter the substrate is rotated at a speed of 500 to 3000 rpm for 10 to 60 sec to thereby shake off the solvent.

Even in the event of chemical treatment by spin coating, preferably, the substrate is washed with a solvent in order to remove any excess chemical species from the substrate. If this is done, it is preferred to employ the same solvent as used in the treating agent. The washing method is preferably one in which while the substrate is rotated at a speed of 50 to 500 rpm, the solvent is spouted toward the center of the substrate at a flow rate of 0.5 to 5 ml/sec for 5 to 30 sec and thereafter the substrate is rotated at a speed of 500 to 3000 rpm for 10 to 60 sec to thereby shake off the solvent. The washing method is not limited to this.

Further, from the viewpoint of attainment of a maximized advance of reaction between the treating agent and resist pattern and/or polymerization reaction of the treating agent, it is preferred to heat the substrate.

The heating temperature is preferably in the range of 60° C. to 200° C., more preferably 800 to 180° C. and most preferably 100° C. to 160° C. The heating time is preferably in the range of 30 to 120 sec, more preferably 40 to 100 sec.

After the heating, the substrate is cooled. Preferably, the substrate is further washed with a solvent in order to remove any excess treating agent and any reaction by-products. As this solvent, it is preferred to employ the same solvent as in the treating agent or the first resist.

The washing method is preferably one in which while the substrate is rotated at a speed of 50 to 500 rpm, the solvent is spouted toward the center of the substrate at a flow rate of 0.5 to 5 ml/sec for 5 to 30 sec and thereafter the substrate is rotated at a speed of 500 to 3000 rpm for 10 to 60 sec to thereby shake off the solvent. The washing method is not limited to this.

Still further, it is preferred to add a heating step for removing any remaining washing solvent. The heating temperature is preferably in the range of 60° to 200° C., more preferably 700 to 170° C. and most preferably 80° to 150° C. The heating time is preferably in the range of 30 to 120 sec, more preferably 40 to 100 sec.

<Formation of Second Resist Pattern>

In the present invention, the second resist composition for use is filtered and applied onto the substrate provided with the first resist pattern that has undergone the chemical treatment. The filtration is the same as in the first resist pattern.

The second resist composition is applied onto the first resist pattern having undergone the chemical treatment (freezing treatment) in the same manner as in the formation of the first resist pattern, thereby forming a resist film. In the subsequent steps for the formation of the second resist pattern including drying (prebaking), exposure, post-baking, development and rinsing, the same procedure as described with respect to the method of forming the first resist pattern is applicable. Thus, a second resist pattern other than the first resist pattern can be formed.

### EXAMPLES

Now, the present invention will be described in greater detail with reference to Examples, which however in no way limit the scope of the present invention.

<Synthesis of Resins>

Synthesis of Resin (1)

In a nitrogen stream, 8.4 g of methyl isobutyl ketone was placed in a three-necked flask and heated at 80° C. A solution obtained by dissolving 9.4 g of 2-methyl-2-adamantyl methacrylate, 4.7 g of 3-hydroxy-1-adamantyl methacrylate, 6.8 g of β-methacryloyloxy-γ-butyrolactone and 6 mol %, based on the total amount of monomers, of azobisisobutyronitrile in 75.3 g of methyl isobutyl ketone was dropped thereinto over a period of 6 hours. After the completion of the dropping, reaction was continued at 80° C. for 2 hours. The reaction mixture was allowed to stand to cool and was poured into a mixture of 720 ml of heptane and 80 ml of ethyl acetate. The thus-precipitated powder was collected by filtration and dried, thereby obtaining 18.1 g of resin (1).

As a result of GPC measurement using a polystyrene standard, the weight average molecular weight (Mw) of the obtained resin was found to be 10,500. The degree of dispersal (Mw/Mn) thereof was 1.51.

<Synthesis of Resins (2) and (3)>

Resins (2) and (3) were synthesized by the same synthetic method as employed for the resin (1).

With respect to each of the obtained resins (1) to (3), the composition, component ratio, weight average molecular weight (Mw) and degree of dispersal (Mw/Mn) are given in Table 2.

TABLE 2

| | | | | Component ratio | | |
|---|---|---|---|---|---|---|
| Resin | Monomer 1 | Monomer 2 | Monomer 3 | (Monomer 1/Monomer 2/Monomer 3) | Mw | Mw/Mn |
| 1 | 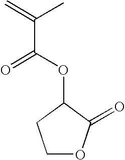 | 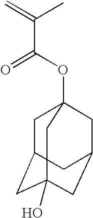 | 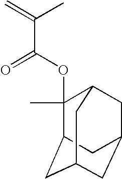 | 40/20/40 | 10500 | 1.51 |
| 2 | 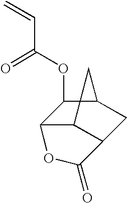 | 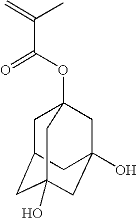 | 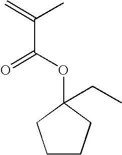 | 50/20/30 | 8500 | 1.50 |
| 3 | 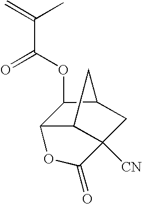 | 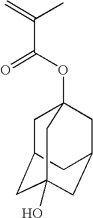 | 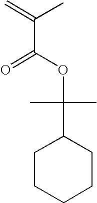 | 35/25/40 | 6000 | 1.44 |

<Preparation of Positive Resist Composition>

Each of the positive resist solutions was prepared by dissolving the components indicated in Table 3 in a solvent to thereby obtain a solution of 3.2 mass % solid content and passing the same through a polyethylene filter of 0.1 μm pore size.

TABLE 3

| | | Acid | Basic | Hydrophobic | | |
|---|---|---|---|---|---|---|
| | Resin | generator | compound | resin | Surfactant | Solvent |
| Resist | (mass/g) | (mass/g) | (mass/g) | (mass/g) | (mass/g) | (mass ratio) |
| RE 1 | Resin 1 | PAG-C | PEA | HR-25 | W-1 | A2/B3 |
| | (10) | (0.40) | (0.04) | (0.04) | (0.02) | (95/5) |
| RE 2 | Resin 2 | PAG-A | DIA | HR-51 | W-2 | A1/B1 |
| | (10) | (0.60) | (0.04) | (0.08) | (0.02) | (40/60) |
| RE 3 | Resin 3 | PAG-H | TPA | HR-58 | W-3 | A1/B2 |
| | (10) | (0.80) | (0.07) | (0.03) | (0.02) | (90/10) |

The abbreviations for acid generator, basic compound, surfactant and solvent indicated in Table 3 are as defined below.

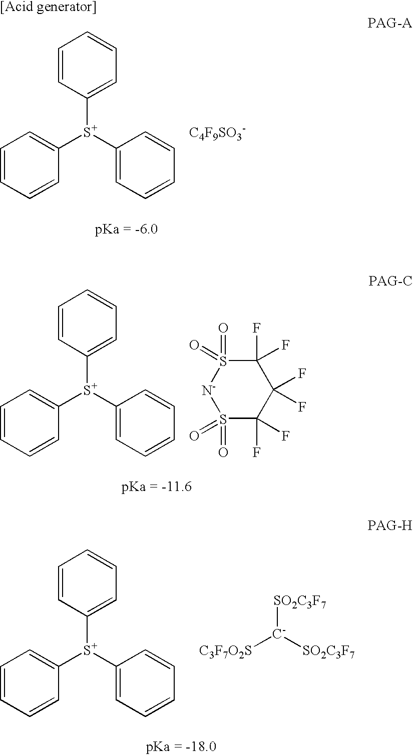

[Basic Compound]

DIA: 2,6-diisopropylaniline,

TPA: tripentylamine, and

PEA: N-phenyldiethanolamine.

[Surfactant]

W-1: Megafac R08 (produced by Dainippon Ink & Chemicals, Inc.) (fluorinated and siliconized),

W-2: Troy Sol S-366 (produced by Troy Chemical Co., Ltd.), and

W-3: PF6320 (produced by OMNOVA)(fluorinated).

[Solvent]

A1: propylene glycol monomethyl ether acetate,

A2: cyclohexanone,

B1: propylene glycol monomethyl ether,

B2: ethyl acetate, and

B3: γ-butyrolactone.

<Formation of Pattern>

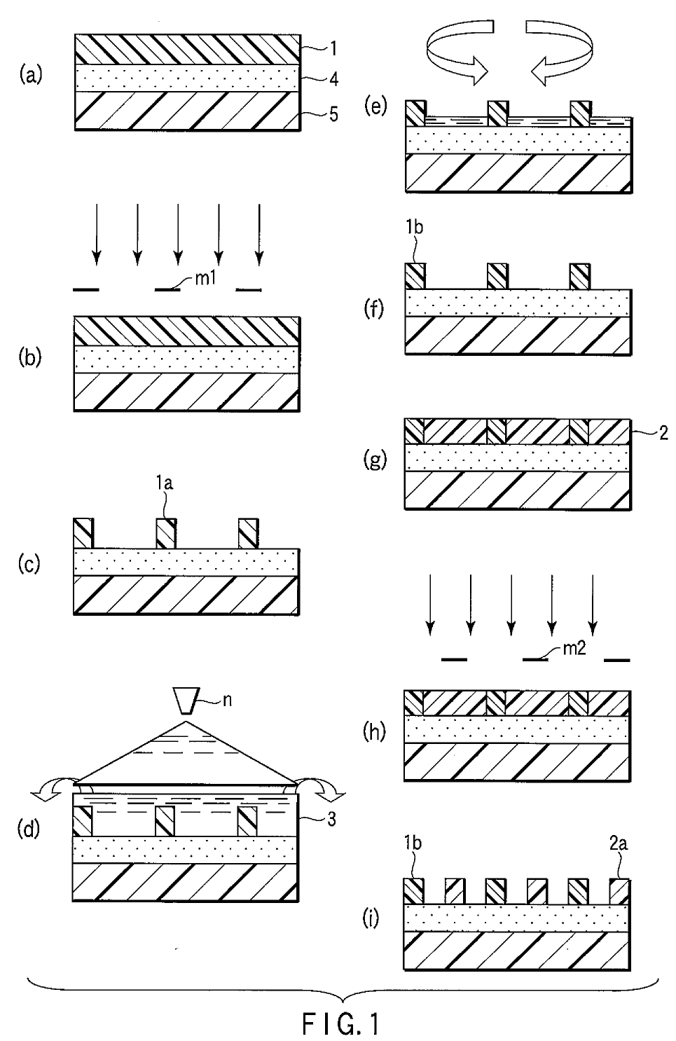

Referring to FIG. 1, the method of forming a pattern having undergone a freezing treatment will be described below.

An organic antireflection film (ARC29A (produced by Nissan Chemical Industries, Ltd.)) was applied onto a silicon wafer (5) and baked at 205° C. for 60 sec, thereby forming a 78 nm thick antireflection film (4). The above prepared first positive resist composition was applied thereonto and baked at 110° C. for 60 sec, thereby forming an 80 nm thick first resist film (1) (see FIG. 1(a)).

Subsequently, liquid immersion patterning exposure of the wafer furnished with the resist film (1) was performed through an exposure mask (m1) (line/space=1/3) with the use of an ArF excimer laser scanner (manufactured by ASML, TWINSCAN XT:1700Fi) (see FIG. 1(b)). Pure water was used as the liquid for liquid immersion. The intensity of exposure was regulated so as to obtain a desired line width. Thereafter, the exposed wafer was heated at 120° C. for 60 sec, developed with an aqueous solution of tetramethylammonium hydroxide (2.38 mass %) for 30 sec, rinsed with pure water, spin dried and heated at 90° C. for 90 sec so as to remove any remaining water, thereby obtaining a first resist pattern (1a) of 200 nm pitch and 50 nm line width (see FIG. 1(c)).

When the step of acid washing was added, each of the acid solutions listed in Table 4 was puddled on the substrate and allowed to stand still for 30 sec. Then the substrate was rotated at a speed of 500 rpm for 2 sec to thereby shake off most of the puddled solution. Thereafter, while the substrate was rotated at a speed of 200 rpm, the same solvent as used in the acid solution (consisting of the solvent only, not containing any other components) was spouted toward the center of the substrate at a flow rate of 3 ml/sec for 20 sec. Thereafter the substrate was rotated at a speed of 2000 rpm for 30 sec to thereby shake off the solvent.

Next, while the substrate was rotated at a speed of 100 rpm, a surface treating agent (freezing agent) was spouted through a nozzle (n) toward the center of the substrate at a flow rate of 2 cc/sec for 5 sec to thereby form a puddle. The substrate was allowed to stand still for 30 sec to thereby bring the treating agent into contact with the resist pattern (see FIG. 1(d)). Thereafter, the substrate was rotated at a speed of 2000 rpm for 30 sec to thereby shake off the treating agent (see FIG. 1(e)).

Further, in order to remove any excess treating agent, the same solvent as used in the treating agent (consisting of the solvent only, not containing any other components) was spouted toward the center of the substrate at a flow rate of 1 ml/sec for 10 sec while the substrate was rotated at a speed of 300 rpm. Thereafter, the substrate was rotated at a speed of 2000 rpm for 30 sec to thereby shake off the solvent. The resultant substrate was baked at 150° C. for 60 sec so as to advance the reaction (see FIG. 1(f)).

Furthermore, the second positive resist composition was applied onto the substrate furnished with the first resist pattern that had undergone the chemical treatment, and baked at 110° C. for 60 sec, thereby obtaining an 80 nm thick second resist film (2) (see FIG. 1(g)). The same composition as that of the first resist was used as the second positive resist composition.

Patterning exposure of the wafer furnished with the resist film (2) was performed through an exposure mask (m2) (line/space=1/3) with the use of ArF excimer laser scanner (manufactured by ASML, TWINSCAN XT:1700Fi) (see FIG. 1(h)). Thereafter, the exposed wafer was heated at 120° C. for 60 sec, developed with an aqueous solution of tetramethylammonium hydroxide (2.38 mass %) for 30 sec, rinsed with pure water, spin dried and further heated at 90° C. for 90 sec so as to remove any remaining water, thereby obtaining a second resist pattern (2a) of 200 nm pitch and 50 nm line width with the result that an overall resist pattern (1b and 2a) of 100 nm pitch and 50 nm line width was obtained (see FIG. 1(i)).

<Method of Measuring Pattern Dimensions>

With respect to each of the resist pattern (1a) prior to the chemical treatment and the resist pattern (1b) after the formation of the second resist pattern, the width of the pattern was measured by the use of a scanning electron microscope (SEM, model S-9380II manufactured by Hitachi, Ltd.). The height of the resist pattern was measured by the use of scanning electron microscope (SEM, model S-4800 manufactured by Hitachi, Ltd.). The results are summarized in Table 6.

<Method of Evaluating Line Width Roughness>

In the evaluation of line width roughness (LWR), the formed line pattern was observed by the use of a scanning electron microscope (SEM, model S9380 manufactured by Hitachi, Ltd.). With respect to a 2 μm range of the longitudinal edge of line pattern, the distance from a reference line on which edges were to be present was measured at 50 points. The standard deviation of measurements was determined, and 3σ was computed.

The acid solutions and freezing agents employed for pattern formation together with evaluation results are as follows.

TABLE 4
[Acid solution]

| Acid | Acid | | Acid conc. | |
|---|---|---|---|---|
| sol. | Type | pKa*¹ | (mol %) | Solvent*² |
| AL1 | Acid A | −0.4 | 0.5 | Butanol |
| AL2 | Acid B | −0.4 | 1.0 | Hexanol |
| AL3 | Acid C | −2.2 | 3.0 | Octanol |
| AL4 | Acid B | −0.4 | 2.5 | Hexanol/PGMEA (98/2) |
| AL5 | Acid A | −0.4 | 1.2 | Butanol/PGME (95/5) |
| AL6 | Acid C | −2.2 | 2.0 | Pentanol |

*¹Each value was determined by calculation with the use of the
aforementioned software package.
*²With respect to each mixing solvent, the mixing ratio (mass) of
two solvents is indicated.

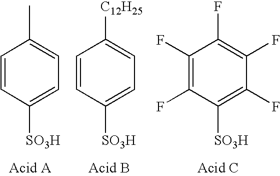

PGMEA: Propylene glycol monomethyl ether acetate
PGME: Propylene glycol monomethyl ether

TABLE 5
[Freezing agent]

| | | Concen- | | Concen- | | | Mixing ratio |
|---|---|---|---|---|---|---|---|
| | Chemical | tration | | tration | | | of solvent |
| Freezing agent | species | (mass %) | Initiator | (mass %) | Solv. 1 | Solv. 2 | (mass ratio) |
| FR1 | CR B | 1.5 | RG A | 0.1 | Butanol | | 100/0 |
| FR2 | CR D | 3.0 | RG C | 0.5 | Hexanol | | 100/0 |
| FR3 | CR C | 4.0 | RG B | 0.8 | Octanol | | 100/0 |
| FR4 | CR A | 0.5 | RG D | 0.9 | Hexanol | PGMEA | 90/10 |
| FR5 | CR C | 4.5 | RG D | 0.4 | Butanol | PGME | 95/5 |
| FR6 | CR B | 2.0 | RG A | 0.05 | Pentanol | | 100/0 |
| FR7 | CR D | 3.5 | RG C | 0.6 | Heptanol | | 100/0 |
| FR8 | CR A | 1.5 | RG B | 0.7 | Isoamyl alcohol | | 100/0 |
| FR9 | CR E | 4.0 | RG D | 0.6 | Butanol | | 100/0 |
| FR10 | CR F | 4.0 | RG A | 0.9 | Hexanol | | 100/0 |
| FR11 | CR C | 4.5 | — | — | Butanol | | 100/0 |

Chemical species

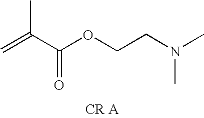

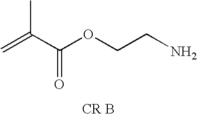

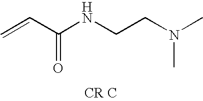

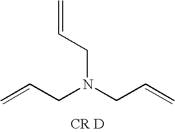

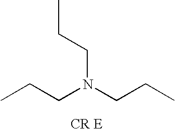

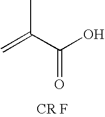

Polymerization initiator

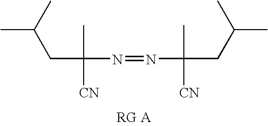

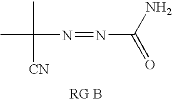

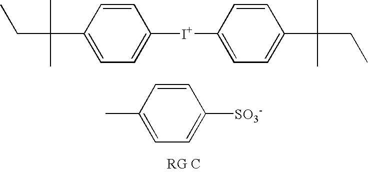

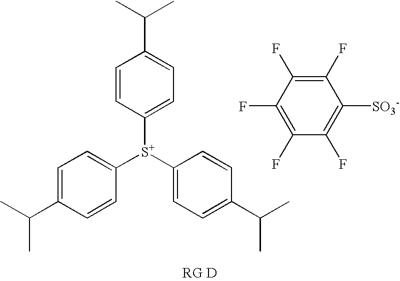

TABLE 6

| | | | | | | | First resist pattern after | | |
|---|---|---|---|---|---|---|---|---|---|
| | | | | | | | formation of | | |
| | | | | First resist pattern | | | second resist pattern | | |
| | | Acid | Freezing | Width | LWR | Height | Width | LWR | Height |
| | Resist | treatment | agent | (nm) | (nm) | (nm) | (nm) | (nm) | (nm) |
| Example 1 | RE1 | AL4 | FR2 | 50.5 | 5.5 | 77.5 | 53.6 | 5.8 | 76.5 |
| Example 2 | RE2 | AL1 | FR5 | 49.8 | 4.8 | 78.2 | 50.2 | 5.0 | 77.0 |
| Example 3 | RE2 | AL4 | FR2 | 49.8 | 4.8 | 78.2 | 53.1 | 5.3 | 77.6 |
| Example 4 | RE3 | AL3 | FR4 | 50.2 | 5.2 | 77.8 | 50.7 | 5.6 | 77.5 |
| Example 5 | RE3 | AL1 | FR8 | 50.2 | 5.2 | 77.8 | 50.6 | 5.1 | 77.6 |
| Example 6 | RE2 | — | FR5 | 49.8 | 4.8 | 78.2 | 55.4 | 6.5 | 74.5 |
| Example 7 | RE2 | AL3 | FR5 | 49.8 | 4.8 | 78.2 | 50.0 | 4.7 | 78.0 |
| Example 8 | RE2 | AL2 | FR3 | 49.8 | 4.8 | 78.2 | 50.6 | 4.9 | 78.1 |
| Example 9 | RE2 | AL2 | FR5 | 49.8 | 4.8 | 78.2 | 50.4 | 5.0 | 77.3 |
| Example 10 | RE2 | AL4 | FR3 | 49.8 | 4.8 | 78.2 | 51.0 | 5.2 | 77.2 |
| Example 11 | RE2 | AL5 | FR6 | 49.8 | 4.8 | 78.2 | 50.8 | 5.1 | 77.1 |
| Example 12 | RE3 | AL2 | FR1 | 50.2 | 5.2 | 77.8 | 50.5 | 5.2 | 77.5 |
| Example 13 | RE3 | AL4 | FR7 | 50.2 | 5.2 | 77.8 | 50.6 | 5.6 | 77.0 |
| Example 14 | RE2 | AL4 | FR6 | 49.8 | 4.8 | 78.2 | 50.4 | 5.2 | 78.0 |
| Example 15 | RE2 | — | FR4 | 49.8 | 4.8 | 78.2 | 54.2 | 6.8 | 72.1 |
| Example 16 | RE2 | AL6 | FR6 | 49.8 | 4.8 | 78.2 | 50.0 | 5.3 | 77.5 |
| Example 17 | RE3 | AL4 | FR3 | 50.2 | 5.2 | 77.8 | 50.8 | 5.5 | 77.6 |
| Example 18 | RE2 | AL2 | FR7 | 49.8 | 4.8 | 78.2 | 50.9 | 5.0 | 77.5 |
| Example 19 | RE1 | AL5 | FR4 | 50.5 | 5.5 | 77.5 | 50.9 | 5.6 | 75.9 |
| Example 20 | RE3 | AL5 | FR5 | 50.2 | 5.2 | 77.8 | 50.4 | 5.2 | 77.0 |
| Example 21 | RE3 | AL2 | FR2 | 50.2 | 5.2 | 77.8 | 54.1 | 5.6 | 77.6 |
| Example 22 | RE1 | AL4 | FR6 | 50.5 | 5.5 | 77.5 | 50.6 | 5.6 | 75.9 |
| Example 23 | RE2 | AL3 | FR2 | 49.8 | 4.8 | 78.2 | 52.9 | 4.9 | 77.5 |
| Example 24 | RE2 | AL4 | FR8 | 49.8 | 4.8 | 78.2 | 51.0 | 4.8 | 77.0 |
| Example 25 | RE1 | AL3 | FR4 | 50.5 | 5.5 | 77.5 | 50.9 | 5.4 | 77.0 |
| Example 26 | RE1 | AL6 | FR3 | 50.5 | 5.5 | 77.5 | 50.9 | 5.9 | 77.2 |
| Example 27 | RE3 | AL5 | FR6 | 50.2 | 5.2 | 77.8 | 50.4 | 5.3 | 76.6 |
| Example 28 | RE2 | AL5 | FR5 | 49.8 | 4.8 | 78.2 | 50.0 | 5.0 | 77.5 |
| Example 29 | RE2 | AL3 | FR4 | 49.8 | 4.8 | 78.2 | 50.9 | 5.0 | 77.6 |
| Example 30 | RE2 | AL4 | FR1 | 49.8 | 4.8 | 78.2 | 50.6 | 5.3 | 77.4 |
| Example 31 | RE1 | AL4 | FR11 | 50.5 | 5.5 | 77.5 | 59.5 | 7.4 | 68.7 |
| Comp. 1 | RE1 | AL4 | FR9 | 50.5 | 5.5 | 77.5 | Pattern vanished. | | |
| Comp. 2 | RE1 | AL4 | FR10 | 50.5 | 5.5 | 77.5 | 70.3 | 8.4 | 32.8 |

It is apparent from Table 6 that any changes in the width, LWR and height of the first resist pattern exhibited upon the formation of the second resist pattern can be suppressed by the use of the surface treating agent for resist pattern of the present invention.

What is claimed is:

1. A surface treating agent for resist pattern, containing a chemical species having a functional group capable of chemical adsorption to resist pattern and a polymerizable group, and a solvent.

2. The surface treating agent for resist pattern according to claim 1, wherein the chemical adsorption is based on an ionic bond or electrostatic attractive force.

3. The surface treating agent for resist pattern according to claim 1, wherein the functional group capable of chemical adsorption is a basic functional group.

4. The surface treating agent for resist pattern according to claim 3, wherein the basic functional group is an amino group.

5. The surface treating agent for resist pattern according to claim 1, wherein the polymerizable group is a group containing an ethylenically unsaturated bond.

6. The surface treating agent for resist pattern according to claim 1, wherein further a polymerization initiator is contained.

7. The surface treating agent for resist pattern according to claim 6, wherein the polymerization initiator is a thermal radical initiator.

8. The surface treating agent for resist pattern according to claim 1, in a resist pattern consisting of a first resist pattern obtained by exposing a first resist film and developing the exposed film and a second resist pattern obtained by exposing a second resist film provided on the first resist pattern and developing the exposed film, being a surface treating agent for the first resist pattern.

9. A method of forming a resist pattern, including the step of exposing a first resist film and developing the exposed film to thereby obtain a first resist pattern and the step of forming a second resist film on the first resist pattern obtained in the above step, exposing the second resist film and developing the exposed film to thereby obtain a second resist pattern, wherein between the first resist pattern forming step and the second resist pattern forming step, there is interposed the step of treating the first resist pattern with the use of the surface treating agent according to claim 1.

10. The resist pattern forming method according to claim 9, wherein a heating step is interposed between the first resist pattern treating step using the surface treating agent and the second resist pattern forming step.

11. The resist pattern forming method according to claim 9, wherein the step of treating the first resist pattern with the use of an acid is interposed between the first resist pattern forming step and the first resist pattern treating step using the surface treating agent.

12. The resist pattern forming method according to claim 11, wherein a heating step is interposed between the step of treating the first resist pattern with the use of an acid and the first resist pattern treating step using the surface treating agent.
